(19) United States
(12) Patent Application Publication
(10) Pub. No.: US 2026/0255702 A1
(43) Pub. Date: Aug. 27, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventors: TOMOHIKO KAWAMURA, KANAGAWA (JP); HIROKAZU EJIRI, KANAGAWA (JP)

(21) Appl. No.: 19/489,644

(22) PCT Filed: May 13, 2024
(86) PCT No.: PCT/JP2024/017673

§ 371 Date: Dec. 3, 2025

(30) Foreign Application Priority Data
Jun. 28, 2023 (JP) 2023-105943

(51) Int. Cl. H10F 39/00; H10F 39/18

(52) U.S. Cl. CPC H10F 39/8023; H10F 39/182; H10F 39/811; H10F 39/8063

(57) ABSTRACT

To increase a degree of freedom of arrangement of a pixel transistor in a photoelectric conversion region. A photodetection device including: a semiconductor layer including a first surface portion and a second surface portion located on sides opposite to each other in a thickness direction; a photoelectric conversion region partitioned by an isolation region extending in the thickness direction of the semiconductor layer and provided in the semiconductor layer, the photoelectric conversion region including an upper surface portion located on the first surface portion side of the semiconductor layer and a first side surface portion located on the isolation region side; a transfer transistor provided on the upper surface portion side of the photoelectric conversion region and transferring a signal charge photoelectrically converted by the photoelectric conversion unit to a charge holding unit; and a plurality of pixel transistors provided on the upper surface portion of the photoelectric conversion region, wherein at least one pixel transistor of the plurality of pixel transistors includes a gate electrode provided in the isolation region adjacent to the first side surface portion of the photoelectric conversion region with a gate insulating film interposed therebetween.

### TECHNICAL FIELD

The present technology (technology according to the present disclosure) relates to a photodetection device and an electronic apparatus, and particularly relates to a technology effective when applied to a photodetection device in which a pixel transistor is provided in a photoelectric conversion region and an electronic apparatus including the photodetection device.

### BACKGROUND ART

A photodetection device such as a solid-state imaging device or a distance measuring device includes a transfer transistor that transfers photoelectrically converted signal charges to a charge holding unit, and a pixel circuit that outputs a pixel signal based on the signal charges held in the charge holding unit. Patent Document 1 discloses a solid-state imaging device in which a transfer transistor and a pixel transistor included in the pixel circuit are provided in a photoelectric conversion region of a semiconductor layer. In addition, Patent Document 1 also discloses a photoelectric conversion region partitioned by a trench-type isolation region.

On the other hand, Patent Document 2 discloses an imaging device in which a groove for shallow trench isolation (STI) is formed in a substrate, a voltage is applied to an embedded polysilicon electrode embedded in the groove via an insulating film to enhance pinning of an STI sidewall at the time of accumulation, and a voltage is applied to a pixel region P well and the embedded polysilicon electrode to improve signal charge transfer at the time of transfer.

### CITATION LIST

### Patent Document

Patent Document 1: Japanese Patent Application Laid-Open No. 2021-101491

Patent Document 2: Japanese Patent Application Laid-Open No. 2006-120804

### SUMMARY OF THE INVENTION

### Problems to be Solved by the Invention

Meanwhile, in recent years, high-resolution image sensors have been demanded in the market, and development of image sensors with a reduced pixel size has been advanced.

However, as the pixel size is reduced, it becomes difficult to arrange active elements such as transfer transistors and pixel transistors in the photoelectric conversion region, and the degree of freedom in arrangement of the active elements is reduced.

An object of the present technology is to provide a technology capable of increasing a degree of freedom in arrangement of active elements in a photoelectric conversion region.

### Solutions to Problems

(1) A photodetection device according to an aspect of the present technology includes:
a semiconductor layer including a first surface portion and a second surface portion located on sides opposite to each other in a thickness direction; and
a photoelectric conversion region partitioned by an isolation region extending in a thickness direction of the semiconductor layer and provided in the semiconductor layer.

Then, the photoelectric conversion region includes:
an upper surface portion located on the first surface portion side of the semiconductor layer and a first side surface portion located on the isolation region side;
a transfer transistor provided on the upper surface portion side of the photoelectric conversion region and transferring a signal charge photoelectrically converted by the photoelectric conversion unit to a charge holding unit; and
a plurality of pixel transistors provided on the upper surface portion of the photoelectric conversion region.

Then, at least one pixel transistor of the plurality of pixel transistors includes a gate electrode provided in the isolation region so as to be adjacent to the first side surface portion of the photoelectric conversion region with a gate insulating film interposed therebetween.

(2) A photodetection device according to another aspect of the present technology includes:
a semiconductor layer; and
a photoelectric conversion region partitioned by an isolation region extending in a thickness direction of the semiconductor layer and provided in the semiconductor layer.

Then, the photoelectric conversion region includes:
an upper surface portion and a side surface portion;
a charge holding unit provided on the upper surface portion side and holding a signal charge transferred from the photoelectric conversion unit via a transfer transistor; and
a pixel transistor provided on the upper surface portion side.

Then, in two of the photoelectric conversion regions adjacent to each other via the isolation region in plan view, the pixel transistor provided in one photoelectric conversion region includes a gate electrode provided over the upper surface portion of one photoelectric conversion region and the isolation region in plan view and connected to the charge holding unit of the other photoelectric conversion region at the side surface portion of the other photoelectric conversion region.

(3) An electronic apparatus according to another aspect of the present technology includes:
the photodetection device;
an optical lens that forms an image of image light from a subject on an imaging surface of the detection device; and
a signal processing circuit that performs signal processing on a signal output from the photodetection device.

### BRIEF DESCRIPTION OF DRAWINGS

FIG. 1 is a chip layout diagram illustrating a configuration example of a solid-state imaging device according to a first embodiment of the present technology.

FIG. 2 is a block diagram illustrating a configuration example of the solid-state imaging device according to the first embodiment of the present technology.

FIG. 3 is an equivalent circuit diagram illustrating a configuration example of a pixel and a pixel circuit according to the first embodiment of the present technology.

FIG. 4A is a plan view schematically illustrating a configuration example of four pixels included in a pixel array unit of FIG. 1.

FIG. 4B is an enlarged plan view of a part of FIG. 4A.

FIG. 5A is a longitudinal sectional view schematically illustrating a longitudinal sectional structure taken along line a4-a4 in FIG. 4A.

FIG. 5B is an enlarged longitudinal sectional view schematically illustrating a part of FIG. 5A.

FIG. 6 is an enlarged longitudinal sectional view schematically illustrating a part of a longitudinal sectional structure taken along line b4-b4 in FIG. 4A.

FIG. 7 is an enlarged longitudinal sectional view schematically illustrating a part of a longitudinal sectional structure taken along line c4-c4 in FIG. 4A.

FIG. 8 is an enlarged longitudinal sectional view schematically illustrating a part of a longitudinal sectional structure taken along line d4-d4 in FIG. 4A.

FIG. 9 is a diagram schematically illustrating steps of a method for manufacturing the solid-state imaging device according to the first embodiment of the present technology (longitudinal sectional view taken along line a4-a4 in FIG. 4A). FIG. 10 is a view schematically illustrating a step after the step in FIG. 9 (longitudinal sectional view taken along line a4-a4 in FIG. 4A).

FIG. 11 is a view schematically illustrating a step after the step in FIG. 10 (longitudinal sectional view taken along line a4-a4 in FIG. 4A).

FIG. 12 is a view schematically illustrating a step subsequent to FIG. 11 (longitudinal sectional view taken along line a4-a4 in FIG. 4A).

FIG. 13 is a view schematically illustrating a step subsequent to FIG. 12 (longitudinal sectional view taken along line a4-a4 in FIG. 4A).

FIG. 14 is a view schematically illustrating a step subsequent to FIG. 13 (longitudinal sectional view taken along line b4-b4 in FIG. 4A).

FIG. 15 is a view schematically illustrating a step subsequent to FIG. 14 (longitudinal sectional view taken along line b4-b4 in FIG. 4A).

FIG. 16 is a view schematically illustrating a step subsequent to FIG. 15 (longitudinal sectional view taken along line a4-a4 in FIG. 4A).

FIG. 17A is a view schematically illustrating a step subsequent to FIG. 16 (longitudinal sectional view taken along line a4-a4 in FIG. 4A).

FIG. 17B is a view schematically illustrating a step subsequent to FIG. 16 (longitudinal sectional view taken along line b4-b4 in FIG. 4A).

FIG. 18A is a view schematically illustrating a step subsequent to FIG. 17A (longitudinal sectional view taken along line a4-a4 in FIG. 4A).

FIG. 18B is a view schematically illustrating a step subsequent to FIG. 17B (longitudinal sectional view taken along line b4-b4 in FIG. 4A).

FIG. 19 is a longitudinal sectional view schematically illustrating a part of a longitudinal sectional structure of a solid-state imaging device according to a second embodiment of the present technology.

FIG. 20 is a plan view schematically illustrating a configuration example of one pixel block in a solid-state imaging device according to a third embodiment of the present technology.

FIG. 21 is a longitudinal sectional view schematically illustrating a part of a longitudinal sectional structure taken along line a20-a20 in FIG. 20.

FIG. 22 is a plan view schematically illustrating a part of a longitudinal sectional structure of a solid-state imaging device according to a fourth embodiment of the present technology.

FIG. 23 is a plan view schematically illustrating a configuration example of two pixel blocks in a solid-state imaging device according to a fifth embodiment of the present technology.

FIG. 24 is an enlarged longitudinal sectional view schematically illustrating a part of a longitudinal sectional structure taken along line a23-a23 in FIG. 23.

FIG. 25 is a plan view schematically illustrating a configuration example of two pixel blocks in a solid-state imaging device according to a sixth embodiment of the present technology.

FIG. 26 is an enlarged longitudinal sectional view schematically illustrating a part of a longitudinal sectional structure taken along line a25-a25 in FIG. 25.

FIG. 27 is an enlarged longitudinal sectional view schematically illustrating a part of a longitudinal sectional structure taken along line b25-b25 in FIG. 25.

FIG. 28 is an enlarged longitudinal sectional view schematically illustrating a part of a longitudinal sectional structure taken along line c25-c25 in FIG. 25.

FIG. 29 is an enlarged longitudinal sectional view schematically illustrating a part of a longitudinal sectional structure taken along line d25-d25 in FIG. 25.

FIG. 30 is an equivalent circuit diagram illustrating a configuration example of a pixel and a pixel circuit in a solid-state imaging device according to a seventh embodiment of the present technology.

FIG. 31 is a plan view schematically illustrating a configuration example of two pixel blocks in a solid-state imaging device according to a seventh embodiment of the present technology.

FIG. 32 is an enlarged longitudinal sectional view schematically illustrating a part of a longitudinal sectional structure taken along line a30-a30 in FIG. 30.

FIG. 33 is an equivalent circuit diagram schematically illustrating a configuration example of a pixel and a pixel circuit in a solid-state imaging device according to an eighth embodiment of the present technology.

FIG. 34 is a plan view schematically illustrating a configuration example of two pixel blocks in a solid-state imaging device according to an eighth embodiment of the present technology.

FIG. 35 is an enlarged longitudinal sectional view schematically illustrating a part of a longitudinal sectional structure taken along line a34-a34 in FIG. 34.

FIG. 36 is a main part longitudinal sectional view schematically illustrating Modification 8-1 according to the eighth embodiment of the present technology.

FIG. 37 is a main part longitudinal sectional view schematically illustrating Modification 8-2 according to the eighth embodiment of the present technology.

FIG. 38 is a main part longitudinal sectional view schematically illustrating Modification 8-3 according to the eighth embodiment of the present technology.

FIG. 39 is a main part longitudinal sectional view schematically illustrating Modification 8-4 according to the eighth embodiment of the present technology.

FIG. 40 is a main part longitudinal sectional view schematically illustrating Modification 8-5 according to the eighth embodiment of the present technology.

FIG. 41 is a main part longitudinal sectional view schematically illustrating Modification 8-6 according to the eighth embodiment of the present technology.

FIG. 42 is a main part longitudinal sectional view schematically illustrating Modification 8-7 according to the eighth embodiment of the present technology.

FIG. 43 is a plan view schematically illustrating a configuration example of two pixel blocks in a solid-state imaging device according to a ninth embodiment of the present technology.

FIG. 44 is a longitudinal sectional view schematically illustrating a longitudinal sectional structure taken along line a43-a43 in FIG. 43.

FIG. 45 is a plan view schematically illustrating a configuration example of two pixel blocks in a solid-state imaging device according to a tenth embodiment of the present technology.

FIG. 46 is a longitudinal sectional view schematically illustrating a longitudinal sectional structure taken along line a45-a45 in FIG. 45.

FIG. 47 is a diagram illustrating a configuration example of an electronic apparatus according to an eleventh embodiment of the present technology.

### MODE FOR CARRYING OUT THE INVENTION

Embodiments of the present technology will be described in detail hereinafter with reference to the drawings.

Note that in the illustration of the drawings referred to in the following description, the same or similar portions are denoted by the same or similar reference signs. It should be noted that the drawings are schematic, and relationships between thicknesses and planar dimensions, ratios of thicknesses between layers, and the like are different from actual ones. Therefore, specific thicknesses and dimensions should be determined in consideration of the following description.

Furthermore, it is needless to say that portions having different dimensional relationships and ratios are included between the drawings. Furthermore, the effects described herein are merely illustrative and not limiting, and there may also be Furthermore, the following embodiments illustrate devices and methods for implementing the technical idea of the present technology and are not intended to limit the configuration to those described below. That is, various modifications can be made to the technical idea of the present technology within the technical scope described in the claims.

Furthermore, definitions of directions such as up and down in the following description are merely for convenience of description and are not intended to limit the technical idea of the present technology. For example, it goes without saying that when an object is observed while being rotated by 90°, the up and down are converted into left and right, and when the object is observed while being rotated by 180°, the up and down are inverted.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a semiconductor layer 21 described later will be described as the Z direction.

In addition, a “plan view” in the following description refers to a case of being viewed from a direction along a thickness direction of a semiconductor layer 21 described later. In addition, the “thickness direction of the semiconductor layer” refers to a direction representing the thickness of the semiconductor layer 21.

### First Embodiment

In a first embodiment, an example where the present technology is applied, as a photodetection device, to a solid-state imaging device that is a back-illuminated complementary metal-oxide-semiconductor (CMOS) image sensor will be described.

Furthermore, in the first embodiment, a case where gate electrodes of a selection transistor and a reset transistor among a plurality of pixel transistors included in a pixel circuit are provided in an isolation region will be described.

### Overall Configuration of Solid-State Imaging Device

First, an overall configuration of a solid-state imaging device 1A will be described.

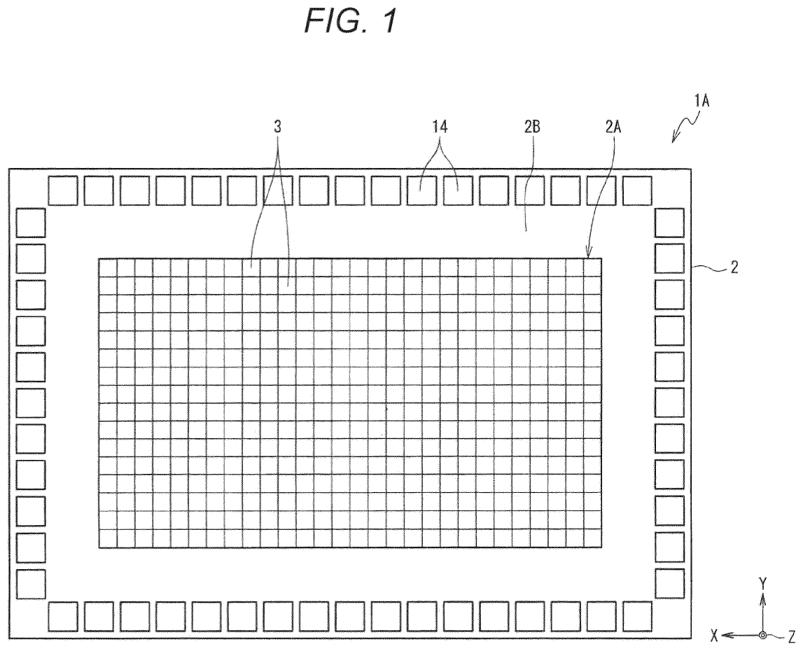

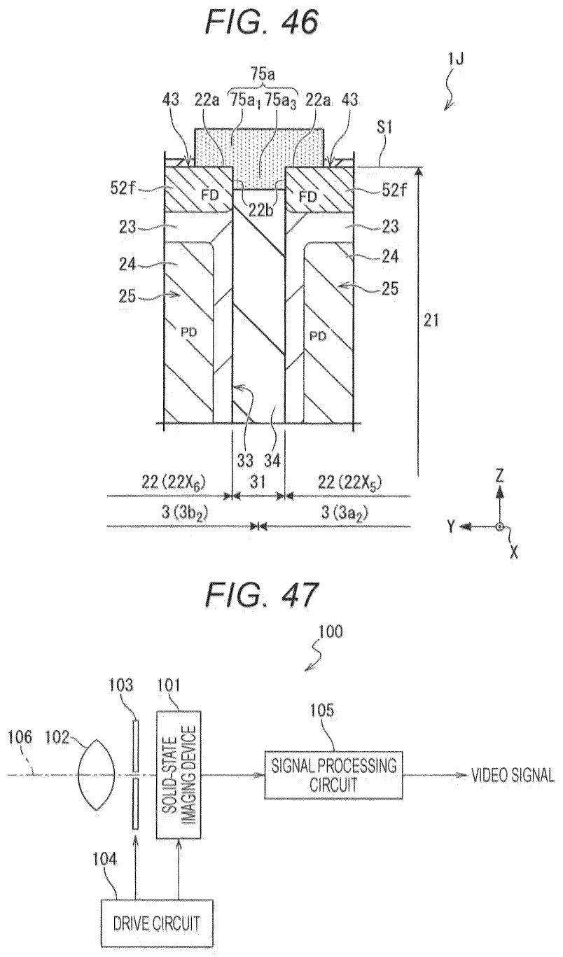

As illustrated in FIG. 1, the solid-state imaging device 1A according to the first embodiment of the present technology mainly includes a semiconductor chip 2 having a square two-dimensional planar shape in plan view. That is, the solid-state imaging device 1A is mounted on the semiconductor chip 2, and the semiconductor chip 2 can be regarded as the solid-state imaging device 1A. As illustrated in FIG. 47, the solid-state imaging device 1A (101) takes in image light (incident light 106) from a subject via an optical lens 102, converts a light amount of the incident light 106 formed on an imaging surface into an electrical signal in units of pixels, and outputs the electrical signal as a pixel signal.

As illustrated in FIG. 1, the semiconductor chip 2 on which the solid-state imaging device 1A is mounted includes, in a two-dimensional plane including the X direction and the Y direction orthogonal to each other, a square pixel array unit 2A provided in a central portion thereof and a peripheral portion 2B provided outside the pixel array unit 2A in such a way as to surround the pixel array unit 2A. A semiconductor wafer including the semiconductor layer 21 described later is diced into small pieces, each serving as a chip formation region, to form the semiconductor chip 2 in a manufacturing process. The configuration of the solid-state imaging device 1A, which will be described below, therefore, is substantially similar to that before the semiconductor wafer is diced into small pieces. That is, the present technology is applicable to both a semiconductor chip and a semiconductor wafer.

The pixel array unit 2A is, for example, a light receiving surface that receives light condensed by an optical lens (optical system) 102 illustrated in FIG. 47. Then, in the pixel array unit 2A, a plurality of pixels 3 (sensor pixels) is arranged in a matrix on a two-dimensional plane including the X direction and the Y direction. In other words, the pixels 3 are repeatedly arranged in the X direction and the Y direction orthogonal to each other in the two-dimensional plane.

As illustrated in FIG. 1, a plurality of bonding pads 14 is arranged in the peripheral portion 2B. Each of the plurality of bonding pads 14 is arranged along each of four sides of the two-dimensional plane of the semiconductor chip 2, for example. Each of the plurality of bonding pads 14 functions as an input/output terminal that electrically connects the semiconductor chip 2 and an external device to each other.

### Logic Circuit

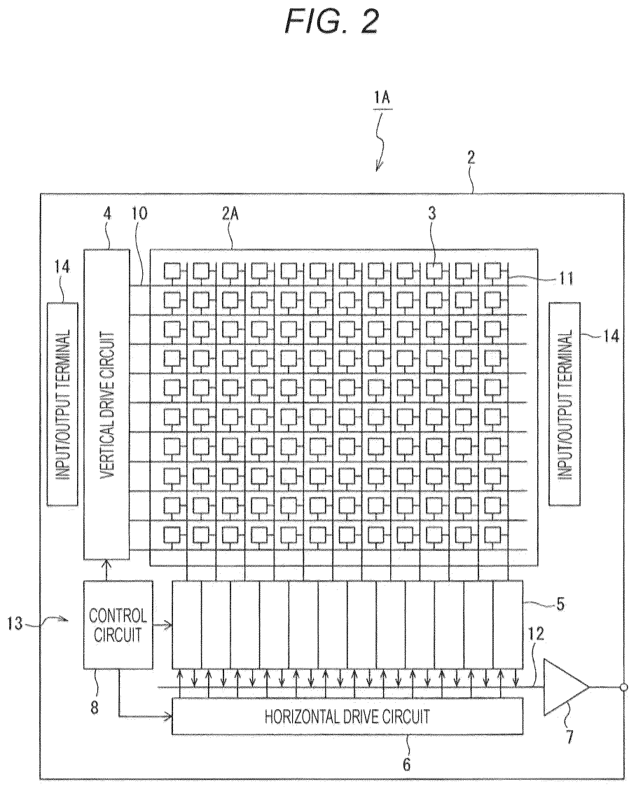

The semiconductor chip 2 includes a logic circuit 13 illustrated in FIG. 2. As illustrated in FIG. 2, the logic circuit 13 includes a vertical drive circuit 4, column signal processing circuits 5, a horizontal drive circuit 6, an output circuit 7, a control circuit 8, and the like. The logic circuit 13 includes, for example, a complementary MOS (CMOS) circuit including an n-channel metal-oxide-semiconductor field-effect transistor (MOSFET) and a p-channel MOSFET as field-effect transistors.

The vertical drive circuit 4 illustrated in FIG. 2 includes a shift register, for example. The vertical drive circuit 4 sequentially selects desired pixel drive lines 10, supplies pulses for driving the pixels 3 to the selected pixel drive lines 10, and drives the pixels 3 row by row. That is, the vertical drive circuit 4 selectively scans the individual pixels 3 in the pixel array unit 2A sequentially in a vertical direction row by row and supplies pixel signals from the pixels 3 based on the signal charge generated by photoelectric conversion units of the pixels 3 in accordance with the amount of light received to the corresponding column signal processing circuits 5 through corresponding vertical signal lines 11.

The column signal processing circuit 5 illustrated in FIG. 2 is arranged, for example, for each column of the pixels 3, and performs signal processing such as noise removal for each pixel column on signals output from the pixels 3 of one row. For example, each column signal processing circuit 5 performs signal processing such as correlated double sampling (CDS) for removing pixel-specific fixed pattern noise, and analog-to-digital (AD) conversion.

The horizontal drive circuit 6 illustrated in FIG. 2 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output pixel signals obtained as a result of signal processing to a horizontal signal line 12.

The output circuit 7 illustrated in FIG. 2 performs signal processing on the pixel signals sequentially supplied from each of the column signal processing circuits 5 through the horizontal signal line 12, and outputs the processed pixel signals. As the signal processing, for example, buffering, black level adjustment, column variation correction, various types of digital signal processing, and the like can be used.

The control circuit 8 illustrated in FIG. 2 generates clock signals and control signals as references for operations of the vertical drive circuit 4, the column signal processing circuits 5, the horizontal drive circuit 6, and the like on the basis of a vertical synchronization signal, a horizontal synchronization signal, and a master clock signal. Then, the control circuit 8 then outputs the generated clock signals and control signals to the vertical drive circuit 4, the column signal processing circuits 5, the horizontal drive circuit 6, and the like.

### Pixel Block

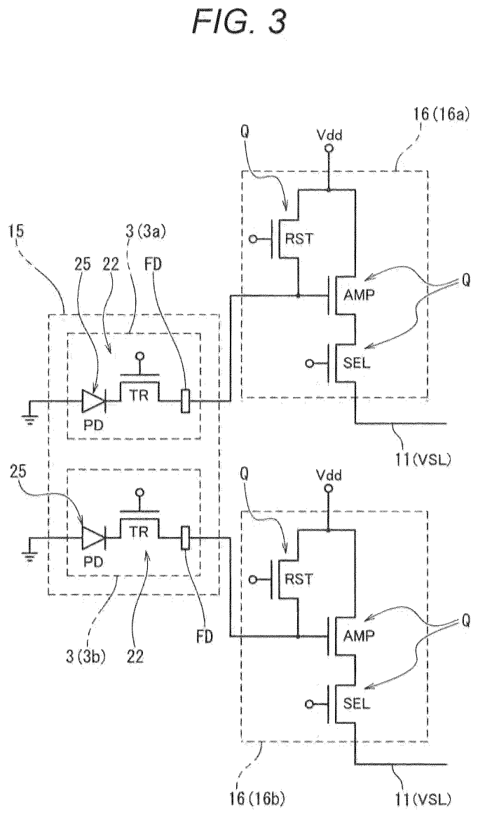

The semiconductor chip 2 includes a pixel block 15 and a pixel circuit (readout circuit) 16 illustrated in FIG. 3.

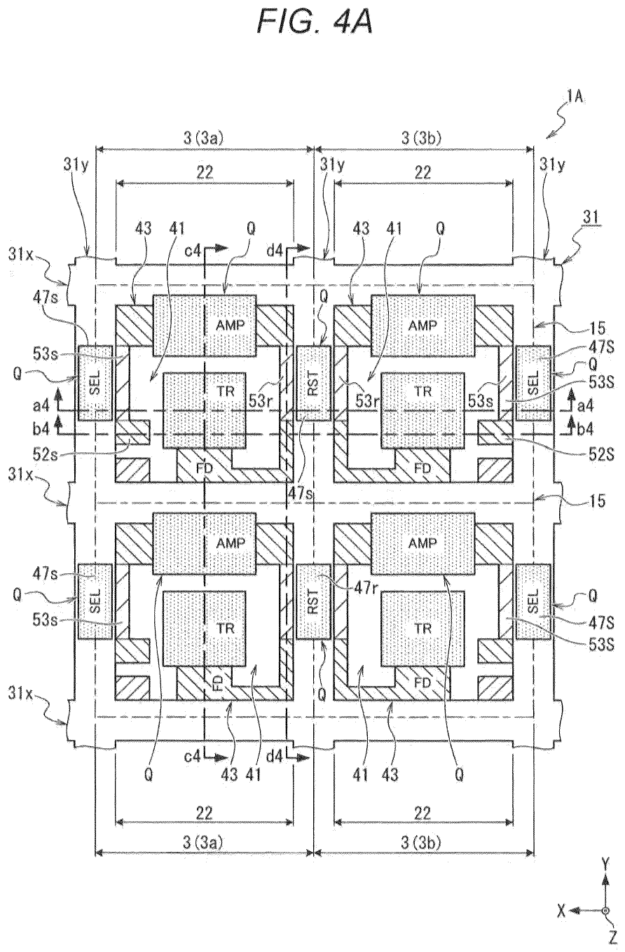

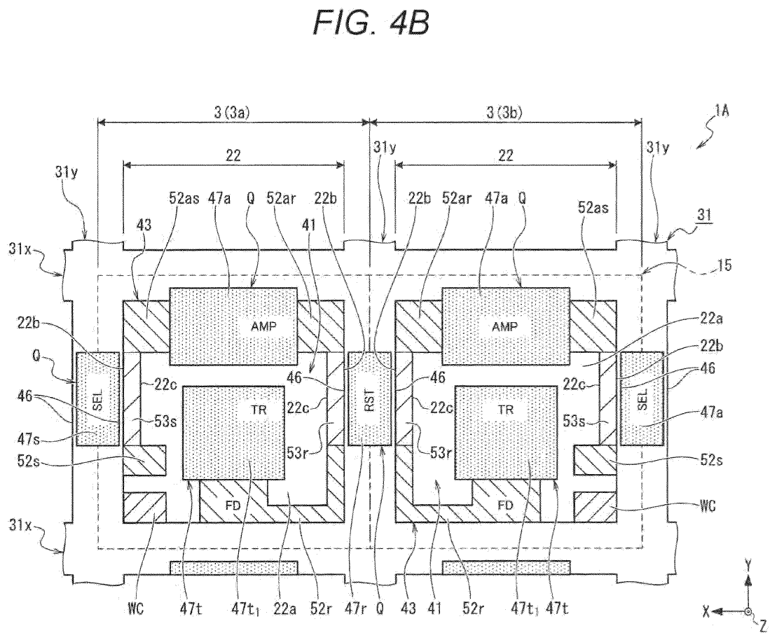

As illustrated in FIGS. 3 and 4A, the pixel block 15 includes a plurality of pixels 3. The pixel block 15 of the first embodiment is not limited thereto, but includes, for example, two pixels 3 (3a, 3b) arranged adjacent to each other in the X direction in plan view as one unit. In FIG. 3, one pixel block 15 is mainly illustrated, and in FIG. 4A, two pixel blocks 15 arranged adjacent to each other mainly in the Y direction are illustrated. However, the pixel blocks 15 are repeatedly arranged in each of the X direction and the Y direction to construct the pixel array unit 2A illustrated in FIG. 1.

As illustrated in FIG. 3, each of two pixels 3a and 3b included in one pixel block 15 has a common component. Specifically, each of the two pixels 3a and 3b included in one pixel block 15 includes a photoelectric conversion unit 25, a floating diffusion region (FD) as a charge holding unit that holds (accumulates) the signal charge photoelectrically converted by the photoelectric conversion unit 25, and a transfer transistor TR that transfers the signal charge photoelectrically converted by the photoelectric conversion unit 25 to the floating diffusion region FD.

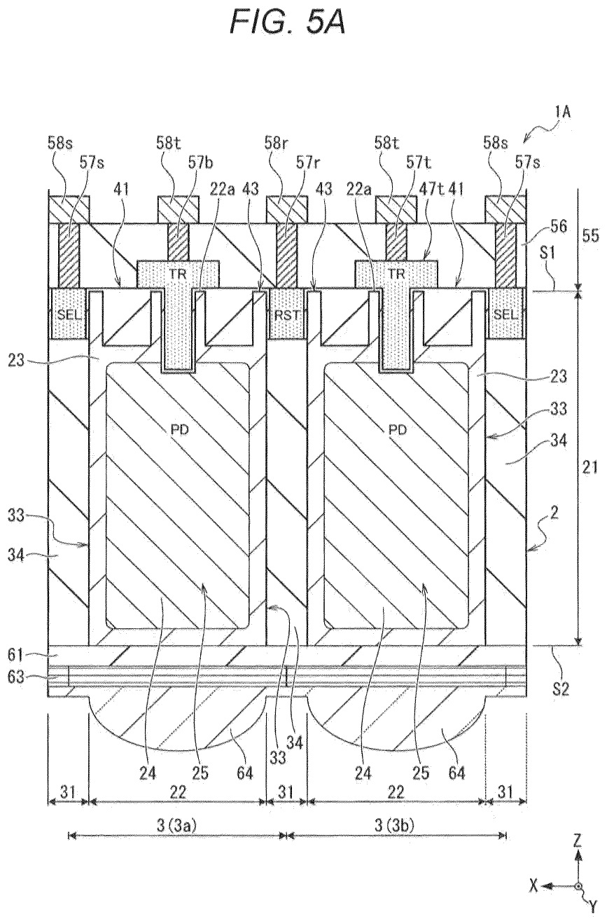

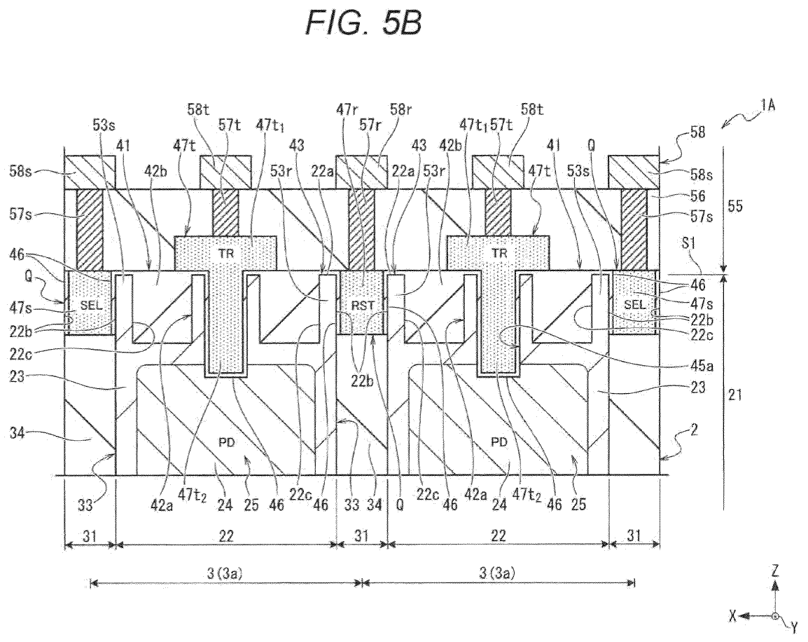

Furthermore, each of the two pixels 3a and 3b included in one pixel block 15 further includes a photoelectric conversion region 22 of the semiconductor layer 21 illustrated in FIG. 5A. Then, as illustrated in FIG. 5A, each of the photoelectric conversion unit 25, the floating diffusion region FD, and the transfer transistor TR is provided in the photoelectric conversion region 22.

### Photoelectric Conversion Unit

The photoelectric conversion unit 25 illustrated in FIG. 3 includes, for example, a pn junction photodiode (PD), and generates a signal charge in accordance with the amount of received light. Furthermore, the photoelectric conversion unit 25 temporarily holds (accumulates) the generated signal charge.

The photoelectric conversion unit 25 has a cathode side electrically connected to a source region of the transfer transistor TR and an anode side electrically connected to a reference potential line (for example, ground).

### Transfer Transistor

The transfer transistor TR illustrated in FIG. 3 transfers the signal charge photoelectrically converted by the photoelectric conversion unit 25 to the floating diffusion region FD. In the transfer transistor TR, a source region is electrically connected to the cathode side of the photoelectric conversion unit 25, and a drain region is electrically connected to the floating diffusion region FD. Then, a gate electrode of the transfer transistor TR is electrically connected to a transfer transistor drive line among the pixel drive lines 10 illustrated in FIG. 2.

### Floating Diffusion Region

The floating diffusion region FD illustrated in FIG. 3 temporarily accumulates and holds the signal charge transferred from the photoelectric conversion unit 25 via the transfer transistor TR.

### Pixel Circuit

As illustrated in FIG. 3, the pixel circuit 16 is provided for each pixel 3, for example, but not limited thereto, and an input side thereof is electrically connected to the floating diffusion region FD.

Here, in the first embodiment, as an example, a circuit configuration in which the pixel circuit 16 is allocated for each pixel 3 is adopted, but the present invention is not limited to the first embodiment. For example, a circuit configuration in which one pixel circuit 16 is allocated to one pixel block 15 having two pixels 3 (3a, 3b) as one unit may be adopted, or a circuit configuration in which one pixel circuit 16 is allocated to one pixel block 15 having two or more pixels 3 as one unit may be adopted. Furthermore, a circuit configuration in which one pixel circuit 16 is allocated to a plurality of pixel blocks 15 each having a plurality of pixels 3 as one unit may be adopted.

Furthermore, as illustrated in FIG. 4A, in the first embodiment, as a configuration of the pixel block 15, the two pixels 3a and 3b adjacent to each other in the X direction are set as one unit, but the number of pixels 3 and the arrangement direction of the pixels 3 are not limited to those in the first embodiment. For example, the pixel block 15 may be configured using four pixels 3 arranged two by two in each of the X direction and the Y direction as one unit.

An input stage of the pixel circuit 16 illustrated in FIG. 3 is electrically connected to the floating diffusion region FD of the pixel 3. Then, the pixel circuit 16 reads the signal charges held in the floating diffusion region FD of the pixel 3, and outputs a pixel signal based on the read signal charges. In other words, the pixel circuit 16 converts the signal charge photoelectrically converted by the photoelectric conversion unit 25 (photodiode PD) into a pixel signal based on the signal charge and outputs the pixel signal.

As illustrated in FIG. 3, the pixel circuit 16 includes, but is not limited to, an amplification transistor AMP, a selection transistor SEL, and a reset transistor RST as the pixel transistor Q, for example. That is, the pixel circuit 16 of the first embodiment has a three-transistor configuration.

The pixel transistor Q (AMP, RST, SEL) and the above-described transfer transistor TR are configured as insulated gate field effect transistors, for example, by MOSFETs (Metal Oxide Semiconductor Field Effect Transistor) whose gate insulating film is a silicon oxide (SiO₂) film. Furthermore, as the pixel transistor and the transfer transistor TR, a metal insulator semiconductor FET (MISFET) in which the gate insulating film includes a silicon nitride (Si₃N₄) film or a laminated film such as a silicon nitride film and a silicon oxide film may be used.

Among the pixel transistors Q (AMP, RST, SEL) included in the pixel circuit 16, the selection transistor SEL and the reset transistor RST mainly function as switching elements. Then, the remaining amplification transistor AMP mainly functions as an amplification element.

The amplification transistor AMP illustrated in FIG. 3 has a source region electrically connected to a drain region of the selection transistor SEL and a drain region electrically connected to a power supply line Vdd and a drain region of the reset transistor RST. Then, the gate electrode of the amplification transistor AMP is electrically connected to the floating diffusion region FD of the pixel 3 (photoelectric conversion region 22) and the source region of the reset transistor RST.

The selection transistor SEL illustrated in FIG. 3 has a source region electrically connected to the vertical signal line 11 (VSL) and a drain region electrically connected to the source region of the amplification transistor AMP. Then, a gate electrode of the selection transistor SEL is electrically connected to a selection transistor drive line among pixel drive lines 10 illustrated in FIG. 2.

In the reset transistor RST illustrated in FIG. 3, the source region is electrically connected to the gate electrode of the amplification transistor AMP and the floating diffusion region FD of the pixel 3, and the drain region is electrically connected to the power supply line Vdd and the drain region of the amplification transistor AMP. Then, a gate electrode of the reset transistor RST is electrically connected to a reset transistor drive line among the pixel drive lines 10 illustrated in FIG. 2.

Note that the selection transistor SEL may be omitted as necessary. In a case where the selection transistor SEL is omitted, the source region of the amplification transistor AMP is electrically connected to the vertical signal line 11 (VSL).

When the transfer transistor TR is turned on, the transfer transistor TR illustrated in FIG. 3 transfers the signal charge generated by the photoelectric conversion unit 25 (photodiode PD) to the floating diffusion region FD.

When the reset transistor RST is turned on, the reset transistor RST illustrated in FIG. 3 resets a potential (signal charge) of the floating diffusion region FD to a potential of the power supply line Vdd. The selection transistor SEL controls output timings of pixel signals from the pixel circuit 16.

The amplification transistor AMP illustrated in FIG. 3 generates a voltage signal corresponding to a level of the signal charge held in the floating diffusion region FD as the pixel signal. The amplification transistor AMP constitutes a source follower type amplifier, and outputs a pixel signal having a voltage corresponding to the level of the signal charge generated by the photoelectric conversion unit 25 (photodiode PD). When the selection transistor SEL is turned on, the amplification transistor AMP amplifies the potential of the floating diffusion region FD, and outputs a voltage corresponding to the potential to the column signal processing circuit 5 via the vertical signal line (VSL) 11.

During the operation of the solid-state imaging device 1A according to the first embodiment, the signal charge generated in the photoelectric conversion unit 25 of the pixel 3 is held (accumulated) in the floating diffusion region FD via the transfer transistor TR of the pixel 3. Then, the signal charge held in the floating diffusion region FD is then read out by the pixel circuit 16 and applied to the gate electrode of the amplification transistor AMP of the pixel circuit 16. A vertical shift register supplies a horizontal line selection control signal to the gate electrode of the selection transistor SEL of the pixel circuit 16. Then, setting the selection control signal to a high (H) level then brings the selection transistor SEL into conduction to allow a current corresponding to the potential of the floating diffusion region FD amplified by the amplification transistor AMP to flow to the vertical signal line 11. Furthermore, setting a reset control signal to be applied to the gate electrode of the reset transistor RST of the pixel circuit 16 to the high (H) level brings the reset transistor RST into conduction to reset the signal charge accumulated in the floating diffusion region FD.

Each of the photoelectric conversion unit 25, the transfer transistor TR, and the floating diffusion region FD illustrated in FIG. 3 is mounted on the semiconductor layer 21 (see FIG. 5A) to be described later. Furthermore, although not limited thereto, the pixel transistor Q (AMP, RST, SEL) included in the pixel circuit 16 in FIG. 3 is also mounted on the semiconductor layer 21, for example.

Note that, as will be described in detail later, in the first embodiment, two pixels 3 (3a, 3b) included in one pixel block 15 share one reset transistor RST. Furthermore, in the first embodiment, two pixel blocks 15 arranged in the X direction share one selection transistor SEL.

### Specific Configuration of Solid-State Imaging Device

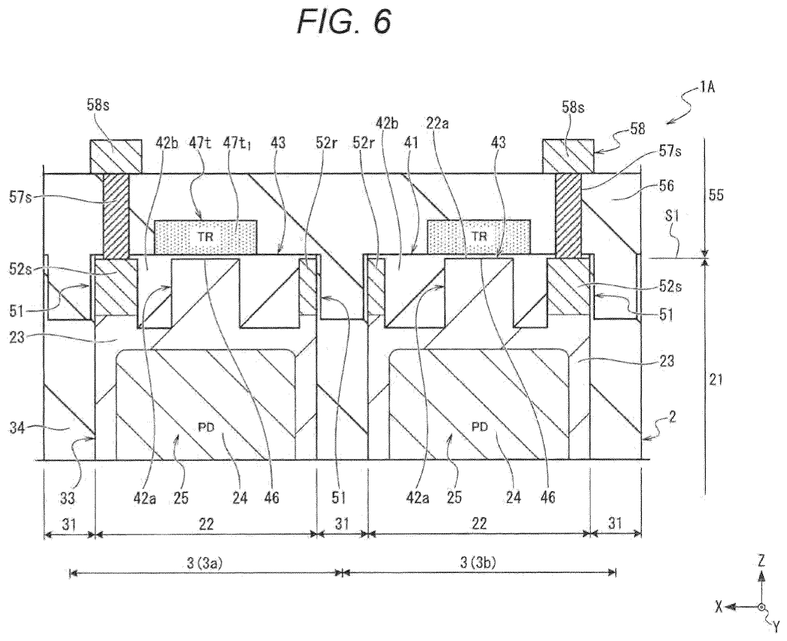

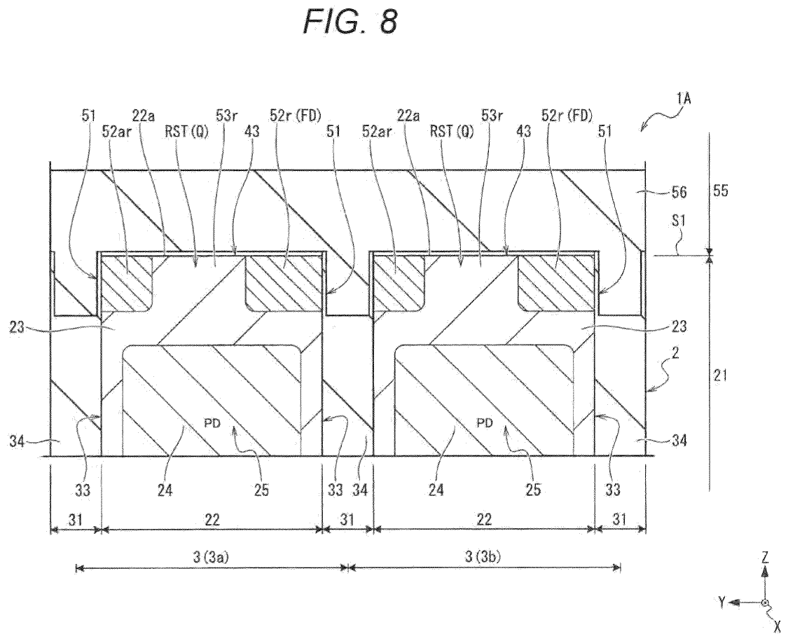

Next, a specific configuration of the semiconductor chip 2 (solid-state imaging device 1A) will be described with reference to FIGS. 4A to 8.

In FIG. 4A, illustration of a multilayer wiring layer 55 to be described later is omitted in order to facilitate viewing of the drawing, and illustration of an upper layer than a first wiring layer 57 included in the multilayer wiring layer 55 is omitted in FIG. 5A. Furthermore, FIG. 1 depicts the light incident surface side of the semiconductor chip 2, but FIG. 4A is a plan view of the semiconductor chip 2 as viewed from the side opposite to the light incident surface side (multilayer wiring layer side).

As illustrated in FIG. 5A, the semiconductor chip 2 includes the semiconductor layer 21 having a first surface portion S1 and a second surface portion S2 located on opposite sides in a thickness direction (Z direction), an inter-pixel isolation region 31 as an isolation region extending in the thickness direction (Z direction) of the semiconductor layer 21, and the photoelectric conversion region 22 partitioned by the inter-pixel isolation region 31 and provided in the semiconductor layer 21.

In addition, as illustrated in FIG. 5A, the semiconductor chip 2 further includes the multilayer wiring layer 55 provided on the first surface portion S1 side of the semiconductor layer 21.

In addition, the semiconductor chip 2 further includes a planarization film 61, an optical filter 63, and a microlens (on-chip lens) 64 sequentially provided on the second surface portion S2 side of the semiconductor layer 21 from the second surface portion S2 side.

Here, the first surface portion S1 of the semiconductor layer 21 will also be referred to as a main surface or an element formation surface, and the second surface portion S2 will also be referred to as a back surface. Then, in the solid-state imaging device 1A according to the first embodiment, incident light incident from the second surface portion S2 side of the semiconductor layer 21 is photoelectrically converted by the photoelectric conversion unit 25 (photodiode PD) provided in the photoelectric conversion region 22 of the semiconductor layer 21. In the first embodiment, therefore, the second surface portion S2 of the semiconductor layer 21 will also be referred to as a light incident surface.

Furthermore, in the first embodiment, the inter-pixel isolation region 31 corresponds to a specific example of the “isolation region” of the present technology.

As illustrated in FIG. 4A, two pixels 3 (3a, 3b) included in one pixel block 15 are adjacent to each other in the X direction in plan view. That is, in the pixel array unit 2A illustrated in FIG. 1, pixel blocks 15 each having two pixels 3 (3a, 3b) as one unit are repeatedly arranged in each of the X direction and the Y direction.

### Planarization Film, Optical Filter, and Microlens

The planarization film 61 illustrated in FIG. 5A is provided on the second surface portion S2 side of the semiconductor layer 21 so as to cover the second surface portion S2 of the semiconductor layer 21, and planarizes the second surface portion S2 side of the semiconductor layer 21.

The optical filter 63 and the microlens 64 illustrated in FIG. 5A are provided for each pixel 3. The optical filter 63 color-isolates incident light incident from the light incident surface side (second surface portion S2 side) of the semiconductor chip 2. The microlens 64 condenses the irradiation light and allows the condensed light to efficiently enter the pixel 3.

### Semiconductor Layer

As illustrated in FIG. 5A, the semiconductor layer 21 includes an inter-pixel isolation region 31 extending in the thickness direction (Z direction) of the semiconductor layer 21, and a photoelectric conversion region 22 partitioned by the inter-pixel isolation region 31. The photoelectric conversion region 22 is provided for each pixel 3. As the semiconductor layer 21, a Si substrate, a SiGe substrate, an InGaAs substrate, or the like may be used. In the first embodiment, although not limited to this, a p-type semiconductor substrate including, for example, single crystal silicon is used as the semiconductor layer 21.

### Isolation Region

### Planar Shape

As illustrated in FIG. 4A, the inter-pixel isolation region 31 includes first planar portions (planar extending portions) 31x extending in the X direction and second planar portions (planar extending portions) 31y extending in the Y direction in plan view. Then, the inter-pixel isolation region 31 further includes intersections (intersection points) where the first planar portion 31x and the second planar portion 31y intersect each other on the same plane. In the first embodiment, the first planar portion 31x and the second planar portion 31y are, for example, orthogonal to each other.

The first planar portions 31x are repeatedly arranged at predetermined intervals in the Y direction. Furthermore, the second planar portions 31y are repeatedly arranged at predetermined intervals in the X direction. That is, in the inter-pixel isolation region 31, a planar pattern in plan view is a lattice-shaped planar pattern.

As illustrated in FIG. 4A, the inter-pixel isolation region 31 corresponding to one photoelectric conversion region 22 is an annular planar pattern (ring-shaped planar pattern) having a square planar shape in plan view, and surrounds the periphery of one photoelectric conversion region 22. Then, the inter-pixel isolation region 31 corresponding to one pixel block 15 is a composite planar pattern including a square annular planar pattern surrounding the outer peripheries of the two pixels 3a and 3b and a planar pattern of the second planar portion 31y arranged between the two pixels 3a and 3b.

### Cross-Sectional Shape

As illustrated in FIG. 5A, the inter-pixel isolation region 31 extends in the thickness direction (Z direction) of the semiconductor layer 21, and electrically and optically isolates two photoelectric conversion regions 22 adjacent to each other in plan view. Then, the inter-pixel isolation region 31 is, for example, a dug type, a so-called trench type, in which a dug portion 33 is formed in the semiconductor layer 21 to partition and isolate the photoelectric conversion region 22.

The inter-pixel isolation region 31 includes, but is not limited to, for example, the dug portion 33 extending over the first surface portion S1 and the second surface portion S2 of the semiconductor layer 21, and an isolation insulating film 34 provided in the dug portion 33. That is, the inter-pixel isolation region 31 extends over the first surface portion S1 and the second surface portion S2 of the semiconductor layer 21. As the isolation insulating film 34, for example, a silicon oxide film may be used. In the first embodiment, the dug portion 33 is embedded in, for example, the isolation insulating film 34.

### Photoelectric Conversion Region

As illustrated in FIGS. 4A and 4B, the photoelectric conversion region 22 is surrounded by the inter-pixel isolation region 31 in plan view, and has a square planar shape. Specifically, the photoelectric conversion region 22 is surrounded by two first planar portions 31x extending in the X direction and separated in the Y direction and two second planar portions 31y extending in the Y direction and separated in the X direction in the inter-pixel isolation region 31. Then, the photoelectric conversion region 22 is partitioned by the first planar portion 31x and the second planar portion 31y, and is isolated from the other photoelectric conversion regions 22.

As illustrated in FIGS. 5A and 5B, the photoelectric conversion region 22 includes an upper surface portion 22a located on the first surface portion S1 side of the semiconductor layer 21 and a first side surface portion (outer wall surface portion) 22b located on the inter-pixel isolation region 31 side.

Furthermore, the photoelectric conversion region 22 further includes the photoelectric conversion unit 25, the floating diffusion region FD, and the transfer transistor TR described above.

Furthermore, as illustrated in FIGS. 4A to 5B, the photoelectric conversion region 22 further includes an inter-element isolation region (field isolation region) 41 provided on the upper surface portion 22a side, and an island-shaped element formation region (active region) 43 partitioned by the inter-element isolation region 41 and the inter-pixel isolation region 31 and provided on the upper surface portion 22a side (the first surface portion S1 side of the semiconductor layer 21).

Furthermore, the photoelectric conversion region 22 further includes an amplification transistor AMP, a selection transistor SEL, and a reset transistor RST as the pixel transistor Q included in the pixel circuit 16 described above.

In addition, the photoelectric conversion region 22 further includes a second side surface portion 22c located on the opposite side to the first side surface portion 22b in plan view and adjacent to the inter-element isolation region 41.

Furthermore, the photoelectric conversion region 22 further includes a p-type semiconductor region (well region) 23, an n-type semiconductor region 24, and a p-type power supply contact region WC (see FIG. 4B).

### p-Type Semiconductor Region and n-Type Semiconductor Region

As illustrated in FIGS. 5A and 5B, the p-type semiconductor region 23 is provided over a wide range over the first surface portion S1 side and the second surface portion S2 side of the semiconductor layer 21 in the photoelectric conversion region 22. Then, the p-type semiconductor region 23 is in contact with the inter-pixel isolation region 31 along the depth direction (Z direction) of the semiconductor layer 21.

As illustrated in FIGS. 5A and 5B, the n-type semiconductor region 24 is provided in the p-type semiconductor region 23 in the photoelectric conversion region 22. That is, in the n-type semiconductor region 24, six surfaces including an upper surface portion, a lower surface portion, and four side surface portions are surrounded by the p-type semiconductor region 23. Then, the n-type semiconductor region 24 is separated from the first surface portion S1 and the second surface portion S2 of the semiconductor layer 21 and the inter-pixel isolation region 31.

### Photoelectric Conversion Unit

The photoelectric conversion unit 25 illustrated in FIGS. 5A and 5B includes the p-type semiconductor region 23 and the n-type semiconductor region 24 in the photoelectric conversion region 22. Then, the photoelectric conversion unit 25 is configured as a pn junction type photodiode (PD) including a pn junction between the p-type semiconductor region 23 and the n-type semiconductor region 24.

The photoelectric conversion unit 25 photoelectrically converts light incident on the n-type semiconductor region 24 from the second surface portion S2 side of the semiconductor layer 21 into signal charges in the n-type semiconductor region 24, and temporarily holds (accumulates) the photoelectrically converted signal charges in the pn junction between the p-type semiconductor region 23 and the n-type semiconductor region 24.

### Floating Diffusion Region

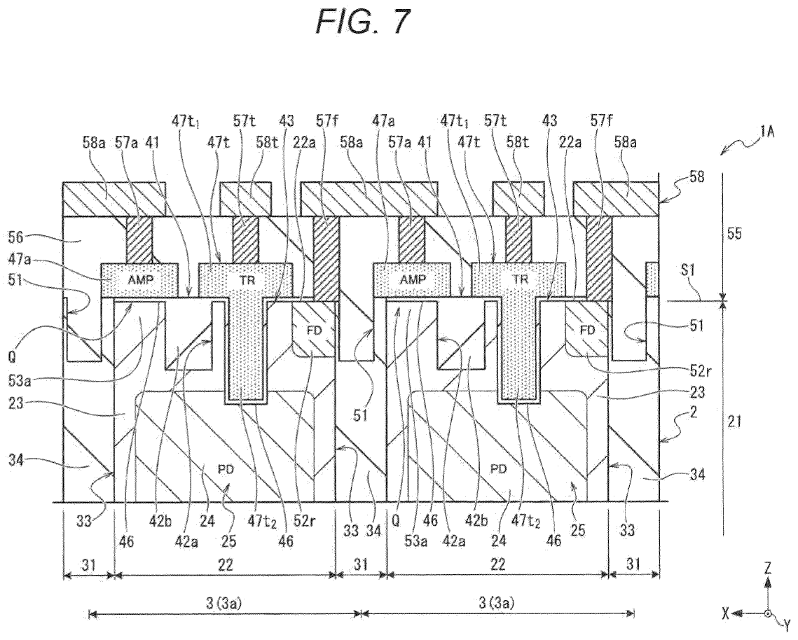

As illustrated in FIG. 7, the floating diffusion region FD is provided in the p-type semiconductor region 23 on the first surface portion S1 side of the semiconductor layer 21 (the upper surface portion 22a side of the photoelectric conversion region 22). Then, the floating diffusion region FD overlaps the n-type semiconductor region 24 in plan view, and is separated from the n-type semiconductor region 24 in the thickness direction (Z direction) of the semiconductor layer 21. That is, the p-type semiconductor region 23 is provided between the floating diffusion region FD and the n-type semiconductor region 24. The floating diffusion region FD is shared with a main electrode region 52r of the reset transistor RST to be described later, and includes an n-type semiconductor region.

### Inter-Element Isolation Region and Element Formation Region

As illustrated in FIGS. 5A to 7, the inter-element isolation region 41 is provided in a surface layer portion of the photoelectric conversion region 22 on the upper surface portion 22a side, that is, a surface layer portion of the semiconductor layer 21 on the first surface portion S1 side. The inter-element isolation region 41 has, but is not limited to, a shallow trench isolation (STI) structure in which an isolation insulating film 42b is embedded in a shallow groove portion 42a recessed from the first surface portion S1 toward the second surface portion S2 of the semiconductor layer 21, for example.

As illustrated in FIG. 4B, the inter-element isolation region 41 is an island-shaped planar pattern separated from the inter-pixel isolation region 31 except for a part in plan view, and partitions the element formation region 43 together with the inter-pixel isolation region 31.

As illustrated in FIGS. 5A to 7, the element formation region 43 is provided in a surface layer portion of the photoelectric conversion region 22 on the upper surface portion 22a side, that is, in a surface layer portion of the semiconductor layer 21 on the first surface portion S1 side. Then, as illustrated in FIG. 4B, the element formation region 43 is partitioned by the inter-element isolation region 41 and the inter-pixel isolation region 31, and is a planar pattern extending in a ribbon shape along four sides of the photoelectric conversion region 22 in plan view.

The planar pattern of the element formation region 43 is different between the two pixels 3a and 3b included in the pixel block 15. That is, as illustrated in FIG. 4B, in the two pixels 3a and 3b included in the pixel block 15, the planar pattern of the element formation region 43 in one pixel 3a and the planar pattern of the element formation region 43 in the other pixel 3b are inverted about the boundary between the pixels 3a and 3b arranged in the X direction.

### p-Type Power Supply Contact Region

As illustrated in FIG. 4B, the p-type power supply contact region WC is provided on a corner side sandwiched between two sides of the photoelectric conversion region 22 in plan view. Although not illustrated in detail, the p-type power supply contact region WC is provided in the surface layer portion of the photoelectric conversion region 22 on the upper surface portion 22a side, that is, the surface layer portion of the semiconductor layer 21 on the first surface portion S1 side. Then, the p-type power supply contact region WC is provided in an island-shaped power supply region partitioned by the inter-element isolation region 41 and the inter-pixel isolation region 31 on the upper surface portion 22a side of the photoelectric conversion region 22. The p-type power supply contact region WC includes a p-type semiconductor region having a higher impurity concentration than the p-type semiconductor region 23. Then, the p-type power supply contact region WC is connected to the p-type semiconductor region 23 and electrically conducted.

A first reference potential of, for example, 0 V is applied to the p-type power supply contact region WC as a reference potential in the semiconductor chip 2 (in the solid-state imaging device 1A) during operation, and the potential is fixed to the first reference potential.

### Transfer Transistor

As illustrated in FIGS. 4B and 5B, the transfer transistor TR is provided on the first surface portion S1 side of the semiconductor layer 21, that is, on the upper surface portion 22a side of the photoelectric conversion region 22. The transfer transistor TR includes a gate electrode 47t provided over the inside and outside of the photoelectric conversion region 22 on the upper surface portion 22a side of the photoelectric conversion region 22, and a gate insulating film 46 provided between the gate electrode 47t and the semiconductor layer 21. Furthermore, the transfer transistor TR further includes an n-type semiconductor region 24 functioning as a source region, an n-type floating diffusion region FD functioning as a drain region, and a p-type semiconductor region 23 functioning as a channel formation portion. The transfer transistor TR is not limited thereto, but is configured as, for example, a vertical type.

As illustrated in FIG. 5B, the gate electrode 47t of the transfer transistor TR includes a head portion 47t₁ provided outside the first surface portion S1 of the semiconductor layer 21 with the gate insulating film 46 interposed therebetween, and a leg portion 47r₂ protruding from the head portion 47t₁ into the semiconductor layer 21 and adjacent to the semiconductor layer 21 with the gate insulating film 46 interposed therebetween. The gate electrode 47t of the first embodiment is not limited thereto, but is formed in, for example, a T-shaped longitudinal sectional shape in which the width of the leg portion 47t₂ is narrower than the width of the head portion 47t₁.

The leg portion 47t₂ of the gate electrode 47t is provided in the dug portion 45a of the semiconductor layer 21 with the gate insulating film 46 interposed therebetween, and enters the inside of the n-type semiconductor region 24 in a state where the tip is insulated and isolated.

### Pixel Transistors

As illustrated in FIGS. 4B and 5B, the element formation region 43 is provided with a plurality of pixel transistors Q (AMP, SEL, RST) included in the pixel circuit 16. Then, at least one pixel transistor Q of the plurality of pixel transistors Q has a gate electrode provided in the inter-pixel isolation region 31. In the first embodiment, among the three pixel transistors Q (AMP, SEL, RST), gate electrodes 47s and 47r of the selection transistor SEL and the reset transistor RST are provided in the inter-pixel isolation region 31.

### Amplification Transistor

As illustrated in FIGS. 4B and 7, the amplification transistor AMP includes a gate electrode 47a provided on the upper surface portion 22a side of the photoelectric conversion region 22 (the first surface portion S1 side of the semiconductor layer 21) so as to overlap the element formation region 43 (semiconductor layer 21) in plan view, and a gate insulating film 46 interposed between the gate electrode 47a and the element formation region 43. Further, the amplification transistor AMP further includes a pair of main electrode regions 52as and 52ar provided in the element formation regions 43 on both sides of the gate electrode 47a in the gate length direction and functioning as a source region and a drain region. Further, the amplification transistor AMP further includes a channel formation portion 53a (see FIG. 7) provided in the element formation region 43 overlapping the gate electrode 47a in plan view. The pair of main electrode regions 52as and 52ar is separated from each other via the channel formation portion 53a. The pair of main electrode regions 52as and 52ar includes an n-type semiconductor region provided in the element formation region 43, and the channel formation portion 53a includes a p-type semiconductor region 23 provided in the element formation region 43.

### Reset Transistor RST

As illustrated in FIGS. 4B, 5B, 6, and 8, the reset transistor RST is provided on the inter-pixel isolation region 31 side between the two photoelectric conversion regions 22 included in the pixel block 15. Then, the reset transistor RST includes a gate electrode 47r provided in the inter-pixel isolation region 31 adjacent to the first side surface portion 22b of the photoelectric conversion region 22 with the gate insulating film 46 interposed therebetween, and a pair of main electrode regions 52r and 52ar provided on the upper surface portion 22a side of the photoelectric conversion region 22 to be separated from each other in the gate length direction of the gate electrode 47r in plan view and functioning as a source region and a drain region. Further, the reset transistor RST further includes a channel formation portion 53r provided in the element formation region 43 (semiconductor layer 21) adjacent to the gate electrode 47r in plan view. The pair of main electrode regions 52r and 52ar includes an n-type semiconductor region, and the channel formation portion 53r includes a p-type semiconductor region 23.

The gate electrode 47r of the reset transistor RST is not limited to the first embodiment, but is selectively provided in the inter-pixel isolation region 31 and embedded in the inter-pixel isolation region 31, for example.

As illustrated in FIGS. 4B and 5B, the reset transistor RST and the amplification transistor AMP are provided in the element formation region 43 such that the main electrode region 52as of the reset transistor RST and the main electrode region 52as of the amplification transistor AMP are shared and connected in series. Then, as illustrated in FIGS. 4B, 5B, and 8, in the reset transistor RST, one main electrode region 52r of the pair of main electrode regions 52r and 52ar is shared with the floating diffusion region FD.

As illustrated in FIGS. 4B and 5B, the reset transistor RST is shared by two pixels 3a and 3b (two photoelectric conversion regions 22) included in the pixel block 15. Then, in the reset transistor RST, the gate electrode 47r is adjacent to the first side surface portion 22b of each of the two photoelectric conversion regions 22 adjacent to each other in plan view with the gate insulating film 46 interposed therebetween. That is, the reset transistor RST of the first embodiment includes the gate electrode 47r provided in the inter-pixel isolation region 31 between the two photoelectric conversion regions 22 adjacent to each other in plan view, and the pair of main electrode regions 52r and 52ar and the channel formation portion 53r provided in each of the two photoelectric conversion regions 22 adjacent to each other in plan view.

### Selection Transistor SEL

As illustrated in FIGS. 4B, 5B, and 8, the selection transistor SEL is provided on the side of the photoelectric conversion region 22 opposite to the reset transistor TST side in plan view. Then, the selection transistor SEL includes a gate electrode 47s provided in the inter-pixel isolation region 31 so as to be adjacent to the first side surface portion 22b of the photoelectric conversion region 22 with the gate insulating film 46 interposed therebetween, and a pair of main electrode regions 52s and 52as provided on the upper surface portion 22a side of the photoelectric conversion region 22 so as to be separated from each other in the gate length direction of the gate electrode 47s in plan view and functioning as a source region and a drain region. In addition, the selection transistor SEL further includes a channel formation portion 53s provided in the element formation region 43 (semiconductor layer 21) adjacent to the gate electrode 47s in plan view. The pair of main electrode regions 52s and 52as includes an n-type semiconductor region, and the channel formation portion 53s includes a p-type semiconductor region 23.

The gate electrode 47s of the selection transistor SEL is not limited to the first embodiment, but is selectively provided in the inter-pixel isolation region 31 and embedded in the inter-pixel isolation region 31, for example.

As illustrated in FIGS. 4B and 5B, the selection transistor SEL and the amplification transistor AMP are provided in the element formation region 43 such that the main electrode region 52as of the selection transistor SEL and the main electrode region 52as of the amplification transistor AMP are shared and connected in series.

As illustrated in FIGS. 4B and 5B, in two pixel blocks 15 arranged in the X direction, the selection transistor SEL is shared by the pixel 3a of one pixel block 15 and the pixel 3b of the other pixel block 15. In other words, in the two pixel blocks 15 arranged in the X direction, the selection transistor SEL is shared by a pixel circuit 16a allocated to the pixel 3a of one pixel block 15 and a pixel circuit 16b allocated to the pixel 3b of the other pixel block 15.

Then, in the selection transistor SEL, the gate electrode 47s is adjacent to the first side surface portion 22b of each of the two photoelectric conversion regions 22 adjacent to each other in plan view with the gate insulating film 46 interposed therebetween. That is, the selection transistor SEL of the first embodiment includes the gate electrode 47s provided in the inter-pixel isolation region 31 between the two photoelectric conversion regions 22 adjacent to each other in plan view, and the pair of main electrode regions 52s and 52as and the channel formation portion 53s provided in each of the two photoelectric conversion regions 22 adjacent to each other in plan view.

### Channel Formation Portion

As illustrated in FIGS. 4B and 5B, each of the channel formation portions 53r and 53s of the reset transistor RST and the selection transistor SEL includes the semiconductor layer 21 between the first side surface portion 22b and the second side surface portion 22c of the photoelectric conversion region 22. That is, each of the reset transistor TRS and the selection transistor SEL includes the channel formation portions 53r and 53s between the first side surface portion 22b and the second side surface portion 22c of the photoelectric conversion region 22. In other words, in each of the reset transistor RST and the selection transistor SEL, the channel formation portions 53r and 53s are provided in the semiconductor layer 21 between the inter-pixel isolation region 31 and the inter-element isolation region 41. The thicknesses of the channel formation portions 53r and 53s in plan view can be reduced by reducing the separation distance between the inter-pixel isolation region 31 and the inter-element isolation region 41. The thicknesses of the channel formation portions 53r and 53s are preferably smaller than 100 nm.

### Material of Gate Electrode

Each of the gate electrodes 47a, 47s, 47r, and 47t of the amplification transistor AMP, the selection transistor SEL, the reset transistor RST, and the transfer transistor TR includes, for example, a polycrystalline silicon film (doped polysilicon film) into which an impurity for reducing the resistance value is introduced.

### Enhancement Type

Each of the reset transistor RST and the selection transistor SEL can be configured as, for example, an enhancement type (normally off type) in which a drain current flows by applying a gate voltage equal to or higher than a threshold voltage to the gate electrodes 47r and 47s. Furthermore, each of the reset transistor RST and the selection transistor SEL can be configured as, for example, a depression type (normally on type) in which a drain current flows without applying a voltage to the gate electrodes 47r and 47s. In the first embodiment, each of the reset transistor RST and the selection transistor SEL is of, but not limited to, an enhancement type. In the case of the enhancement type, in each of the reset transistor RST and the selection transistor SEL, a channel (inversion layer) electrically connecting the pair of main electrode regions 52r (52s) and 52ar (52as) is formed (induced) in the channel formation portions 53r and 53s by a voltage applied to the gate electrodes 47r and 47s, and a current (drain current) flows from the drain region side (for example, the main electrode region 52r, 52s side) to the source region side (for example, the main electrode region 52ar, 52as side) through the channel of the channel formation portions 53r and 53s.

Note that the amplification transistor AMP is also of an enhancement type, for example, similarly to each of the reset transistor RST and the selection transistor SEL.

### Multilayer Wiring Layer

As illustrated in FIGS. 5A to 7, the multilayer wiring layer 55 is provided on the first surface portion S1 side of the semiconductor layer 21. Then, the multilayer wiring layer 55 includes an interlayer insulating film 56 provided on the first surface portion S1 side of the semiconductor layer 21 so as to cover the inter-element isolation region 41 and the element formation region 43, contact electrodes 57a, 57f, 57r, 57s, and 57t provided in the film of the interlayer insulating film 56, and a first wiring layer 58 provided on the side of the interlayer insulating film 56 opposite to the semiconductor layer 21 side. The first wiring layer 58 includes wirings 58a, 58r, 58s, and 58t. As a material of the contact electrodes 57a, 57f, 57r, 57s, and 57t, for example, tungsten (W) of a high melting point metal can be used. As a material of the first wiring layer 58, for example, a metal material such as aluminum (Al) or copper (Cu), an alloy material mainly containing Al or Cu, or the like can be used. As the interlayer insulating film 56, for example, a silicon oxide film can be used. The gate electrode 47t of the transfer transistor TR and the gate electrode (47a, 47s, 47r) of each of the plurality of pixel transistors Q (AMP, SEL, RST) are covered with the interlayer insulating film 56.

### Contact Electrode and Wiring

As illustrated in FIGS. 5B and 7, the gate electrode 47t of the transfer transistor TR is electrically connected to the wiring 58t provided in the wiring layer 58 on the interlayer insulating film 56 via the contact electrode 57t provided in the interlayer insulating film 56.

As illustrated in FIG. 5B, the gate electrode 47r of the reset transistor RST is electrically connected to the wiring 58r provided in the wiring layer 58 on the interlayer insulating film 56 via the contact electrode 57r provided in the interlayer insulating film 56.

As illustrated in FIG. 5B, the gate electrode 47s of the selection transistor SEL is electrically connected to the wiring 58s provided in the wiring layer 58 on the interlayer insulating film 56 via the contact electrode 57s provided in the interlayer insulating film 56.

As illustrated in FIG. 7, in the two pixels 3a and 3a arranged in the Y direction, the gate electrode 47a of the amplification transistor AMP provided in the photoelectric conversion region 22 of one pixel 3a is electrically connected to the wiring 58a provided in the wiring layer 58 on the interlayer insulating film 56 via the contact electrode 57a provided in the interlayer insulating film 56. Then, the wiring 58a is electrically connected to the floating diffusion region FD (main electrode region 52r) provided in the photoelectric conversion region 22 of the other pixel 3a via the contact electrode 57f provided in the interlayer insulating film 56. That is, in the two pixels 3a and 3a arranged in the Y direction, the gate electrode 47a of the amplification transistor AMP provided in one photoelectric conversion region 3a and the floating diffusion region FD (main electrode region 52r) provided in the other photoelectric conversion region 22 are electrically connected via the contact electrode 57a, the wiring 58a, and the contact electrode 57f.

### Method for Manufacturing Solid-State Imaging Device

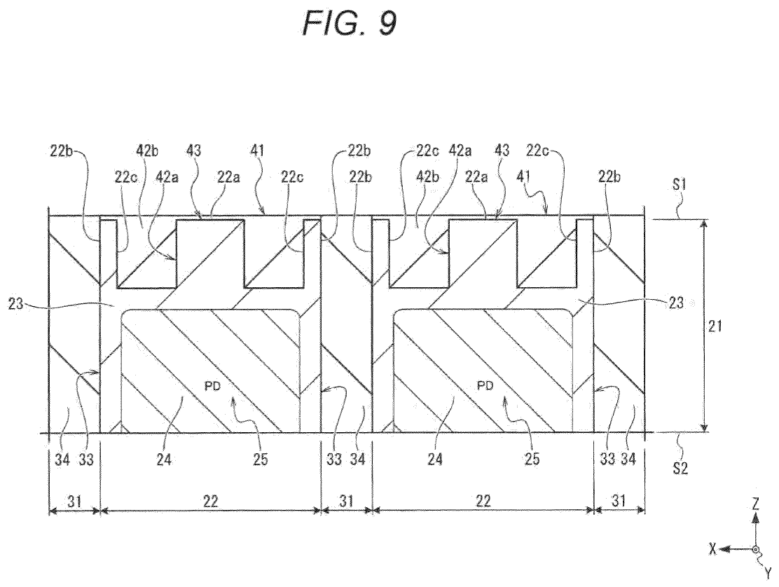

Next, a method for manufacturing the solid-state imaging device 1A according to the first embodiment of the present technology will be described with reference to FIGS. 9 to 19.

In the first embodiment, manufacturing of a pixel transistor included in a method for manufacturing the solid-state imaging device 1A will be specifically described.

Furthermore, FIGS. 9 to 13, 16, 17A, and 18A are longitudinal sectional views schematically illustrating a part of the longitudinal sectional structure taken along line a4-a4 in FIG. 4A.

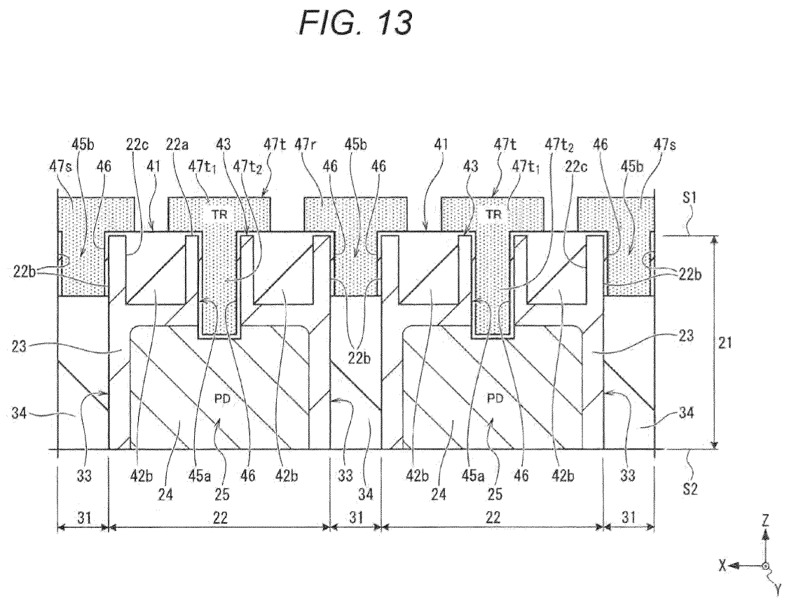

Furthermore, FIGS. 14, 15, 17B, and 18B are longitudinal sectional views schematically illustrating a part of the longitudinal sectional structure taken along line b4-b4 in FIG. 4A.

First, as illustrated in FIG. 9, the photoelectric conversion region 22 partitioned by the inter-pixel isolation region 31 is formed in the semiconductor layer 21, and the element formation region 43 partitioned by the inter-element isolation region 41 is formed on the upper surface portion 22a side of the photoelectric conversion region 22, which is the first surface portion S1 side of the semiconductor layer 21.

The photoelectric conversion region 22 includes the upper surface portion 22a located on the first surface portion S1 side of the semiconductor layer 21, the first side surface portion 22b located on the inter-pixel isolation region 31 side, and the second side surface portion 22c located on the opposite side to the first side surface portion 22b in plan view and adjacent to the inter-element isolation region 41.

The inter-pixel isolation region 31 can be formed by forming the dug portion 33 extending in the thickness direction (Z direction) of the semiconductor layer 21 in the semiconductor layer 21, and then selectively embedding the dug portion 33 with the isolation insulating film 34. The inter-element isolation region 41 can be formed by forming the shallow groove portion 42a on the first surface portion S1 side of the semiconductor layer 21 and then selectively embedding the shallow groove portion 42a with the isolation insulating film 42b. Then, by forming the inter-pixel isolation region 31 and the inter-element isolation region 41, the photoelectric conversion region 22 partitioned by the inter-pixel isolation region 31 and the inter-element isolation region 41 and including the upper surface portion 22a, the first side surface portion 22b, and the second side surface portion 22c is formed.

Next, as illustrated in FIG. 10, the dug portion 45a and a dug portion 45b extending in the thickness direction (Z direction) of the semiconductor layer 21 are formed. The dug portion 45a is for forming the gate electrode 47t of the transfer transistor TR, and is formed in the central portion of the photoelectric conversion region 22 to be separated from the inter-pixel isolation region 31 in plan view. The dug portion 45b is for forming a gate electrode of the pixel transistor Q, and is formed in the inter-pixel isolation region 31. In the first embodiment, the dug portion 45b is formed in each of the first gate electrode formation portion where the gate electrode 47r of the reset transistor RST is formed and the second gate electrode formation portion where the gate electrode 47s of the selection transistor SEL is formed in the inter-pixel isolation region 31.

The dug portion 45a can be formed by selectively etching the semiconductor layer 21 using a known photolithography technique and an anisotropic dry etching technique. The dug portion 45b can be formed by selectively etching the pixel application isolation region 31 using a known photolithography technique and an anisotropic dry etching technique. The dug portion 45a and the dug portion 45b are basically formed in separate steps, but may be formed in any order first.

In this step, the dug portion 45a is formed such that the semiconductor layer 21 is exposed from the inner wall surface portion including the side wall surface portion and the bottom wall surface portion of the dug portion 45a.

Furthermore, in this step, the dug portion 45b is formed such that the first side surface portion 22b of the photoelectric conversion region 22 is exposed from the side wall surface portion of the dug portion 45b.

Furthermore, in this step, since the depth of the dug portion 45a defines the length of a leg portion 42t2 of the gate electrode 42t in the transfer transistor TR, the dug portion 45a is preferably formed at a depth at which the tip enters the inside of the n-type semiconductor region 24.

Furthermore, in this step, since the depth of the dug portion 45b defines the gate widths of the gate electrodes 42r and 42s of the reset transistor RST and the selection transistor SEL, the dug portion 45b is preferably formed at a depth of about 0.1 μm to 1 μm.

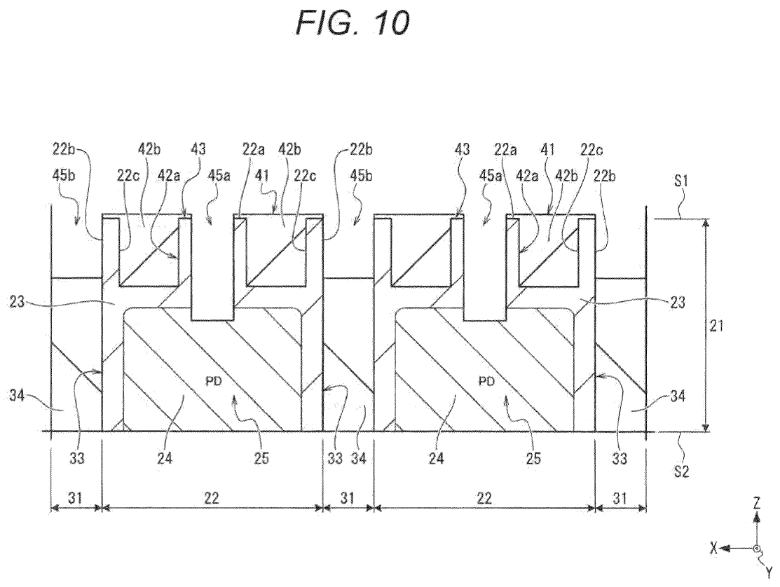

Next, after a natural oxide film and an excessive insulating film on the first surface portion S1 side of the semiconductor layer 21 and on the upper surface portion 22a side of the photoelectric conversion region 22 are removed by, for example, wet etching to expose the first surface portion S1 of the semiconductor layer 21 (the upper surface portion 22a of the photoelectric conversion region 22), the gate insulating film 46 is formed as illustrated in FIG. 11. The gate insulating film 46 is formed on the upper surface portion 22a of the photoelectric conversion region 22 and the inner wall surface portion of the dug portion 45a, and is formed on the first side surface portion 22b of the photoelectric conversion region 22 exposed inside the dug portion 45b.

As the gate insulating film 46, for example, a silicon oxide film can be used. The silicon oxide film can be formed by a thermal oxidation method or a deposition method, but in the first embodiment, a silicon oxide film by a thermal oxidation method is formed as the gate insulating film 46. The thermal oxidation method can form a silicon oxide film having better film quality than the deposition method.

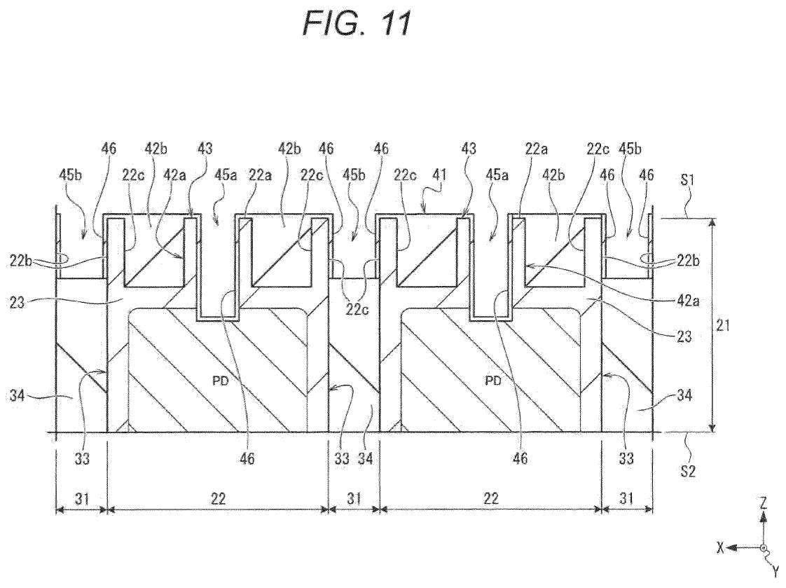

Next, as illustrated in FIG. 12, the gate electrode film 47 is formed. The gate electrode film 47 is formed on the first surface portion S1 side of the semiconductor layer 21 so as to embed into the interior of each of the dug portions 45a and 45b. As the gate electrode film 47, a polycrystalline silicon film that can be formed by a CVD method can be used.

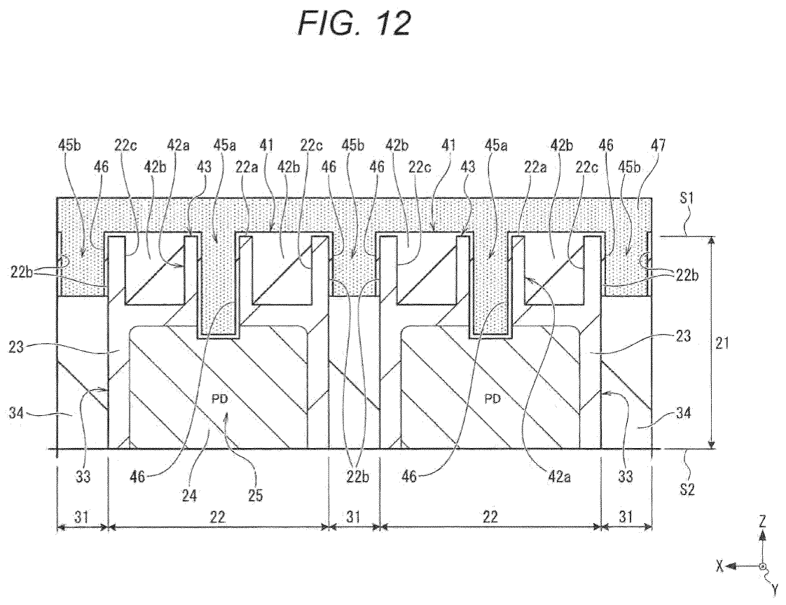

Next, the gate electrode film 47 is patterned to form each of the gate electrode 47t, the gate electrode 47r, and the gate electrode 47s as illustrated in FIG. 13, and form the gate electrode 47a (see FIG. 4B) although not illustrated.

In this step, the gate electrode 47t is formed in a T-shaped longitudinal sectional shape including the head portion 47t₁ provided outside the first surface portion S1 of the semiconductor layer 21 (outside the upper surface portion 22a of the photoelectric conversion region 22) with the gate insulating film 46 interposed therebetween, and the leg portion 47t₂ protruding from the head portion 47a₁ into the dug portion 45a of the semiconductor layer 21 and adjacent to the semiconductor layer 21 with the gate insulating film 46 interposed therebetween.

Furthermore, in this step, each of the gate electrodes 47r and 47s is formed in a T-shaped longitudinal sectional shape including head portions 47r₁ and 47s₁ provided outside the first surface portion S1 of the semiconductor layer 21 (outside the upper surface portion 22a of the photoelectric conversion region 22) with the gate insulating film 46 interposed therebetween, and leg portions 47r₂ and 47s₂ protruding from the head portions 47r₁ and 47s₁ into the dug portion 45b of the semiconductor layer 21 and provided in the inter-pixel isolation region 31 adjacent to each other with the first side surface portion 22b of the photoelectric conversion region 22 and the gate insulating film 46 interposed therebetween.

Furthermore, in this step, the gate electrode 47a is formed on the element formation region 43 with the gate insulating film 46 interposed therebetween.

Next, as illustrated in FIG. 14, a dug portion 51 is formed in the inter-pixel isolation region 31. Although not illustrated in detail, the dug portion 51 is formed along the periphery of the photoelectric conversion region 22 except for the regions of the gate electrodes 47r and 47s in plan view.

In this step, since the depth of the dug portion 51 defines the depth of the pair of main electrode regions of the pixel transistor Q (AMP, SEL, RST), it is preferable to form the dug portion 51 at a depth of about 0.1 μm to 1 μm.

Furthermore, in this step, the dug portion 51 is preferably formed such that the isolation insulating film 34 remains with a thin film thickness on the first side surface portion 22b of the photoelectric conversion region 22, in other words, the first side surface portion 22b of the photoelectric conversion region 22 is covered with the isolation insulating film 34 with a thin film thickness.

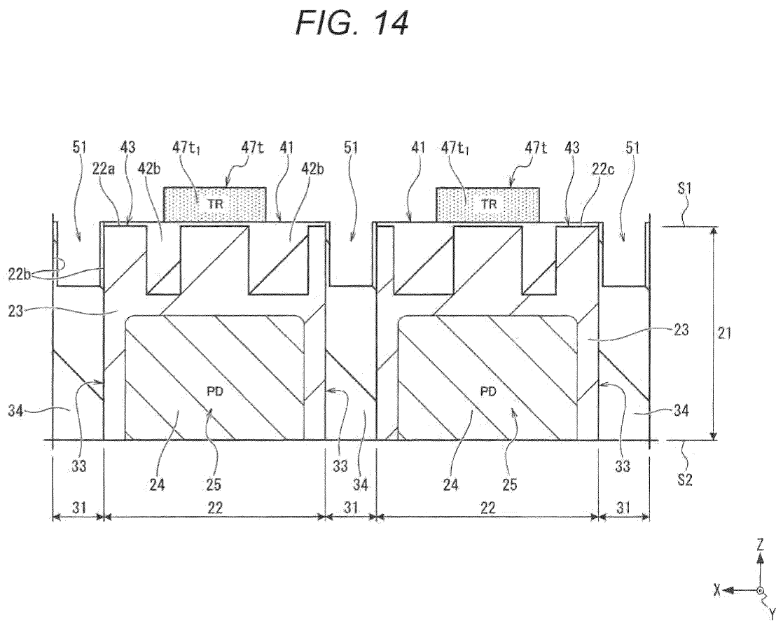

Next, referring to FIGS. 15 and 4B, as illustrated in FIGS. 15 and 4B, main electrode regions 52as, 52ar, 52r, and 52s each including an n-type semiconductor region are formed in the element formation region 43 of the photoelectric conversion region 22.

Specifically, each of the main electrode regions 52as, 52ar, 52r, and 52s is formed by implanting impurity ions into the element formation region 43 from the upper surface portion 22a side of the photoelectric conversion region 22 illustrated in FIG. 15 and from the first side surface portion 22b side of the photoelectric conversion region 22 through the dug portion 51 illustrated in FIG. 15, and then performing heat treatment for activating the implanted impurity ions. Impurity ions are implanted using the inter-pixel isolation region 31, the inter-element isolation region 41, and the gate electrodes 47a, 47r, and 47s as masks. Furthermore, impurity ions are implanted in a state where the implantation direction is inclined with respect to the upper surface portion 22a and the first side surface portion 22b of the photoelectric conversion region 22. As the impurity ions, for example, phosphorus (P⁺) or arsenic (As⁺) can be used.

By this step, referring to FIGS. 4B and 7, the channel formation portion 53a is formed in the semiconductor layer 21 between the main electrode regions 52as and 52ar and overlapping the gate electrode 47a in plan view. Then, the amplification transistor AMP including the gate insulating film 46, the gate electrode 47a, the pair of main electrode regions 52as and 52ar, and the channel formation portion 53a is formed.

Furthermore, by this step, as will be described with reference to FIGS. 4B, 5B, and 8, the channel formation portion 53r adjacent to the gate electrode 47r with the gate insulating film 46 interposed therebetween is formed in the semiconductor layer 21 between the main electrode regions 52r and 52ar and between the first side surface portion 22b and the second side surface portion 22c of the photoelectric conversion region 22. Then, the reset transistor RST including the gate insulating film 46, the gate electrode 47r, the pair of main electrode regions 52r and 52ar, and the channel formation portion 53r is formed.

Furthermore, according to this step, as will be described with reference to FIGS. 4B and 5B, the channel formation portion 53r adjacent to the gate electrode 47r with the gate insulating film 46 interposed therebetween is formed in the semiconductor layer 21 between the main electrode regions 52s and 52as and between the first side surface portion 22b and the second side surface portion 22c of the photoelectric conversion region 22. Then, the reset transistor RST including the gate insulating film 46, the gate electrode 47r, the pair of main electrode regions 52r and 52ar, and the channel formation portion 53r is formed.

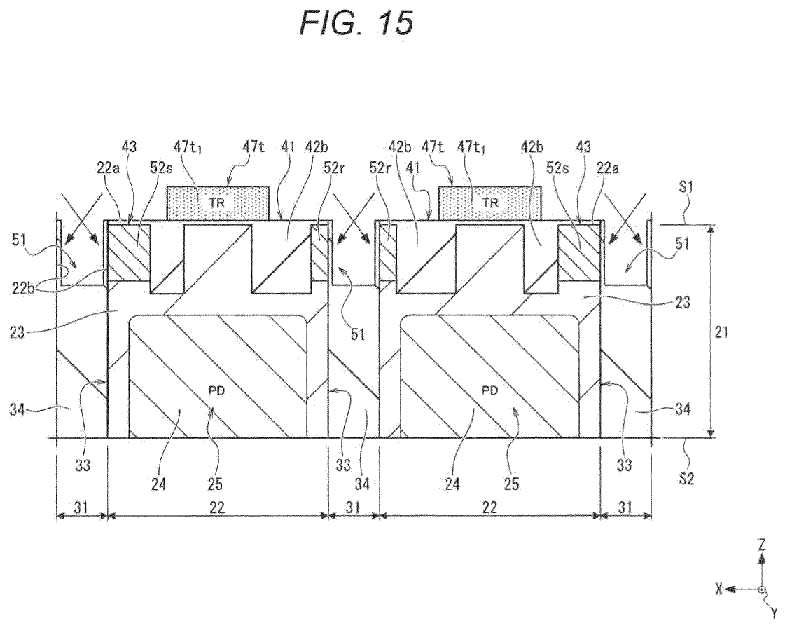

Next, the head portions 47r₁ and 47s₁ of the gate electrodes 47r and 47s are selectively removed to form the gate electrodes 47r and 47s embedded in the inter-pixel isolation region 31 as illustrated in FIG. 16.

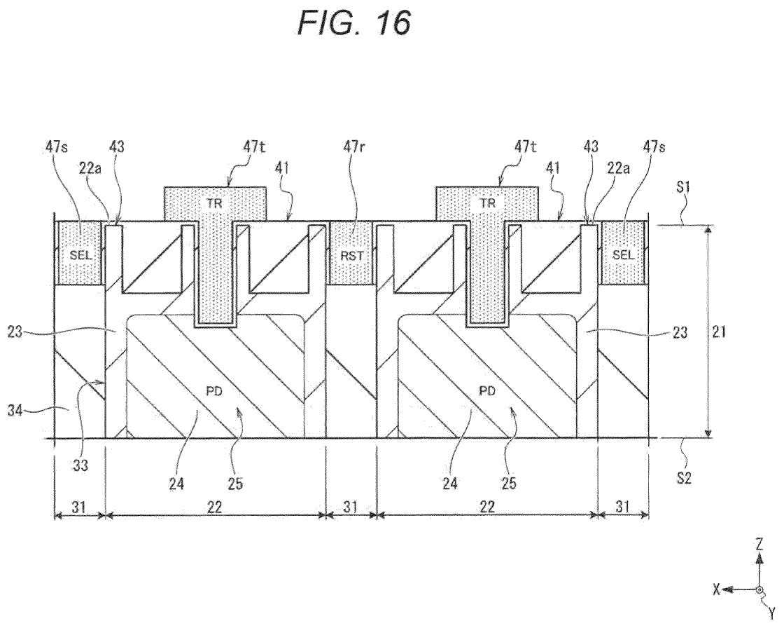

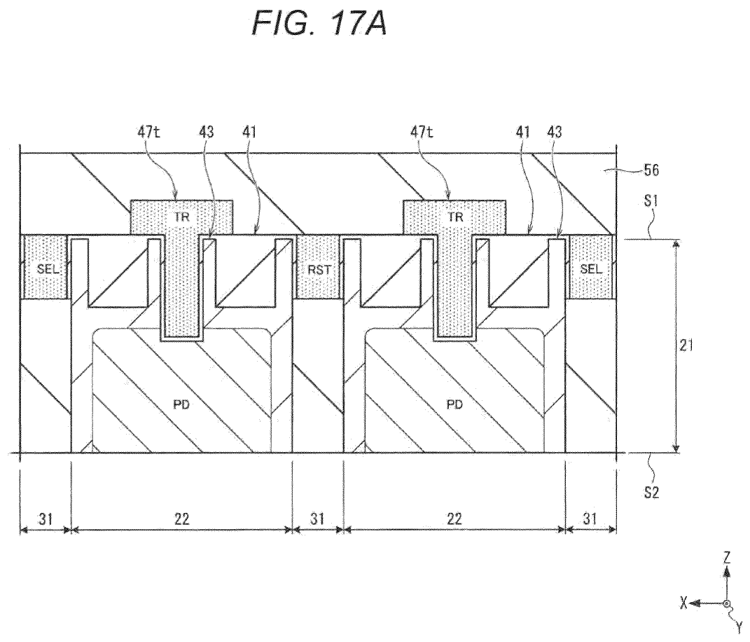

Next, as illustrated in FIGS. 17A and 17B, the interlayer insulating film 56 is formed on the first surface portion S1 side of the semiconductor layer 21. The interlayer insulating film 56 covers the inter-element isolation region 41 and the element formation region 43, covers the gate electrode 47t of the transfer transistor TR and the gate electrodes 47a, 47s, and 47r of each of the plurality of pixel transistors Q (AMP, SEL, RST), and is formed so as to embed the dug portion 51. As the interlayer insulating film 56, a silicon oxide film that can be formed by a CVD method can be used.

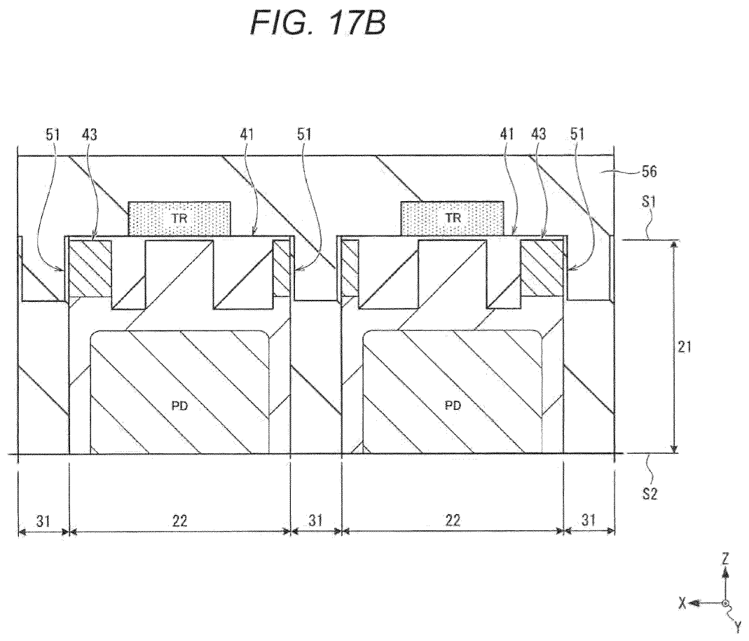

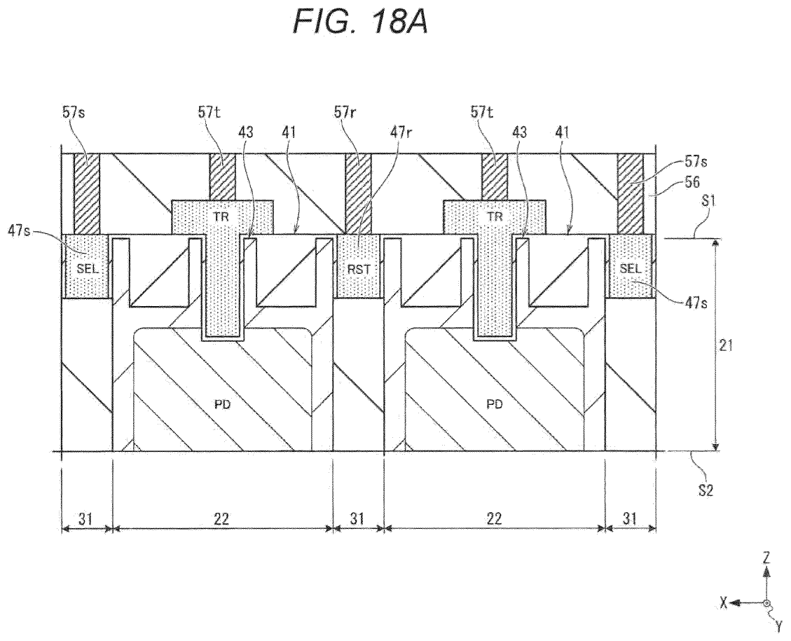

Next, as illustrated in FIGS. 18A and 18B, the contact electrodes 57t, 57a, 57r, and 57s are formed on the interlayer insulating film 56, and the contact electrode 57f (not illustrated) is formed, and then the wirings 58t, 58a, 58s, and 58r are formed on the interlayer insulating film 56, whereby the state illustrated in FIGS. 5A to 7 is obtained.

### Main Effects of First Embodiment

Next, main effects of the first embodiment will be described.

As illustrated in FIGS. 4A and 5B, in the solid-state imaging device 1A according to the first embodiment, among the plurality of pixel transistors Q (AMP, RST, SEL) included in the pixel circuit 16, each of the reset transistor RSE and the selection transistor SEL includes the first side surface portion 22b of the photoelectric conversion region 22, and the gate electrodes 47r and 47s provided in the inter-pixel isolation region 31 adjacent to each other with the gate insulating film 46 interposed therebetween. Therefore, as compared with a case where the gate electrodes 47r and 47s of the reset transistor RST and the selection transistor SEL are arranged in the photoelectric conversion region 22, the occupancy area occupied by each of the reset transistor RST and the selection transistor SEL in the photoelectric conversion region 22 can be reduced, and the degree of freedom in arrangement (degree of freedom in layout) in which the active elements including the pixel transistor Q (AMP, RST, SEL) and the transfer transistor TR are arranged in the photoelectric conversion region 22 can be increased. Therefore, according to the solid-state imaging device 1A according to the first embodiment, it is possible to increase the degree of freedom in arrangement of the active elements in the photoelectric conversion region 22.

In addition, since it is possible to reduce the area occupied by each of the reset transistor RST and the selection transistor SEL in the photoelectric conversion region 22, it is possible to miniaturize the photoelectric conversion region 22 without miniaturizing the pixel transistor Q provided in the photoelectric conversion region 22. As a result, it is possible to miniaturize the photoelectric conversion region 22 while suppressing characteristic deterioration accompanying miniaturization of the pixel transistor Q provided in the photoelectric conversion region 22.

Furthermore, the gate electrodes 47r and 47s of the reset transistor RST and the selection transistor SEL are provided in the inter-pixel isolation region 31 adjacent to the first side surface portion 22b of the photoelectric conversion region 22 with the gate insulating film 46 interposed therebetween. Therefore, gate widths Wg of the gate electrodes 47r and 47s can be increased in the thickness direction (Z direction) of the semiconductor layer 21, and the transconductance (gm) can be improved without increasing the planar sizes of the reset transistor RST and the selection transistor SEL.

In addition, the pair of main electrode regions 52r and 52ar of the reset transistor RST and the pair of main electrode regions 52s and 52as of the selection transistor SEL are provided on the upper surface portion 22a side of the photoelectric conversion region 22 (the first surface portion S1 side of the semiconductor layer 21) while being separated from each other along the side (edge) of the photoelectric conversion region 22 in plan view. Therefore, the pair of main electrode regions 52r and 52ar of the reset transistor RST can be easily electrically connected to the wiring of the multilayer wiring layer 55, and the pair of main electrode regions 52s and 52as of the selection transistor SEL can be easily electrically connected to the wiring of the multilayer wiring layer 55, so that the degree of freedom in routing the wiring in the multilayer wiring layer 55 can be increased.

In addition, the main electrode region 52ar of the reset transistor RST and the main electrode region 52ar of the amplification transistor AMP are shared. In addition, the main electrode region 52as of the selection transistor SEL and the main electrode region 52as of the amplification transistor AMP are shared. Furthermore, the floating diffusion region FD is shared with the main electrode region 52r of the transfer transistor TR. Therefore, the planar size of the photoelectric conversion region 22 can be reduced, and the number of pixels of the pixel array unit 1A can be increased without increasing the planar size of the pixel array unit 1A. In recent years, an image sensor capable of high resolution has been demanded in the market, and can contribute to high resolution of the image sensor.

In addition, the photoelectric conversion region 22 includes the first side surface portion 22b on the side of the inter-pixel isolation region 31, and the second side surface portion 22c located on the side opposite to the first side surface portion 22b and adjacent to the inter-element isolation region 41. Then, each of the reset transistor RST and the selection transistor SEL includes the channel formation portions 53r and 53s between the first side surface portion 22b and the second side surface portion 22c of the photoelectric conversion region 22. Therefore, the thicknesses of the channel formation portions 53r and 53s in the planar direction can be easily adjusted by the separation distance between the inter-pixel isolation region 31 and the inter-element isolation region 41, and the channel formation portions 53r and 53s can be thinned (reduced in thickness). As a result, it is possible to make the depletion layer substantially not extend from the main electrode regions 52r, 52ar, 52s, and 52as functioning as the source region and the drain region, so that the short channel effect can be reduced and the back bias effect from the semiconductor layer 21 can also be reduced in each of the reset transistor RST and the selection transistor SEL. As a result, the transistor characteristics of the reset transistor RST and the selection transistor SEL can be improved.

Furthermore, in the two photoelectric conversion regions 22 (pixels 3) arranged in the Y direction in plan view, the floating diffusion region FD of one photoelectric conversion region 22 and the amplification transistor AMP of the other photoelectric conversion region 22 are arranged so as to be adjacent to each other, whereby the conductive path electrically connecting the floating diffusion region FD of one photoelectric conversion region 22 and the gate electrode 47a of the amplification transistor AMP of the other photoelectric conversion region 22 can be shortened, and the wiring capacitance added to the floating diffusion region FD can be reduced. As a result, the conversion efficiency can be increased, and the random noise characteristic can be improved.

Here, in the amplification transistor AMP, a defect at the interface of the gate insulating film 46 affects random noise. Since the number of defects at the interface of the gate insulating film 46 is smaller on the upper surface portion 22a side than on the second side surface portion 22c side of the photoelectric conversion region 22, the amplification transistor AMP is preferably provided on the upper surface portion side of the photoelectric conversion region.

### Modifications of First Embodiment

In the first embodiment described above, the case where the gate electrodes 47r and 47s of the reset transistor RST and the selection transistor SEL are provided in the inter-pixel isolation region 31 has been described, but the present technology is not limited to the first embodiment described above.

For example, the gate electrode 47a of the amplification transistor AMP may be provided in the inter-pixel isolation region 31. That is, the present technology has a configuration in which the gate electrode of at least one pixel transistor of the plurality of pixel transistors Q included in the pixel circuit 16 is provided in the inter-pixel isolation region 31.

Furthermore, in the first embodiment described above, the case where the gate electrodes 47r and 47s of the reset transistor RST and the selection transistor SEL are embedded in the inter-pixel isolation region 31 has been described. However, a part of the gate electrodes 47r and 47s of the reset transistor RST and the selection transistor SEL may overlap the inter-pixel isolation region 31, and the other part may be embedded in the inter-pixel isolation region 31. In other words, the gate electrodes 47r and 47s of the reset transistor RST and the selection transistor SEL may extend in and out of the inter-pixel isolation region 31 in the thickness direction (Z direction) of the semiconductor layer 21.

### Second Embodiment

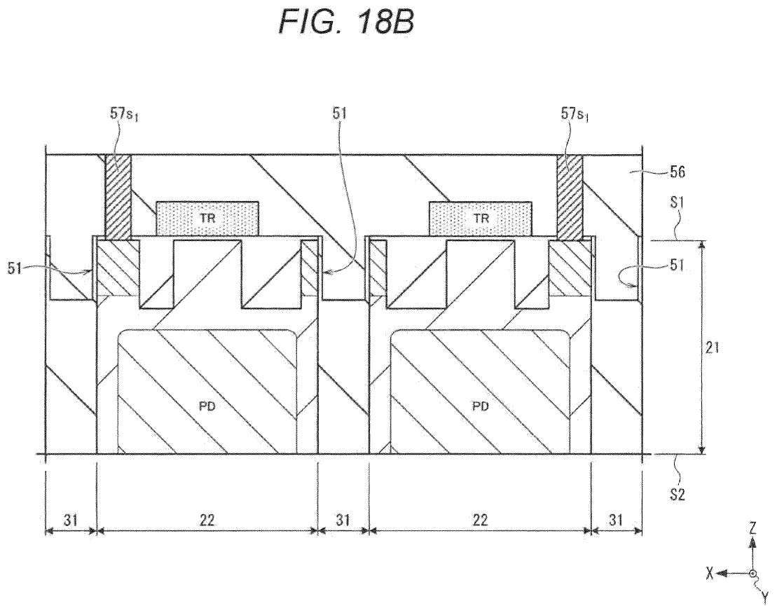

As illustrated in FIG. 19, a solid-state imaging device 1B according to a second embodiment of the present technology basically has a configuration similar to that of the solid-state imaging device 1A according to the first embodiment described above, and differs in the configuration of an inter-pixel isolation region.

That is, as illustrated in FIGS. 5A and 5B, the inter-pixel isolation region 31 of the first embodiment described above includes one vertical portion extending linearly over the first surface portion S1 side and the second surface portion S2 side of the semiconductor layer 21.

On the other hand, as illustrated in FIG. 19, the inter-pixel isolation region 31B of the second embodiment has a stepped structure including a first vertical portion 31b₁ provided on the first surface portion S1 side of the semiconductor layer 21, a second vertical portion 31b₂ extending from the first vertical portion 31b₁ toward the second surface portion S2 side of the semiconductor layer 21 and having a width narrower than the width of the first vertical portion 31b₁, and a step portion 31bz due to a difference between the width of the first vertical portion 31b₁ and the width of the second vertical portion 31b₂.

The gate electrodes 47r and 47s of the reset transistor RST and the selection transistor SEL are embedded in the first vertical portion 31b₁ of the inter-pixel isolation region 31B. Then, each of the gate electrodes 47r and 47s is adjacent to the first side surface portion 22b of the photoelectric conversion region 22 with the gate insulating film 46 interposed therebetween.

The inter-pixel isolation region 31B can be formed, for example, by forming a shallow groove portion on the first surface portion S1 side of the semiconductor layer 21, then forming a dug portion extending from the bottom surface portion of the shallow groove portion toward the second surface portion S2 side of the semiconductor layer 21, and then selectively embedding the isolation insulating film 34 in the dug portion and the shallow groove portion.

Furthermore, the inter-pixel isolation region 31B can be formed, for example, by forming a dug portion extending from the first surface portion S1 side toward the second surface portion S2 side of the semiconductor layer 21, then selectively embedding the isolation insulating film 34 in the dug portion, then selectively etching the semiconductor layer 21 in a region overlapping the dug portion in which the isolation insulating film 34 is embedded and its peripheral portion on the first surface portion S1 side of the semiconductor layer 21 to form a shallow groove portion, and then selectively embedding the isolation insulating film in the shallow groove portion.

The present technology can also be applied to the inter-pixel isolation region 31B of the second embodiment.

Furthermore, by applying the present technology, effects similar to those of the solid-state imaging device 1A according to the first embodiment described above can be obtained also in the solid-state imaging device 1B according to the second embodiment.

In addition, in the case of the inter-pixel isolation region 31B of the second embodiment, since the volume of the n-type semiconductor region 24 can be increased as compared with the inter-pixel isolation region 31 of the first embodiment described above, the saturation signal amount Qs can be further improved.

### Third Embodiment

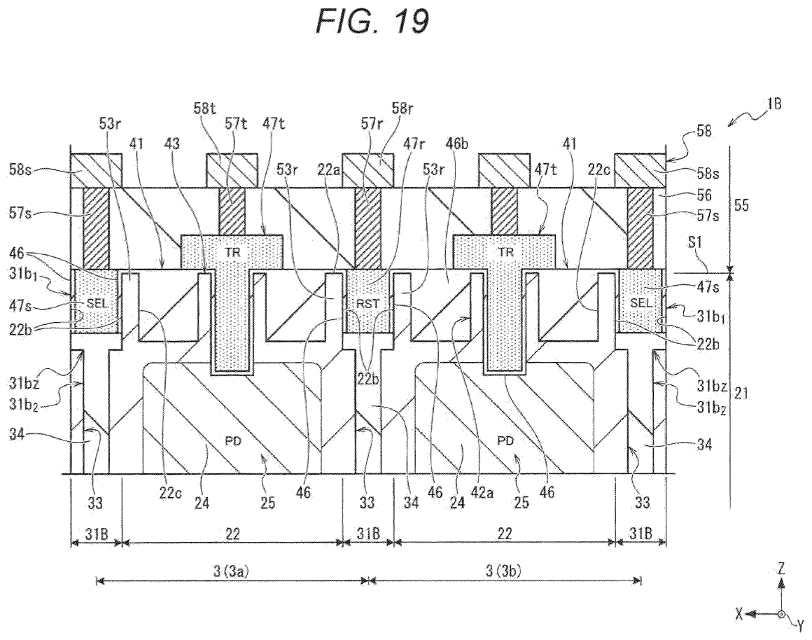

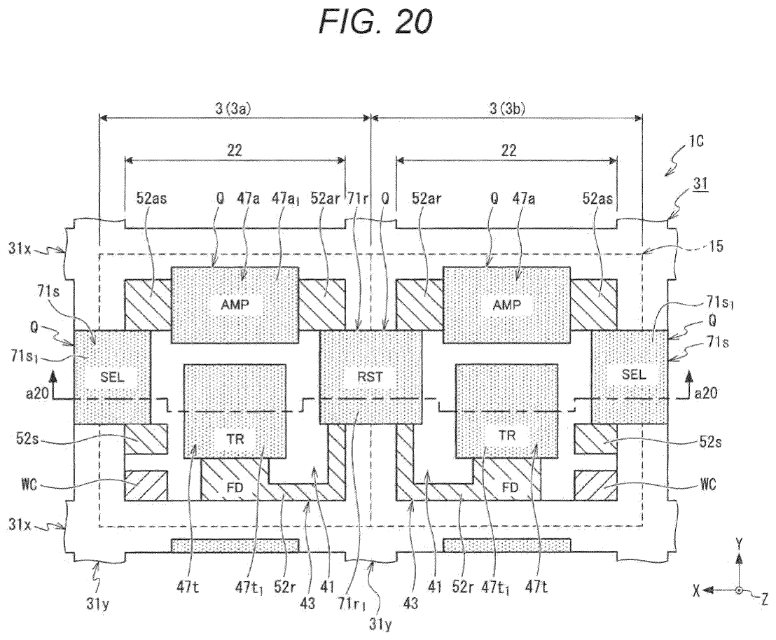

As illustrated in FIGS. 20 and 21, a solid-state imaging device 1C according to the third embodiment of the present technology basically has a configuration similar to that of the solid-state imaging device 1A according to the first embodiment described above, and differs in the configurations of the gate electrodes of the reset transistor RST and the selection transistor SEL.

That is, as illustrated in FIGS. 20 and 21, the reset transistor RST and the selection transistor SEL of the third embodiment include gate electrodes 71r and 71s instead of the gate electrodes 47r and 47s illustrated in FIGS. 4B and 5B of the first embodiment described above. Other configurations are substantially similar to those in the first embodiment.

As illustrated in FIGS. 20 and 21, the gate electrode 71r of the reset transistor RST is provided over the upper surface portion 22a and the first side surface portion 22b of the photoelectric conversion region 22 with the gate insulating film 46 interposed therebetween.

Specifically, the gate electrode 71r includes a head portion 71r₁ that extends over the photoelectric conversion region 22 and the inter-pixel isolation region 31 in plan view outside the first surface portion S1 of the semiconductor layer 21, and a leg portion 71r₂ that protrudes from the head portion 71r₁ toward the inter-pixel isolation region 31 and is adjacent to the first side surface portion 22b of the photoelectric conversion region 22 with the gate insulating film 46 interposed therebetween. Then, the gate insulating film 46 is provided between the head portion 71r₁ and the upper surface portion 22a of the photoelectric conversion region 22.

Furthermore, as illustrated in FIGS. 20 and 21, similarly to the gate electrode 71r, the gate electrode 71s of the selection transistor SEL is also provided over the upper surface portion 22a and the first side surface portion 22b of the photoelectric conversion region 22 with the gate insulating film 46 interposed therebetween.

Specifically, similarly to the gate electrode 71r, the gate electrode 71s also includes a head portion 71s₁ that extends over the photoelectric conversion region 22 and the inter-pixel isolation region 31 in plan view outside the first surface portion S1 of the semiconductor layer 21, and a leg portion 71s₂ that protrudes from the head portion 71s₁ toward the inter-pixel isolation region 31 and is adjacent to the first side surface portion 22b of the photoelectric conversion region 22 with the gate insulating film 46 interposed therebetween. Then, the gate insulating film 46 is also provided between the head portion 71s1 and the upper surface portion 22a of the photoelectric conversion region 22.

In the gate electrodes 71r and 71s of the reset transistor RST and the selection transistor SEL of the third embodiment, similarly to the gate electrode 47r of the transfer transistor TR, the widths of the head portions 71r₁ and 71s₁ are wider than the widths of the leg portions 71r₂ and 71r₂, and the longitudinal sectional shape is a T shape.

The solid-state imaging device 1C according to the third embodiment can also produce effects similar to the effects produced by the solid-state imaging device 1A according to the first embodiment described above.

In addition, since the gate electrodes 71r and 71s of the reset transistor RST and the selection transistor SEL of the third embodiment are provided over the upper surface portion 22a and the first side surface portion 22b of the photoelectric conversion region 22 with the gate insulating film 46 interposed therebetween, gate widths Wg of the gate electrodes 71r and 71s can be further widened as compared with the first embodiment.

Note that, in the third embodiment, a case where the present technology is applied to each of the reset transistor RST and the selection transistor SEL has been described, but the present technology can also be applied to the amplification transistor AMP.

### Fourth Embodiment

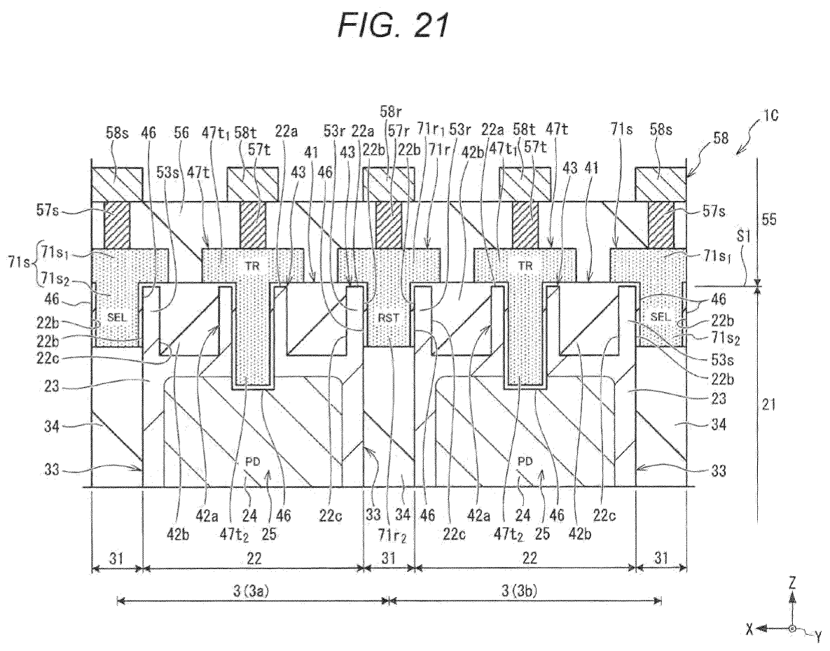

As illustrated in FIG. 22, a solid-state imaging device 1D according to the fourth embodiment of the present technology basically has a configuration similar to that of the solid-state imaging device 1A according to the first embodiment described above, and differs in the configurations of the gate electrodes of the reset transistor RST and the selection transistor SEL.

That is, as illustrated in FIG. 22, the reset transistor RST and the selection transistor SEL of the fourth embodiment include gate electrodes 72r and 72s instead of the gate electrodes 47r and 47s illustrated in FIGS. 4B and 5B of the first embodiment described above. Other configurations are substantially similar to those in the first embodiment.

As illustrated in FIG. 22, the gate electrode 72r of the reset transistor RST is provided over each of the upper surface portion 22a, the first side surface portion 22b, and the second side surface portion 22c of the photoelectric conversion region 22 with the gate insulating film 46 interposed therebetween.

Specifically, the gate electrode 72r includes: a head portion 72r₁ that is located outside the first surface portion S1 of the semiconductor layer 21 and extends across the inter-pixel isolation region 31 and the inter-element isolation region 41 across the upper surface portion 22a (element formation region 43) of the photoelectric conversion region 22 in plan view; a first leg portion 72r₂ that protrudes from the head portion 72r₁ toward the inter-pixel isolation region 31 and is adjacent to the first side surface portion 22b of the photoelectric conversion region 22 with the gate insulating film 46 interposed therebetween; and a second leg portion 723 that protrudes from the head portion 72r₁ toward the inter-element isolation region 41 and is adjacent to the second side surface portion 22c of the photoelectric conversion region 22 with the gate insulating film 46 interposed therebetween. Then, the gate insulating film 46 is provided between the head portion 72r₁ and the upper surface portion 22a of the photoelectric conversion region 22. Then, also in the fourth embodiment, since the reset transistor RST is shared by the two pixels 3a and 3b adjacent to each other in the X direction, the gate electrode 72r has two second leg portions 7213 for one head portion 72r₁.

As illustrated in FIG. 22, similarly to the gate electrode 72r of the reset transistor RST, the gate electrode 72s of the selection transistor SEL is also provided over the upper surface portion 22a, the first side surface portion 22b, and the second side surface portion 22c of the photoelectric conversion region 22 with the gate insulating film 46 interposed therebetween.

Specifically, the gate electrode 72s includes: a head portion 72s₁ provided outside the first surface portion S1 of the semiconductor layer 21 and extending over the inter-pixel isolation region 31 and the inter-element isolation region 41 across the upper surface portion 22a of the photoelectric conversion region 22 in plan view; a first leg portion 72s₂ protruding from the head portion 72s₁ toward the inter-pixel isolation region 31 and adjacent to the first side surface portion 22b of the photoelectric conversion region 22 with the gate insulating film 46 interposed therebetween; and a second leg portion 72r₃ protruding from the head portion 72sr₁ toward the inter-element isolation region 41 and adjacent to the second side surface portion 22c of the photoelectric conversion region 22 with the gate insulating film 46 interposed therebetween.

Then, the gate insulating film 46 is provided between the head portion 72r₁ and the upper surface portion 22a of the photoelectric conversion region 22. Then, also in the fourth embodiment, in the two pixel blocks 15 adjacent to each other in the X direction, the pixel 3b of one pixel block 15 and the pixel 3a of the other pixel block 15 share the selection transistor SEL. Therefore, the gate electrode 72s also has two second leg portions 72s₃ for one head portion 72s₁.

The solid-state imaging device 1D according to the fourth embodiment can also produce effects similar to the effects produced by the solid-state imaging device 1A according to the first embodiment described above.

In addition, since the gate electrodes 72r and 72s of the reset transistor RST and the selection transistor SEL of the fourth embodiment are provided over the upper surface portion 22a, the first side surface portion 22b, and the second side surface portion 22c of the photoelectric conversion region 22 with the gate insulating film 46 interposed therebetween, gate widths Wg of the gate electrodes 72r and 72s can be further widened as compared with the third embodiment.

Note that, in the fourth embodiment, a case where the present technology is applied to each of the reset transistor RST and the selection transistor SEL has been described, but the present technology can also be applied to the amplification transistor AMP.

### Fifth Embodiment

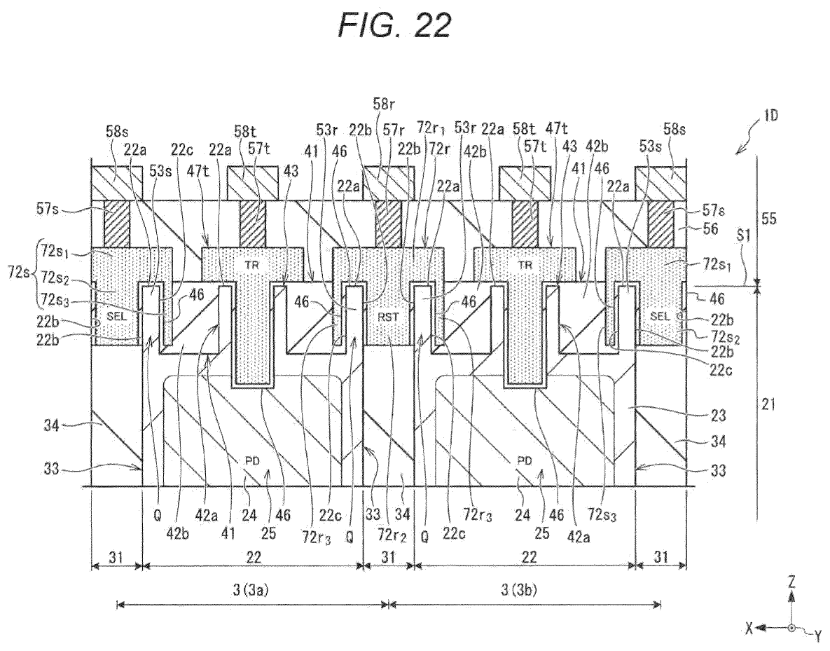

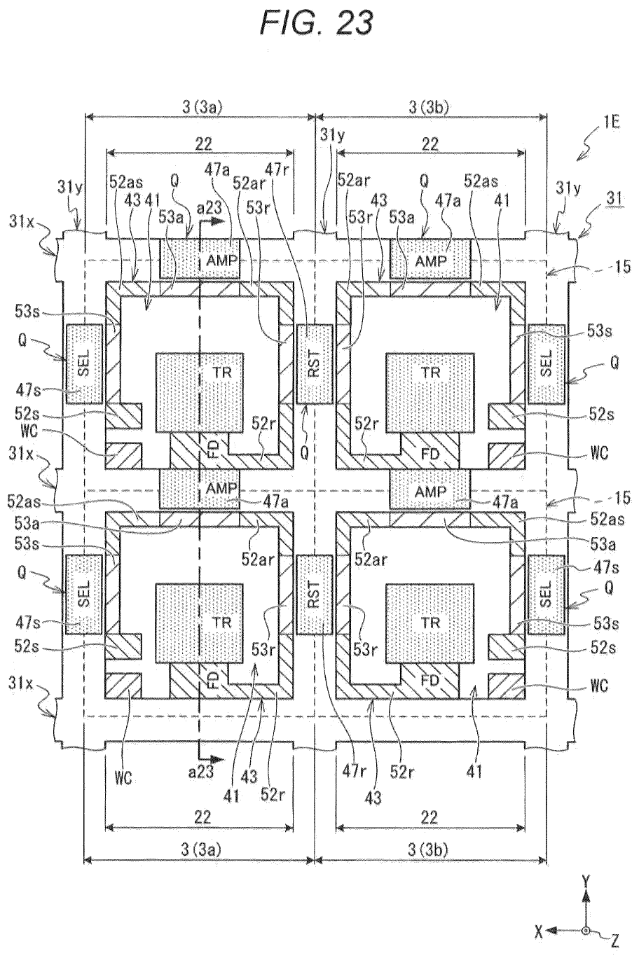

As illustrated in FIGS. 23 and 24, a solid-state imaging device 1E according to the fifth embodiment of the present technology basically has a configuration similar to that of the solid-state imaging device 1A according to the first embodiment described above, and differs in the configuration of the amplification transistor AMP.

That is, as illustrated in FIGS. 23 and 24, in the amplification transistor AMP of the fifth embodiment, the gate electrode 47a is provided in the inter-pixel isolation region 31 between the two photoelectric conversion regions 22 adjacent to each other in the Y direction in plan view.

Specifically, the amplification transistor AMP of the fifth embodiment includes the gate electrode 47a provided in the inter-pixel isolation region 31 adjacent to the first side surface portion 22b of the photoelectric conversion region 22 with the gate insulating film 46 interposed therebetween, and the pair of main electrode regions 52as and 52ar provided on the upper surface portion 22a side of the photoelectric conversion region 22 to be separated from each other in the gate length direction of the gate electrode 47a in plan view and functioning as the source region and the drain region. Further, the amplification transistor AMP further includes a channel formation portion 53a provided in the element formation region 43 (semiconductor layer 21) adjacent to the gate electrode 47a in plan view. The pair of main electrode regions 52as and 52ar includes an n-type semiconductor region, and the channel formation portion 53r includes a p-type semiconductor region 23.

In the two photoelectric conversion regions 22 arranged in the Y direction via the inter-pixel isolation region 31 in plan view, the amplification transistor AMP of the fifth embodiment includes the gate electrode 47a that is connected adjacent to the floating diffusion region FD of one photoelectric conversion region 22 and is provided in the inter-pixel isolation region 31 adjacent to the first side surface portion 22b of the other photoelectric conversion region 22 via the gate insulating film 46.

The solid-state imaging device 1E according to the fifth embodiment can also produce effects similar to the effects produced by the solid-state imaging device 1A according to the first embodiment described above.

In addition, in the amplification transistor AMP of the fifth embodiment, the gate electrode 47a is connected to the floating diffusion region FD so as to be adjacent to each other in plan view. Therefore, the gate electrode 47a and the floating diffusion region FD can be electrically connected at the shortest distance, and the wiring capacitance added to the floating diffusion region FD can be reduced as compared with the case where the gate electrode 47a and the floating diffusion region FD are electrically connected via the wiring of the multilayer wiring layer 55. As a result, conversion efficiency can be increased, and random noise can be reduced.

### Sixth Embodiment

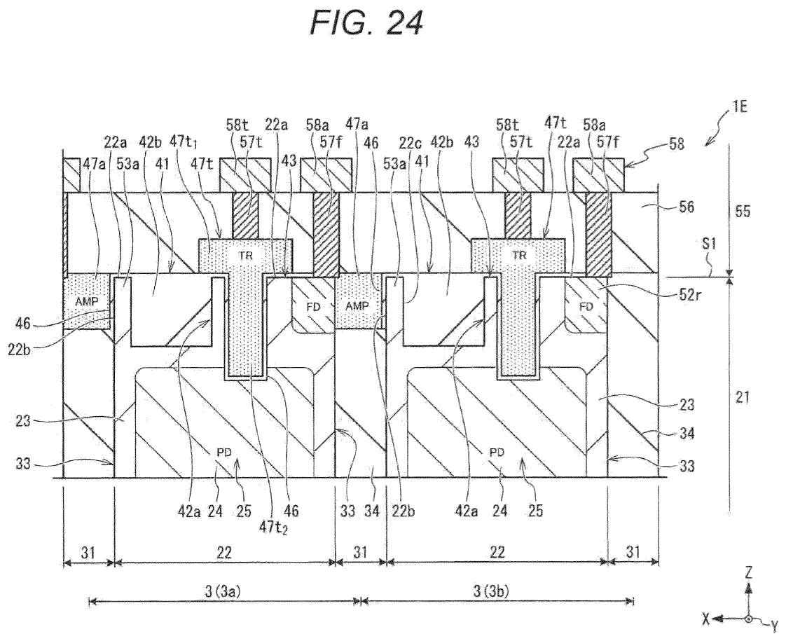

As illustrated in FIGS. 25 to 29, the solid-state imaging device 1F according to the sixth embodiment of the present technology basically has a configuration similar to that of the solid-state imaging device 1A according to the first embodiment described above, and differs in the configuration of the amplification transistor AMP. Furthermore, the solid-state imaging device 1F according to the sixth embodiment of the present technology further includes relay conductor portions 74a and 74b provided in the inter-pixel isolation region 31.

### Gate Electrode

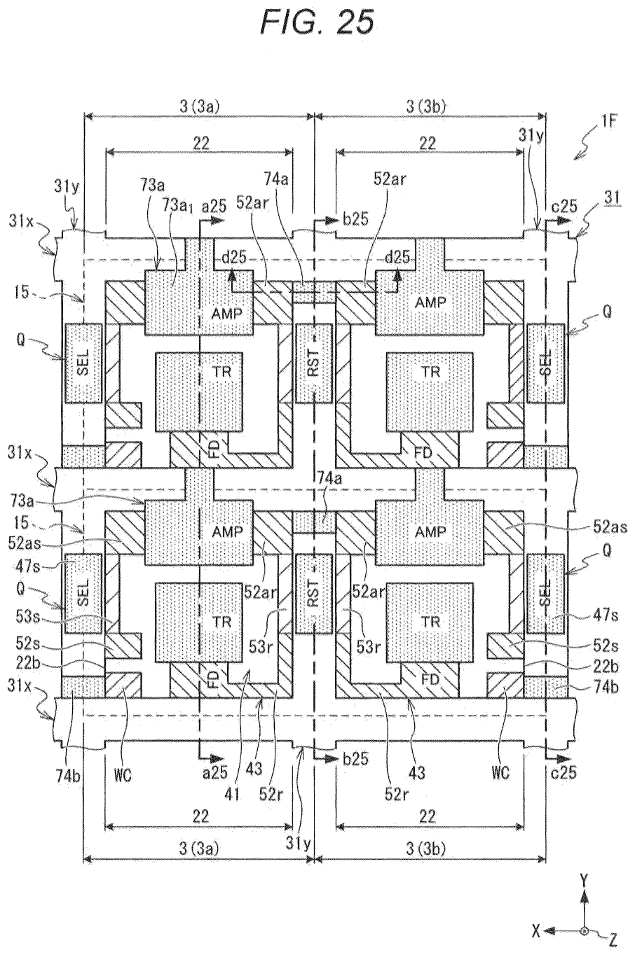

As illustrated in FIGS. 25 and 26, the amplification transistor AMP of the sixth embodiment includes a gate electrode 73a instead of the gate electrode 47a illustrated in FIGS. 4A and 7 of the first embodiment described above. The other configurations are substantially similar to those of the first embodiment described above.

As illustrated in FIGS. 25 and 26, in the two photoelectric conversion regions 22 arranged adjacent to each other in the Y direction via the inter-pixel isolation region 31 in plan view, the amplification transistor AMP provided in one photoelectric conversion region 22 includes the gate electrode 73a provided over the upper surface portion 22a of one photoelectric conversion region 22 and the inter-pixel isolation region 31 in plan view, and electrically and mechanically connected to the floating diffusion region FD provided in the other photoelectric conversion region 22 on the first side surface portion 22b of the other photoelectric conversion region 22.

Specifically, as illustrated in FIGS. 25 and 26, the gate electrode 73a of the amplification transistor AMP according to the sixth embodiment includes a head portion 73a1 extending over one photoelectric conversion region 22 and the inter-pixel isolation region 31 in plan view outside the first surface portion S1 of the semiconductor layer 21, and a relay protrusion portion 73a₃ protruding from the head portion 73a₁ toward the inter-pixel isolation region 31 and electrically and mechanically connected to the floating diffusion region FD of the other photoelectric conversion region 22 at the first side surface portion 22b of the other photoelectric conversion region 22. Then, the gate insulating film 46 is interposed between the head portion 73a1 and the upper surface portion 22a of one photoelectric conversion region 22. Then, the relay protrusion 73a₃ is embedded in the inter-pixel isolation region 31.

### Relay Conductor Portion

As illustrated in FIGS. 25, 27, and 29, the relay conductor portion 74a is provided in the inter-pixel isolation region 31 between the two photoelectric conversion regions 22 included in one pixel block 15. Then, in the two photoelectric conversion regions 22 included in one pixel block 15, the relay conductor portion 74a is electrically and mechanically connected to the main electrode region 52ar of the amplification transistor AMP in one photoelectric conversion region 22 on the first side surface portion 22b of one photoelectric conversion region 22, and is electrically and mechanically connected to the main electrode region 52ar of the amplification transistor AMP in the other photoelectric conversion region 22 on the first side surface portion 22b of the other photoelectric conversion region 22. That is, the relay conductor portion 74a is electrically and mechanically connected to the main electrode region 52ar of each of the two amplification transistors AMP adjacent to each other with the inter-pixel isolation region 31 interposed therebetween on the first side surface portion 22b of each of the two photoelectric conversion regions 22 adjacent to each other in plan view.

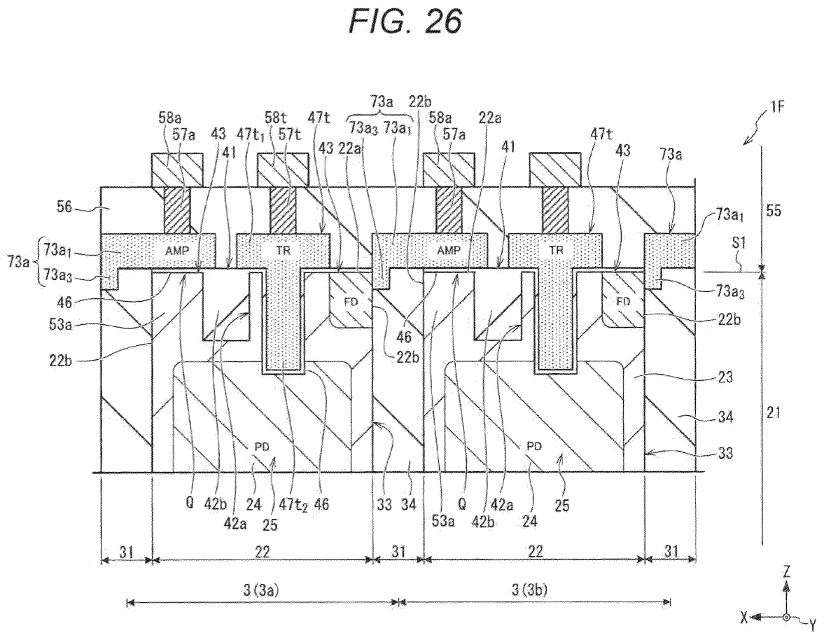

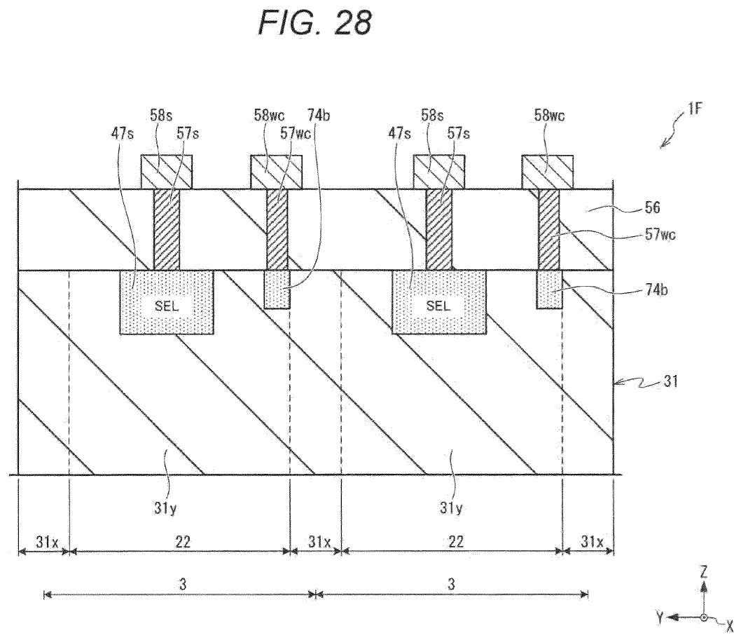

As illustrated in FIGS. 27 and 29, the relay conductor portion 74a is embedded in the inter-pixel isolation region 31, penetrates the inter-pixel isolation region 31 in the X direction, and is connected to the first side surface portion 22b of each of the two photoelectric conversion regions 22 included in one pixel block 15. Then, the relay conductor portion 74a is electrically connected to the wiring 58ar provided in the wiring layer 58 on the interlayer insulating film 56 via the contact electrode 57ar provided in the interlayer insulating film 56.

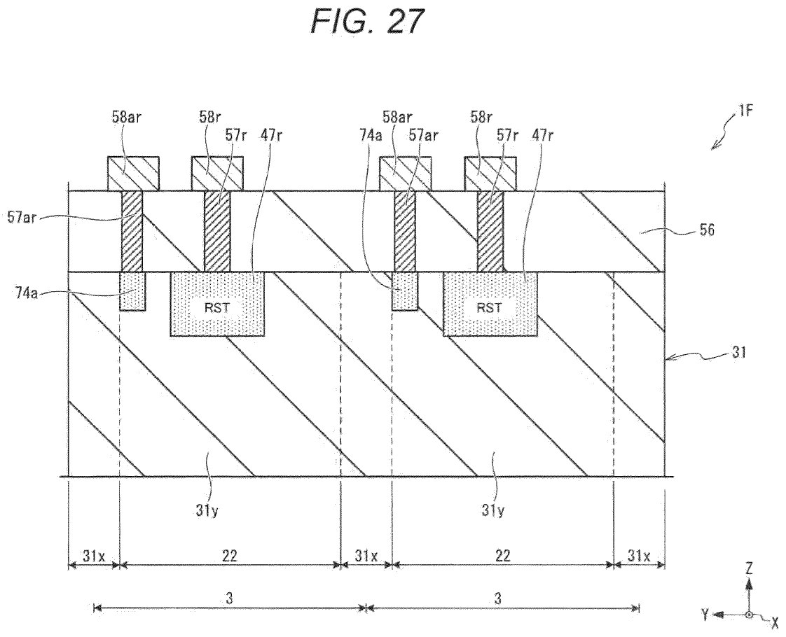

Although not illustrated in detail, referring to FIGS. 25 and 28, the relay conductor portion 74b is provided in the inter-pixel isolation region 31 between two pixel blocks 15 adjacent to each other in the X direction. Then, in the two photoelectric conversion regions 22 adjacent to each other in the two pixel blocks 15 arranged in the X direction, the relay conductor portion 74b is electrically and mechanically connected to the power supply contact region WC of one photoelectric conversion region 22 at the first side surface portion 22b of one photoelectric conversion region 22, and is electrically and mechanically connected to the power supply contact region WC of the other photoelectric conversion region 22 at the first side surface portion 22b of the other photoelectric conversion region 22. That is, the relay conductor portion 74b is electrically and mechanically connected to the two power supply contact regions WC adjacent to each other with the inter-pixel isolation region 31 interposed therebetween at the first side surface portion 22b of each of the two photoelectric conversion regions 22 adjacent to each other in plan view.

Although not illustrated in detail, as will be described with reference to FIG. 28, the relay conductor portion 74b is embedded in the inter-pixel isolation region 31, penetrates the inter-pixel isolation region 31 in the X direction, and is connected to the first side surface portion 22b of each of the two photoelectric conversion regions 22 adjacent to each other with the inter-pixel isolation region 31 interposed therebetween, similarly to the relay conductor portion 74a. Then, similarly to the relay conductor portion 74a, the relay conductor portion 74b is electrically connected to a wiring 58wc provided in the wiring layer 58 on the interlayer insulating film 56 via a contact electrode 57wc provided in the interlayer insulating film 56. A reference potential of, for example, 0 V is supplied from the wiring 58wc to the relay conductor portion 74b through the contact electrode 57wc.

As each of the relay conductor portions 74a and 74b, for example, a polycrystalline silicon film into which an impurity for reducing the resistance value is introduced is used. A metal film may be used as each of the relay conductor portions 74a and 74b, but a polycrystalline silicon film is preferably used in consideration of a difference in thermal expansion coefficient from the inter-pixel isolation region 31 and the semiconductor layer 21.

### Main Effects of Sixth Embodiment

As described above, the amplification transistor AMP of the sixth embodiment includes the gate electrode 73a provided over the upper surface portion 22a of one photoelectric conversion region 22 and the inter-pixel isolation region 31 in the two photoelectric conversion regions 22 arranged in the Y direction via the inter-pixel isolation region 31 in plan view, and electrically and mechanically connected to the floating diffusion region FD of the other photoelectric conversion region 22 at the first side surface portion 22b of the other photoelectric conversion region 22. Therefore, it is not necessary to electrically connect the gate electrode 73a of the amplification transistor AMP and the floating diffusion region FD with the wiring of the multilayer wiring layer 55, and the wiring density of the multilayer wiring layer 55 overlapping the photoelectric conversion region 22 in plan view can be reduced. As a result, the degree of freedom in routing the wiring connected to the pixel transistor Q of the photoelectric conversion region 22 can be increased, and the restriction on the arrangement of the pixel transistor Q due to the routing of the wiring can be relaxed. Therefore, according to the solid-state imaging device 1F according to the sixth embodiment, the degree of freedom in arrangement of the pixel transistors Q in the photoelectric conversion region 22 can be increased.

Furthermore, the solid-state imaging device 1F according to the sixth embodiment includes the relay conductor portion 74a provided in the inter-pixel isolation region 31 between two photoelectric conversion regions 22 arranged in the X direction of one pixel block 15. Then, in the two photoelectric conversion regions 22 included in one pixel block 15, the relay conductor portion 74a is electrically and mechanically connected to the main electrode region 52ar of the amplification transistor AMP in one photoelectric conversion region 22 on the first side surface portion 22b of one photoelectric conversion region 22, and is electrically and mechanically connected to the main electrode region 52ar of the amplification transistor AMP in the other photoelectric conversion region 22 on the first side surface portion 22b of the other photoelectric conversion region 22. Therefore, in the connection between the relay conductor portion 74a and the contact electrode 57ar, it is possible to suppress connection failure due to impurity concentration, etching damage, silicide abnormality, and the like sufficient for connection, and it is possible to suppress generation of dark current due to leakage current.

Furthermore, the solid-state imaging device 1F according to the sixth embodiment includes the relay conductor portion 74b provided in the inter-pixel isolation region 31 between the two pixel blocks 15 adjacent to each other in the X direction. Then, also in the relay conductor portion 74b, similarly to the relay conductor portion 74a, in the two photoelectric conversion regions 22 adjacent to each other in the two pixel blocks 15 arranged in the X direction, the first side surface portion 22b of one photoelectric conversion region 22 is electrically and mechanically connected to the power supply contact region WC of one photoelectric conversion region 22, and the first side surface portion 22b of the other photoelectric conversion region 22 is electrically and mechanically connected to the power supply contact region WC of the other photoelectric conversion region 22. Therefore, in the connection between the relay conductor portion 74b and the contact electrode 57WC, it is possible to suppress connection failure due to impurity concentration, etching damage, silicide abnormality, and the like sufficient for connection, and it is possible to suppress generation of dark current due to leakage current.

### Seventh Embodiment

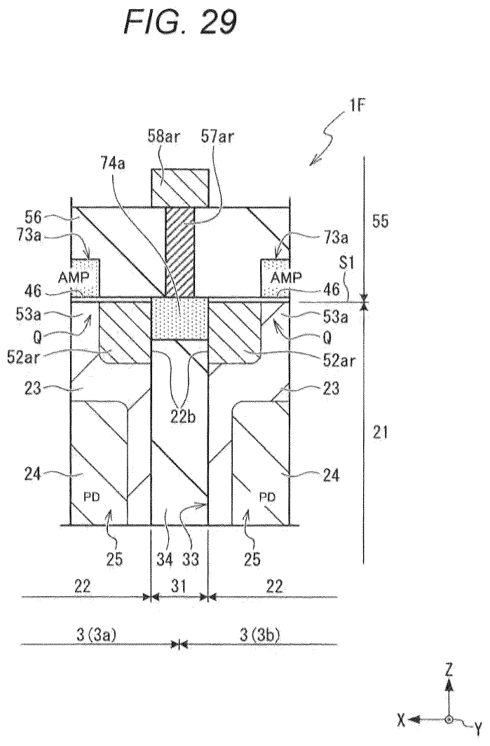

As illustrated in FIGS. 30 to 32, a solid-state imaging device 1G according to a seventh embodiment of the present technology basically has a configuration similar to that of the solid-state imaging device 1A according to the first embodiment described above, and differs in the following configuration.

That is, the solid-state imaging device 1G of the seventh embodiment includes a pixel circuit 16G illustrated in FIG. 30 instead of the pixel circuit 16 illustrated in FIG. 3 of the first embodiment described above. Then, in the seventh embodiment, the transistor layout of the photoelectric conversion region 22 is slightly different from that of the first embodiment described above. Other configurations are substantially similar to those in the first embodiment.

As illustrated in FIG. 30, the pixel circuit 16G has a circuit configuration in which a switching transistor FDG is newly added to the configuration of the pixel circuit 16 described above. That is, the pixel circuit 16G includes an amplification transistor AMP, a selection transistor SEL, a reset transistor RST, and a switching transistor FDG as the pixel transistor Q.

As illustrated in FIG. 30, in the switching transistor FDG, the source region is electrically connected to the gate electrode of the amplification transistor AMP and the floating diffusion region FD, and the drain region is electrically connected to the source region of the reset transistor RST. Then, the switching transistor FDG has a gate electrode electrically connected to a switching transistor drive line among the pixel drive lines 10 illustrated in FIG. 2. The switching transistor FDG controls charge retention by the floating diffusion region FD, and adjusts the multiplication factor of the voltage according to the potential amplified by the amplification transistor AMP.

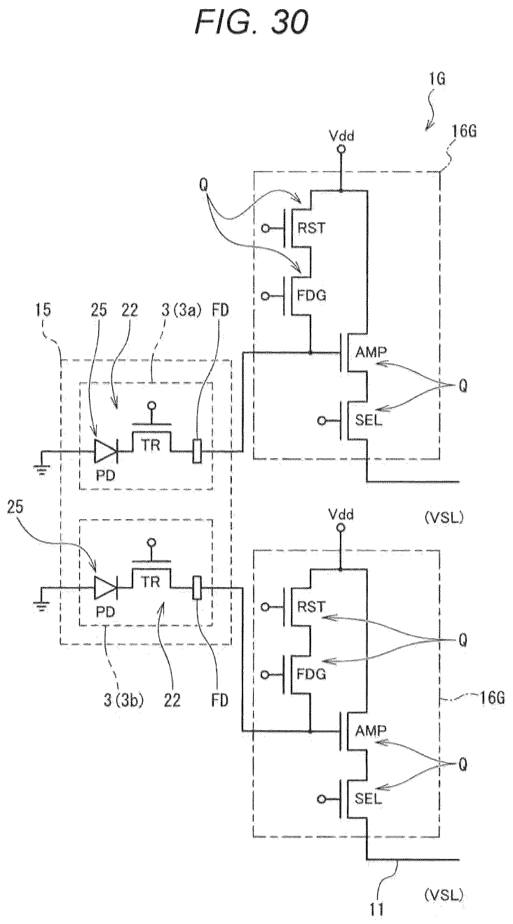

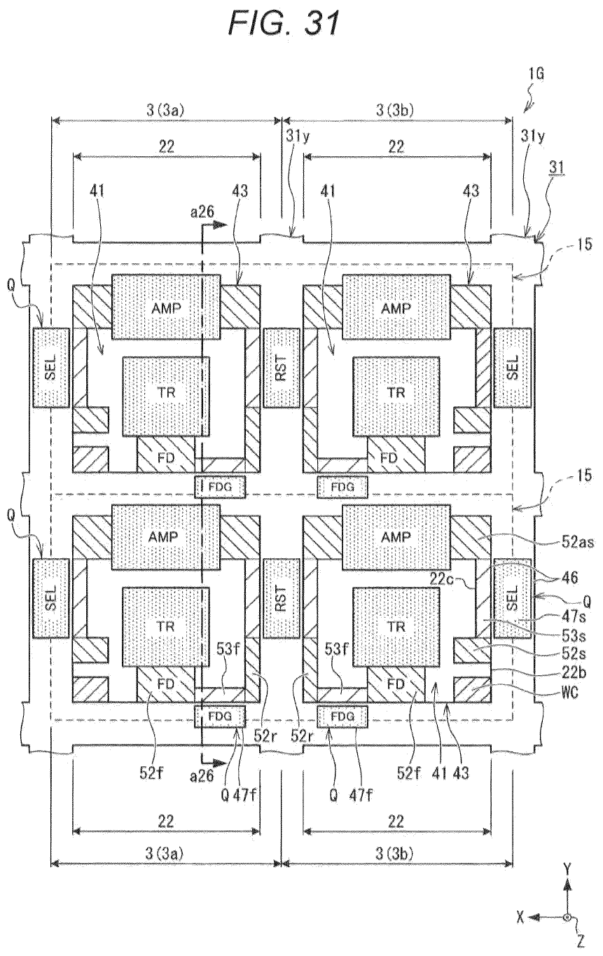

As illustrated in FIGS. 31 and 32, in the switching transistor FDG, a gate electrode 47f is provided in the inter-pixel isolation region 31 between two photoelectric conversion regions 22 adjacent to each other in the Y direction in plan view.

Specifically, the switching transistor FDG includes the gate electrode 47f provided in the inter-pixel isolation region 31 so as to be adjacent to the first side surface portion 22b of the photoelectric conversion region 22 with the gate insulating film 46 interposed therebetween, and a pair of main electrode regions 52f and 52r provided on the upper surface portion 22a side of the photoelectric conversion region 22 so as to be separated from each other in the gate length direction of the gate electrode 47f in plan view and functioning as a source region and a drain region. In addition, the switching transistor FDG further includes a channel formation portion 53f provided in the element formation region 43 (semiconductor layer 21) adjacent to the gate electrode 47f in plan view. The pair of main electrode regions 52f and 52r includes an n-type semiconductor region, and the channel formation portion 53f includes a p-type semiconductor region 23.

The switching transistor FDG is used to switch the conversion efficiency. In general, the pixel signal is small at a time of imaging in a dark place. If the FD capacitance C (floating diffusion capacitance C) of the floating diffusion region FD is large at the time of performing charge-voltage conversion on the basis of Q=CV, the voltage V when converted into a voltage by the amplification transistor AMP becomes small. On the other hand, since the pixel signal increases in a bright place, unless the FD capacitance C of the floating diffusion region FD is large, the floating diffusion region FD cannot receive the electric charge of the photoelectric conversion unit 25 (photodiode PD). Furthermore, the FD capacitance C of the floating diffusion region FD needs to be large so that the voltage V when converted into the voltage by the amplification transistor AMP does not become too large (in other words, it is made smaller). In view of these, when the switching transistor FDG is turned on, the gate capacitance of the switching transistor FDG increases, so that the entire FD capacitance C increases. On the other hand, when the switching transistor FDG is turned off, the entire FD capacitance C decreases. In this manner, by switching on/off of the switching transistor FDG, the FD capacitance C can be made variable, and the conversion efficiency can be switched.

In the seventh embodiment, the floating diffusion region FD is shared with the main electrode region 52f of the switching transistor FDG. Furthermore, the reset transistor RST and the switching transistor FDG are connected in series such that the main electrode region 52r of the reset transistor RST and the main electrode region 52r of the switching transistor FDG are shared.

Also in the solid-state imaging device 1G according to the seventh embodiment, effects similar to those of the solid-state imaging device 1A according to the first embodiment described above can be obtained.

Note that, in the seventh embodiment, as the pixel transistor Q included in the pixel circuit 16G, the case where the gate electrodes 47f, 47r, and 47s of the switching transistor FDG, the reset transistor RST, and the selection transistor SEL are provided in the inter-pixel isolation region 31 has been described. However, the gate electrode of at least one pixel transistor Q of the plurality of pixel transistors Q included in the pixel circuit 16G may be provided in the inter-pixel isolation region 31.

### Eighth Embodiment

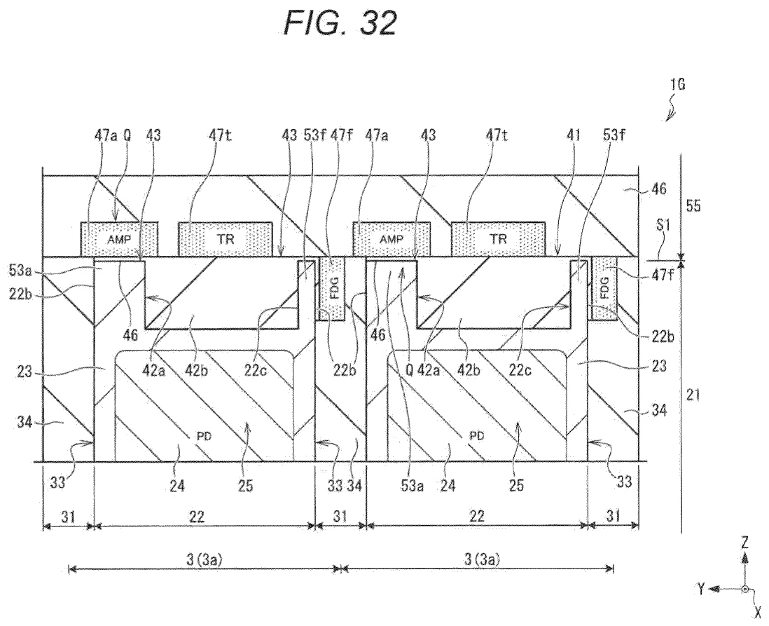

As illustrated in FIGS. 33 to 35, a solid-state imaging device 1H according to an eighth embodiment of the present technology basically has a configuration similar to that of the solid-state imaging device 1A according to the first embodiment described above, and differs in the following configuration.

That is, the solid-state imaging device 1H according to the eighth embodiment includes a pixel circuit 16H illustrated in FIG. 33 instead of the pixel circuit 16 illustrated in FIG. 3 of the first embodiment described above. Then, in the eighth embodiment, the planar layout of the pixel transistor Q included in the pixel circuit 16H is slightly different from that of the first embodiment described above. Then, all gate electrodes of the pixel transistor Q included in the pixel circuit 16H are provided in the element formation region 43 of the photoelectric conversion region 22. Other configurations are substantially similar to those in the first embodiment.

As illustrated in FIG. 33, the pixel circuit 16H has a circuit configuration in which two switching transistors FDG and FCG are newly added to the configuration of the pixel circuit 16 illustrated in FIG. 3 described above. That is, the pixel circuit 16H includes an amplification transistor AMP, a selection transistor SEL, a reset transistor RST, and two switching transistors FCG and FDG as the pixel transistor Q constituting the circuit. The pixel circuit 16G (see FIG. 30) of the seventh embodiment described above includes one switching transistor FDG, but the pixel circuit 16H of the eighth embodiment includes two switching transistors FCG and FDG.

As illustrated in FIG. 33, in the switching transistor FCG, the source region is electrically connected to the drain region of the switching transistor FDG, and the drain region is electrically connected to the source region of the reset transistor RST. Then, the gate electrode of the switching transistor FCG is electrically connected to the first switching transistor drive line among the pixel drive lines 10 illustrated in FIG. 2.

As illustrated in FIG. 33, in the switching transistor FDG, the source region is electrically connected to the gate electrode of the amplification transistor AMP and the floating diffusion region FD, and the drain region is electrically connected to the source region of the switching transistor FCG. Then, the gate electrode of the switching transistor FDG is electrically connected to the second switching transistor drive line among the pixel drive lines 10 illustrated in FIG. 2.

Similarly to the switching transistor FDG of the seventh embodiment described above, each of the two switching transistors FCG and FDG illustrated in FIG. 33 controls charge retention by the floating diffusion region FD, and adjusts the multiplication factor of the voltage according to the potential amplified by the amplification transistor AMP. Then, by switching on/off of each of the two switching transistors FCG and FDG, similarly to the pixel circuit 16G of the seventh embodiment described above, the FD capacitance C can be made variable, and the conversion efficiency can be switched.

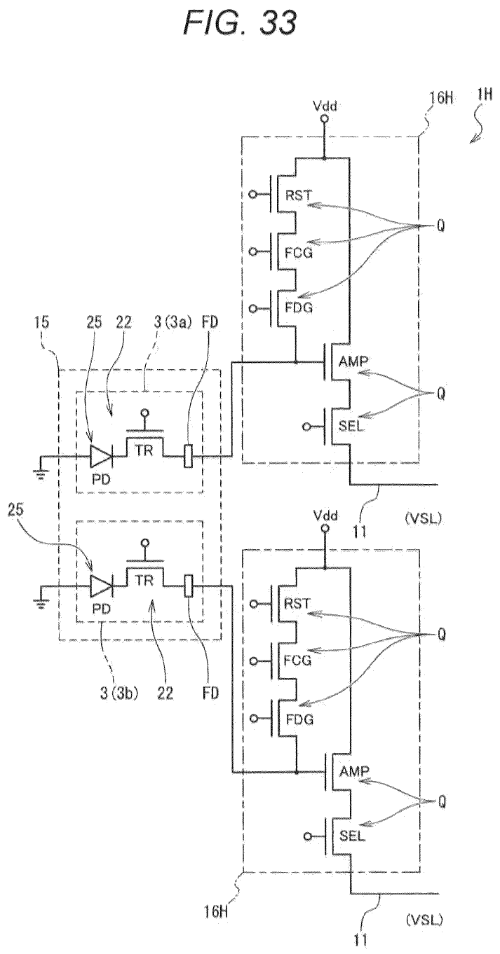

Although not illustrated in detail, referring to FIG. 34, the switching transistor FCG includes a gate electrode 47fc provided in the element formation region 43 of the photoelectric conversion region 22 (the first side surface portion 22b of the photoelectric conversion region 22) with a gate insulating film interposed therebetween, and a pair of main electrode regions 52fc and 52r provided in the element formation region 43 (the upper surface portion 22a) of the photoelectric conversion region 22 to be separated from each other in the gate length direction of the gate electrode 47fc in plan view and functioning as a source region and a drain region. In addition, the switching transistor FCG further includes a channel formation portion provided in the element formation region 43 (semiconductor layer 21) overlapping the gate electrode 47fc in plan view. The pair of main electrode regions 52fc and 52r includes an n-type semiconductor region, and the channel formation portion includes a p-type semiconductor region 23.

Although not illustrated in detail, referring to FIG. 34, the switching transistor FDG includes a gate electrode 47f provided in the element formation region 43 of the photoelectric conversion region 22 (the first side surface portion 22b of the photoelectric conversion region 22) with a gate insulating film interposed therebetween, and a pair of main electrode regions 52f and 52fc provided in the element formation region 43 (the upper surface portion 22a) of the photoelectric conversion region 22 to be separated from each other in the gate length direction of the gate electrode 47f in plan view and functioning as a source region and a drain region. Furthermore, the switching transistor FDG further includes a channel formation portion provided in the element formation region 43 (semiconductor layer 21) overlapping the gate electrode 47f in plan view. The pair of main electrode regions 52f and 52fc includes an n-type semiconductor region, and the channel formation portion includes a p-type semiconductor region 23.

In the eighth embodiment, the floating diffusion region FD is shared with the main electrode region 52f of the switching transistor FDG. In addition, the reset transistor RST and the switching transistor FCG are connected in series such that the main electrode region 52r of the reset transistor RST and the main electrode region 52r of the switching transistor FCG are shared. In addition, the switching transistor FCG and the switching transistor FDG share the main electrode region 52fc of the switching transistor FCG and the main electrode region 52fc of the switching transistor FDG, and are connected in series. That is, the switching transistors FCG and FDG of each of the two reset transistors RST are provided in the element formation region 43 of the photoelectric conversion region 22 in a state of being directly connected.

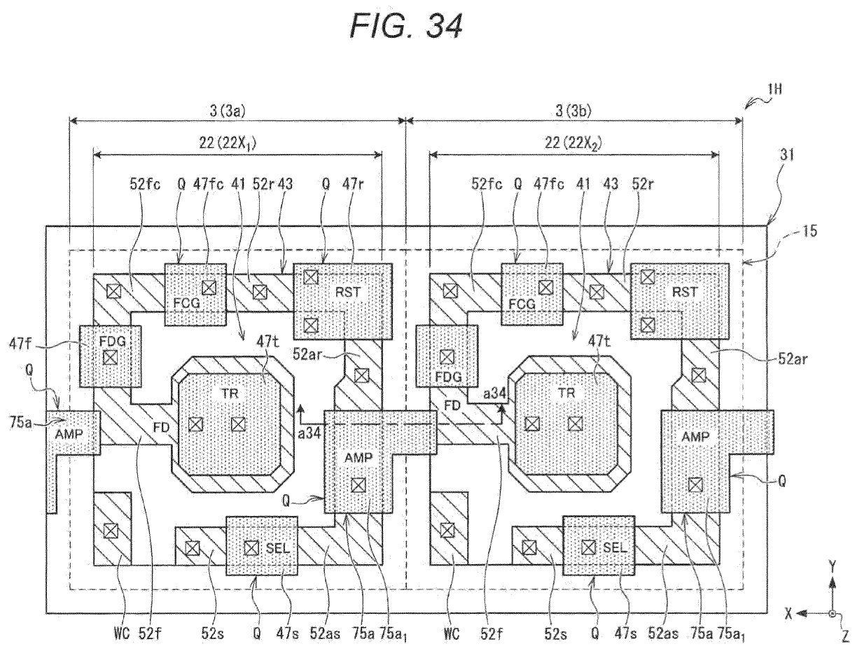

As illustrated in FIGS. 34 and 35, the amplification transistor AMP of the eighth embodiment basically has a configuration similar to that of the amplification transistor AMP of the first embodiment described above, and differs in the configuration of the gate electrode.

That is, in the two photoelectric conversion regions 22 (22X₁ and 22X₂) adjacent to each other in the X direction via the inter-pixel isolation region 31 in plan view, the amplification transistor AMP provided in one photoelectric conversion region 22X1 includes the gate electrode 75a provided over the upper surface portion 22a (element formation region 43) of one photoelectric conversion region 22X₁ and the inter-pixel isolation region 31 in plan view, and connected to the floating diffusion region FD of the other photoelectric conversion region 22X₂ at the first side surface portion 22b of the other photoelectric conversion region 22X₂.

Then, as illustrated in FIG. 35, the gate electrode 75a includes a head portion 75a₁ provided over one photoelectric conversion region 22X₁ and the inter-pixel isolation region 31 in plan view, and a relay connection portion 75a₃ protruding from the head portion 75a₁ toward the inter-pixel isolation region 31 and connected to the floating diffusion region FD at the first side surface portion 22b of the other photoelectric conversion region 22X₂. In other words, the gate electrode 75a extends outside the first surface portion S1 of the semiconductor layer 21 over one photoelectric conversion region 22X₁ and the inter-pixel isolation region 31, protrudes from the head portion 75a₁ to the inside of the inter-pixel isolation region 31, and is electrically and mechanically connected to the floating diffusion region FD at the first side surface portion 22b of the other photoelectric conversion region 22X₂. Similarly to the gate electrode 47a of the amplification transistor AMP according to the first embodiment described above, the gate electrode 75a of the eighth embodiment includes, for example, a polycrystalline silicon film (doped polysilicon film) into which an impurity for reducing the resistance value is introduced. Then, the gate electrode 75a of the eighth embodiment has substantially the same impurity concentration distribution on one photoelectric conversion region 22X₁ side and the other photoelectric conversion region 22X₂ side.

Here, in the eighth embodiment, the first side surface portion 22b of the photoelectric conversion region 22 corresponds to a specific example of the “side surface portion of the photoelectric conversion region” of the present technology.

### Main Effects of Eighth Embodiment

As described above, the amplification transistor AMP of the eighth embodiment includes the gate electrode 75a provided over the upper surface portion 22a of one photoelectric conversion region 22X₁ and the inter-pixel isolation region 31 in the two photoelectric conversion regions 22 (22X₁ and 22X₂) arranged in the X direction via the inter-pixel isolation region 31 in plan view, and electrically and mechanically connected to the floating diffusion region FD of the other photoelectric conversion region 22 in the first side surface portion 22b of the other photoelectric conversion region 22X₂. Therefore, it is not necessary to electrically connect the gate electrode 75a of the amplification transistor AMP and the floating diffusion region FD with the wiring of the multilayer wiring layer 55, and the wiring density of the multilayer wiring layer 55 overlapping the photoelectric conversion region 22 in plan view can be reduced. As a result, the degree of freedom in routing the wiring connected to the pixel transistor Q (AMP, SEL, RST, FCG, FDG) of the photoelectric conversion region 22 can be increased, and the restriction on the arrangement of the pixel transistor Q due to the routing of the wiring can be relaxed. Therefore, also in the solid-state imaging device 1H according to the eighth embodiment, similarly to the solid-state imaging device 1A according to the first embodiment described above, the degree of freedom in arrangement of the pixel transistor Q in the photoelectric conversion region 22 can be increased.

In addition, the gate electrode 75a and the floating diffusion region FD can be electrically connected at the shortest distance, and the wiring capacitance added to the floating diffusion region FD can be reduced as compared with the case where the gate electrode 47a and the floating diffusion region FD are electrically connected via the wiring of the multilayer wiring layer 55. As a result, conversion efficiency can be increased, and random noise can be reduced.

Here, in the CMOS image sensor, high conversion efficiency is an effective means for high sensitivity and low noise. In order to increase the conversion efficiency, it is necessary to reduce the FD capacitance and increase the source-follower gain (SF Gain). However, SF-Gain is generally about 0.8 to 0.9, and a significant improvement cannot be expected. On the other hand, the FD capacitance can be significantly reduced by a structural approach. Then, the FD capacitance mainly includes the sum of the FD diffusion layer capacitance in the floating diffusion region FD, the amplifier/gate capacitance in the amplification transistor AMP, and the FD wiring capacitance in the wiring connected to the floating diffusion region FD. Although, to reduce the capacitance of the FD diffusion layer, it is effective to reduce the area and concentration of the floating diffusion region FD, there is a concern of deterioration of the FD white spot and the FD dark current. To reduce the amplifier/gate capacitance, it is effective to reduce the gate electrode size of the amplification transistor AMP or thicken the gate insulating film 46, but there is a concern that random noise (RN) may deteriorate. However, reduction of the FD wiring capacitance has no concern of deterioration of pixel characteristics, and high conversion efficiency can be achieved. Therefore, in order to further increase the conversion efficiency, it is effective to reduce the FD capacitance by reducing the FD wiring capacitance as in the eighth embodiment.

In the eighth embodiment, the wiring capacitance component occupying the FD capacitance can be substantially eliminated, coupling of signals via other wirings can also be reduced, and fixed pattern noise (FPN) can also be suppressed.

### Modifications of Eighth Embodiment

Next, a modification of an eighth embodiment will be described.

### Modification 8-1

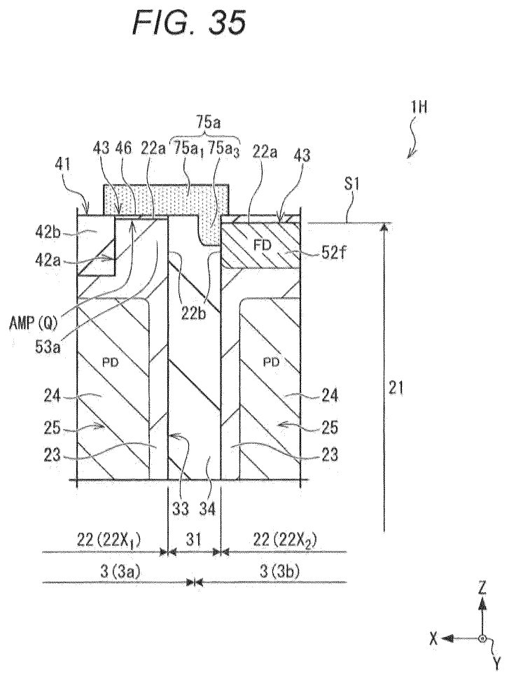

FIG. 36 is a main part longitudinal sectional view schematically illustrating Modification 8-1 according to the eighth embodiment of the present technology.

In the eighth embodiment described above, the case where the impurity concentration of the gate electrode 75a of the amplification transistor AMP has substantially the same impurity concentration distribution on one photoelectric conversion region 22X₁ side and the other photoelectric conversion region 22X₂ side has been described. However, the present technology is not limited to the eighth embodiment described above.

For example, the gate electrode 75a may have an impurity concentration distribution in which the impurity concentration on the other photoelectric conversion region 22X₂ side is lower than the impurity concentration on one photoelectric conversion region 22X₁ side.

In this case, as illustrated in FIG. 36, the gate electrode 75a includes a first portion 75X₁ located on one photoelectric conversion region 22X₁ side and a second portion 75X₂ located on the other photoelectric conversion region 22X₂ side and having an impurity concentration lower than that of the first portion 75X₁. Then, a boundary portion 75Z between the first portion 75X₁ and the second portion 75X₂ overlaps the inter-pixel isolation region 31 in plan view. The first portion 75X₁ includes one photoelectric conversion region 22X₁ side of the head portion 75a₁ of the gate electrode 75a. The second portion 75X₂ includes the other photoelectric conversion region 22X₂ side of the head portion 75a₁ of the gate electrode 75a and includes the relay connection portion 75a₃. That is, in the gate electrode 75a of Modification 8-1, the impurity concentration of the relay connection portion 75a₃ is lower than the impurity concentration on the photoelectric conversion region 22X₁ side.

In the case of Modification 8-1, it is possible to suppress impurity diffusion from the relay connection portion 75a₃ to the floating diffusion region FD while reducing the resistance on the channel formation portion side (portion on one photoelectric conversion region 22 side) of the gate electrode 75a, and it is possible to reduce the capacitance of the FD diffusion layer.

### Modification 8-2

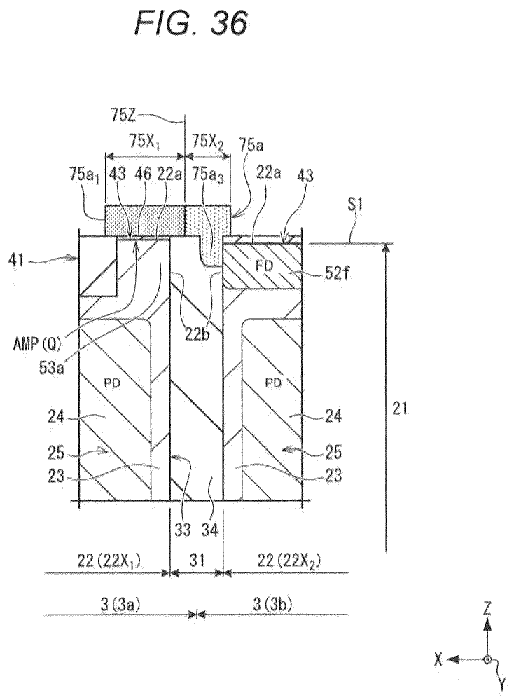

FIG. 37 is a main part longitudinal sectional view schematically illustrating Modification 8-2 according to an eighth embodiment of the present technology.

In the eighth embodiment described above, as illustrated in FIGS. 5A and 35, the inter-pixel isolation region 31 including the dug portion 33 provided in the semiconductor layer 21 and extending in the thickness direction (Z direction) of the semiconductor layer 21 and the isolation insulating film 34 provided in the dug portion 33 of the semiconductor layer 21 so as to embed the dug portion 33 has been described as the inter-pixel isolation region.

On the other hand, as illustrated in FIG. 37, the inter-pixel isolation region 31 of Modification 8-2 includes a dug portion 33 provided in the semiconductor layer 21 and extending in the thickness direction (Z direction) of the semiconductor layer 21, an isolation insulating film 34 provided in the dug portion 33 of the semiconductor layer 21 along the inner wall of the dug portion 33, and a conductor 35 provided in the dug portion 33 of the semiconductor layer 21 via the isolation insulating film 34. Then, although not illustrated, the conductor 35 is electrically connected to the wiring to which the reference potential is applied. That is, the inter-pixel isolation region 31 of Modification 8-2 includes the conductor 35 to which the reference potential is applied. As the reference potential, for example, a negative bias potential is applied.

As illustrated in FIG. 37, the gate electrode 75a of the amplification transistor AMP overlaps the conductor 35 of the inter-pixel isolation region 31 in plan view. Then, the conductor 35 of the inter-pixel isolation region 31 extends along the thickness direction (Z direction) of the semiconductor layer 21, and one end side located on the first surface portion S1 side of the semiconductor layer 21 faces (is adjacent to) the gate electrode 75a of the amplification transistor AMP via the isolation insulating film 34.

Here, if the parasitic capacitance of the floating diffusion region FD is too small, the FD potential swings due to coupling from other signal lines, and deterioration of RN (on resistance) easily occurs. Therefore, by applying a constant potential to the conductor 35 of the inter-pixel isolation region 31 and stabilizing the potential of the capacitively coupled floating diffusion region FD, fluctuation of the potential due to coupling with other signal lines can be reduced or eliminated, and noise reduction can be realized. Therefore, in this Modification 8-2, effects similar to those of the eighth embodiment described above can be obtained, and noise reduction can be realized.

### Modification 8-3

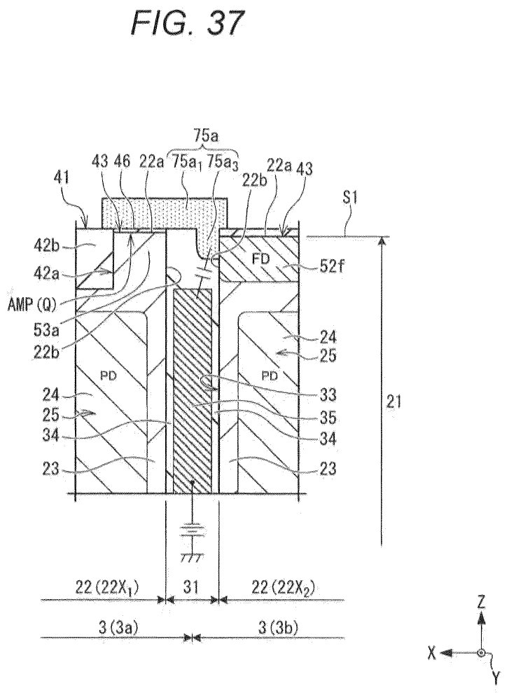

FIG. 38 is a main part longitudinal sectional view schematically illustrating Modification 8-3 according to the eighth embodiment of the present technology.

In the eighth embodiment described above, the gate electrode 75a including the head portion 75a₁ and the relay connection portion 75a₃ has been described as the gate electrode of the amplification transistor AMP, but the present technology is not limited to the gate electrode 75a of the eighth embodiment described above.

For example, as illustrated in FIG. 38, the gate electrode 75a may include a head portion 75a₁ and a relay connection portion 75a₃, and may further include a leg portion 75a₂ protruding from the head portion 75a₁ toward one photoelectric conversion region 22X₁. The leg portion 75a₂ protrudes from the head portion 75a₁ to the inside of the semiconductor layer 21 in the element formation region 43 of one photoelectric conversion region 22X₁, and is adjacent to the channel formation portion 53a of the semiconductor layer 21 with the gate insulating film 46 interposed therebetween. In FIG. 38, one leg portion 75a₂ is illustrated, but two or more leg portions 75a₂ may be provided.

By using the amplification transistor AMP of Modification 8-3, flicker noise and thermal noise can be reduced, and low on resistance can be realized.

### Modification 8-4

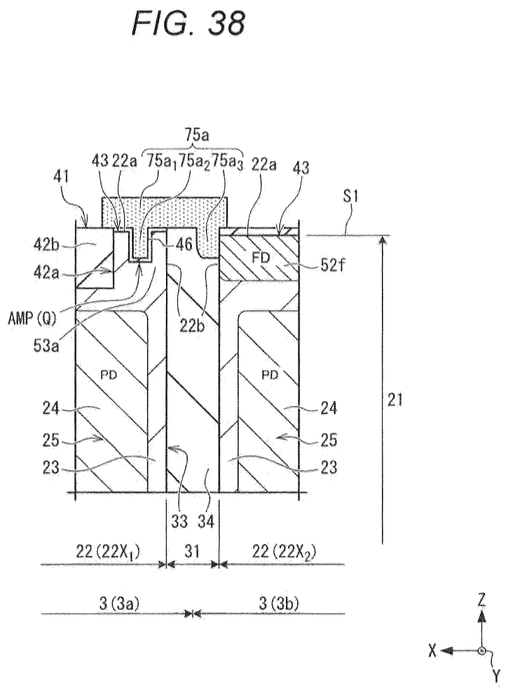

FIG. 39 is a main part longitudinal sectional view schematically illustrating Modification 8-4 according to the eighth embodiment of the present technology.

In the eighth embodiment described above, the case where the gate electrode 75a of the amplification transistor AMP provided in one photoelectric conversion region 22X₁ is electrically and mechanically connected to the floating diffusion region FD of the other photoelectric conversion region 22X₂ at the first side surface portion 22b of the other photoelectric conversion region 22X₂ has been described.

However, the present technology is not limited to the eighth embodiment described above.

For example, as illustrated in FIG. 39, the gate electrode 75a of the amplification transistor AMP provided in one photoelectric conversion region 22X₁ may be electrically and mechanically connected to the floating diffusion region FD of the other photoelectric conversion region 22X₂ at the upper surface portion 22a and the first side surface portion 22b of the other photoelectric conversion region 22X₂.

In the case of Modification 8-4, since the contact area between the gate electrode 75a and the floating diffusion region FD can be increased, resistance can be reduced.

### Modification 8-5

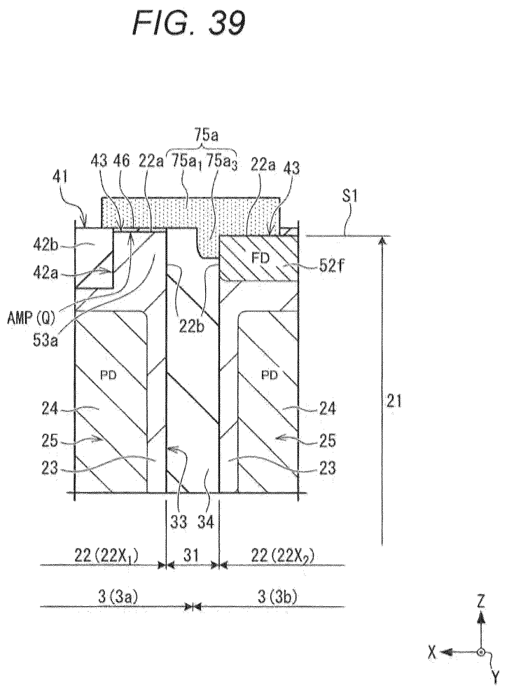

FIG. 40 is a main part longitudinal sectional view schematically illustrating Modification 8-5 according to the eighth embodiment of the present technology.

This modification is a combination of the impurity concentration distribution technique of Modification 8-1 illustrated in FIG. 36 and the parasitic capacitance addition technique of Modification 8-2 illustrated in FIG. 37.

Modification 8-5 can obtain the respective effects of Modification 8-1 and Modification 8-2 described above.

### Modification 8-6

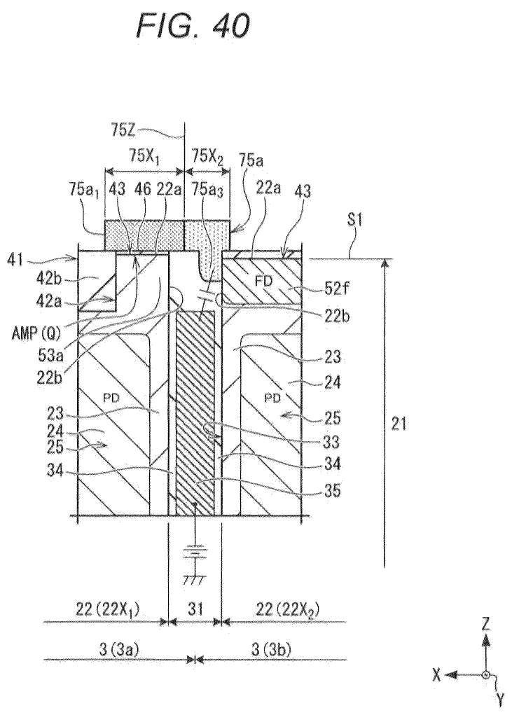

FIG. 41 is a main part longitudinal sectional view schematically illustrating Modification 8-6 according to the eighth embodiment of the present technology.

This modification is a combination of the impurity concentration distribution technique of Modification 8-1 illustrated in FIG. 36 and the channel width extension technique of Modification 8-3 illustrated in FIG. 38. Modification 8-6 can obtain the respective effects of Modification 8-1 and Modification 8-3 described above.

### Modification 8-7

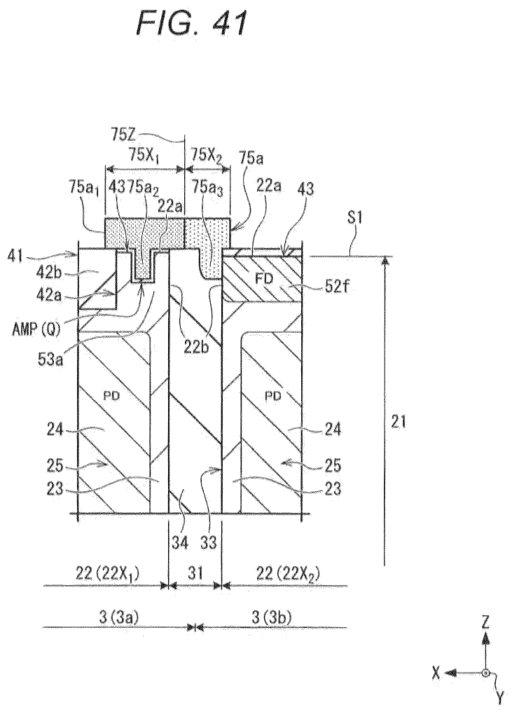

FIG. 42 is a main part longitudinal sectional view schematically illustrating Modification 8-7 according to the eighth embodiment of the present technology.

Modification 8-7 is a combination of the impurity concentration distribution technique of Modification 8-1 illustrated in FIG. 36 and the floating diffusion region connection technique of Modification 8-4 illustrated in FIG. 39. Modification 8-7 can obtain the respective effects of Modification 8-1 and Modification 8-4 described above.

### Other Modifications

Note that, although not illustrated, the parasitic capacitance addition technique of Modification 8-2 illustrated in FIG. 37, the channel width extension technique of Modification 8-3 illustrated in FIG. 38, and the floating diffusion region connection technique of Modification 8-4 illustrated in FIG. 39 can be combined.

Furthermore, although not illustrated, the channel width extension technique of Modification 8-3 illustrated in FIG. 38 and the floating diffusion region connection technique of Modification 8-4 illustrated in FIG. 39 can be combined.

### Ninth Embodiment

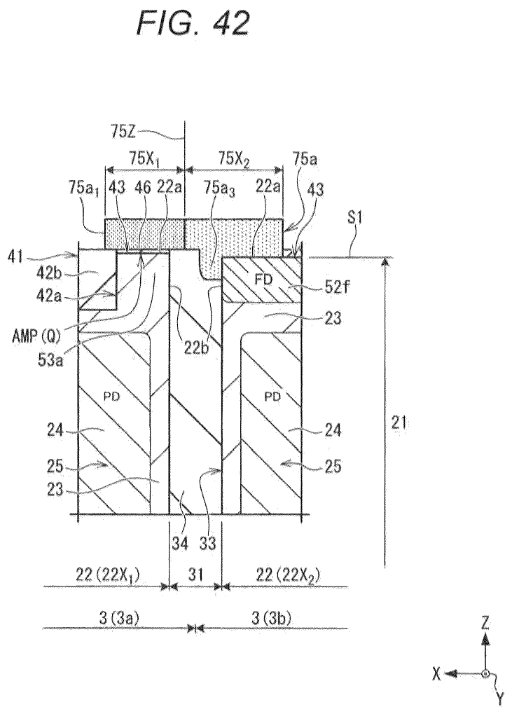

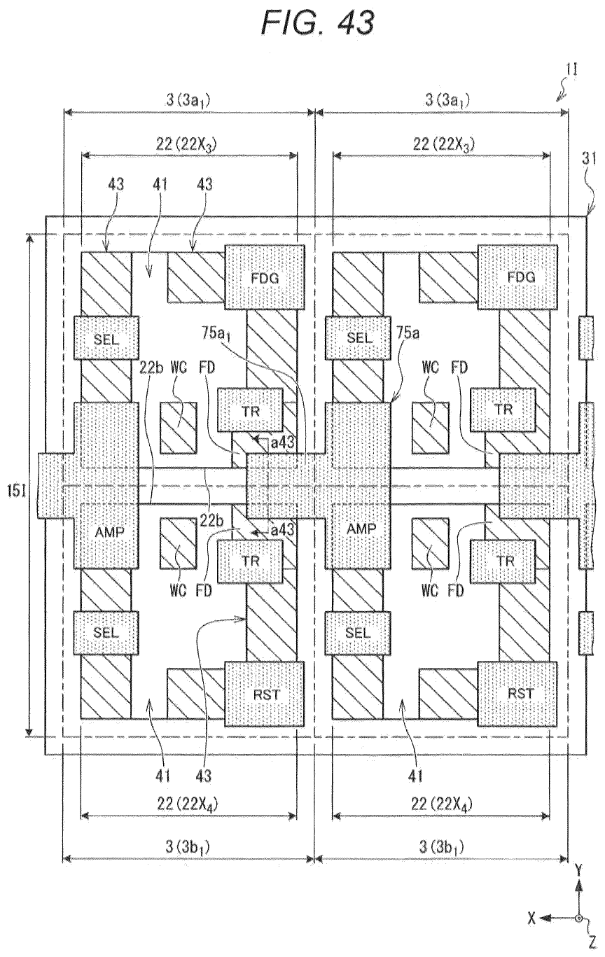

Next, a solid-state imaging device 11 according to a ninth embodiment of the present technology will be described with reference to FIGS. 43 and 44.

FIG. 43 is a plan view schematically illustrating a configuration example of two pixel blocks in the solid-state imaging device according to the ninth embodiment of the present technology.

FIG. 44 is a longitudinal sectional view schematically illustrating a longitudinal sectional structure taken along line a43-a43 in FIG. 43.

The solid-state imaging device 1I according to the ninth embodiment of the present technology includes a pixel block 15I illustrated in FIG. 43. The pixel block 15I of the ninth embodiment mainly includes two pixels 3 (3a₁ and 3b₁) arranged adjacent to each other in the Y direction as one unit.

Each of the two pixels 3 (3a₁ and 3b₁) included in one pixel block 15I includes a photoelectric conversion region 22 (22X₃ and 22X₄) partitioned by the inter-pixel isolation region 31. The photoelectric conversion region 22 (22X₃ and 22X₄) of the ninth embodiment basically has a configuration similar to that of the photoelectric conversion region 22 of the eighth embodiment described above, and differs in the following configuration.

That is, the photoelectric conversion region 22 (22X₃ and 22X₄) of the ninth embodiment is different from the photoelectric conversion region 22 of the eighth embodiment described above in the layout of the transistor and the planar shape of the element formation region 43. Then, in the two photoelectric conversion regions 22 (22X₃ and 22X₄) included in one pixel block 15I, the planar pattern of the element formation region 43 in one photoelectric conversion region 22X₃ and the planar pattern of the element formation region 43 in the other photoelectric conversion region 22X₄ are inverted about the boundary between the pixels 3a₁ and 3b₁ arranged in the Y direction.

Furthermore, in the photoelectric conversion region 22 (22X₃ and 22X₄) of the ninth embodiment, the amplification transistor AMP, the selection transistor SEL, and the switching transistor FDG are provided as pixel transistors in the element formation region 43, but the switching transistor FCG illustrated in FIG. 34 of the eighth embodiment described above is not provided. Then, in the ninth embodiment, the configuration of the amplification transistor AMP is slightly different from that of the eighth embodiment described above.

Specifically, the amplification transistor AMP of the ninth embodiment is shared by two photoelectric conversion regions 22 (22X₃ and 22X₄) included in one pixel block 15I, in other words, is shared by two pixels 3 (3a₁ and 3b₁) included in one pixel block 15I.

Then, as illustrated in FIG. 44, in the amplification transistor AMP of the ninth embodiment includes, in the two photoelectric conversion regions 22 (22X₃ and 22X₄) included in one pixel block 15I, a gate electrode 75a electrically and mechanically connected to the floating diffusion region FD of one photoelectric conversion region 22X₃ at the first side surface portion 22b of one photoelectric conversion region 22X₃, and electrically and mechanically connected to the floating diffusion region FD of the other photoelectric conversion region 22X₄ at the side surface portion 22b of the other photoelectric conversion region 22X₄. That is, the gate electrode 75a of the amplification transistor AMP of the ninth embodiment includes a head portion 75a₁ extending outside the first surface portion S1 of the semiconductor layer 21 over the photoelectric conversion region 22 and the inter-pixel isolation region 31, and a relay connection portion 75a₃ protruding from the head portion 75a₁ to the inside of the inter-pixel isolation region 31 and electrically and mechanically connected to the first side surface portion 22b of each of the two photoelectric conversion regions 22 (22X₃ and 22X₄) adjacent to each other with the inter-pixel isolation region 31 interposed therebetween in plan view.

Also in the solid-state imaging device 1I according to the ninth embodiment, effects similar to those of the solid-state imaging device 1H according to the eighth embodiment described above can be obtained.

### Tenth Embodiment

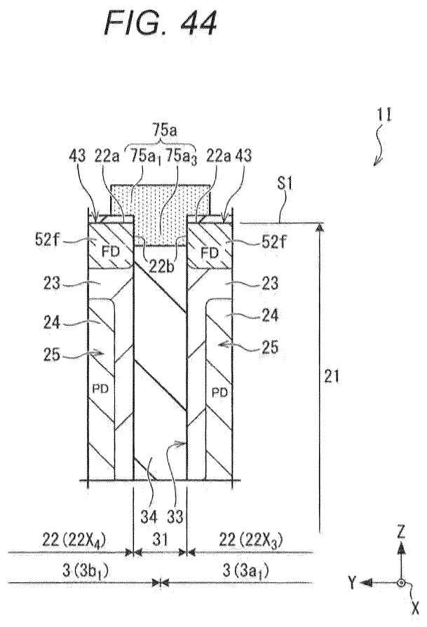

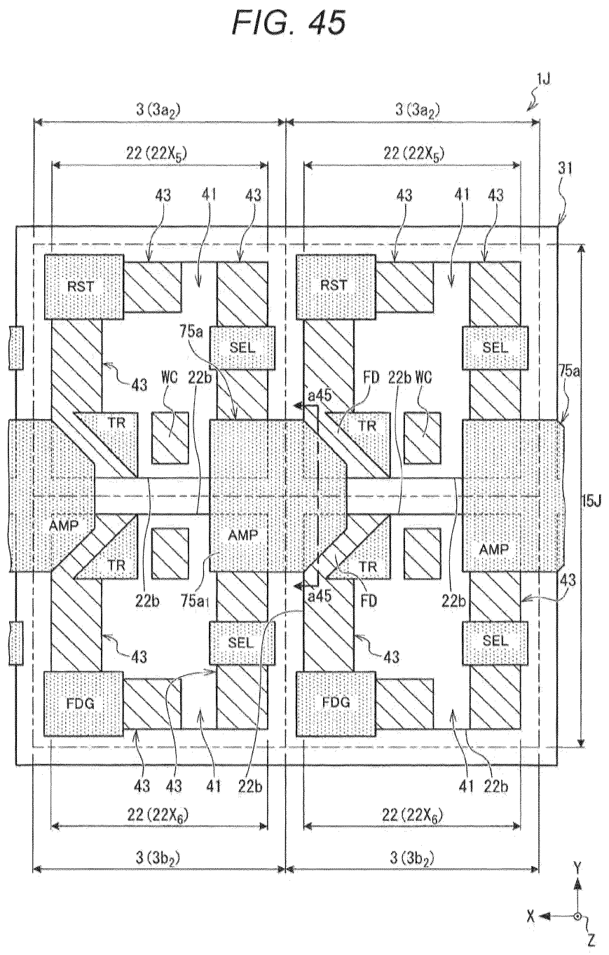

Next, a solid-state imaging device 1I according to a tenth embodiment of the present technology will be described with reference to FIGS. 45 and 46.

FIG. 45 is a plan view schematically illustrating a configuration example of two pixel blocks in the solid-state imaging device according to the tenth embodiment of the present technology.

FIG. 46 is a longitudinal sectional view schematically illustrating a longitudinal sectional structure taken along line a45-a45 in FIG. 45.

A solid-state imaging device 1J according to a tenth embodiment of the present technology includes a pixel block 15J illustrated in FIG. 45. The pixel block 15J of the tenth embodiment mainly includes two pixels 3 (3a₂ and 3b₂) arranged adjacent to each other in the Y direction as one unit.

Each of the two pixels 3 (3a₂ and 3b₂) included in one pixel block 15J includes a photoelectric conversion region 22 (22X₅, 22X₆) partitioned by the inter-pixel isolation region 31. The photoelectric conversion region 22 (22X₅, 22X₆) of the tenth embodiment basically has a configuration similar to that of the photoelectric conversion region 22 of the eighth embodiment described above, and differs in the following configuration.

That is, the photoelectric conversion region 22 (22X₅, 22X₆) of the tenth embodiment is different from the photoelectric conversion region 22 of the eighth embodiment described above in the layout of the transistor and the planar shape of the element formation region 43. Then, in the two photoelectric conversion regions 22 (22X₅ and 22X₆) included in one pixel block 15J, the planar pattern of the element formation region 43 in one photoelectric conversion region 22X₅ and the planar pattern of the element formation region 43 in the other photoelectric conversion region 22X₆ are inverted about the boundary between the pixels 3a₂ and 3b₂ arranged in the Y direction.

Furthermore, in the photoelectric conversion region 22 (22X₅, 22X₆) of the tenth embodiment, the amplification transistor AMP, the selection transistor SEL, and the switching transistor FDG are provided as pixel transistors in the element formation region 43, but the switching transistor FCG illustrated in FIG. 34 of the eighth embodiment described above is not provided. Then, in the tenth embodiment, the configuration of the amplification transistor AMP is slightly different from that of the eighth embodiment described above.

Specifically, the amplification transistor AMP of the tenth embodiment is shared by two photoelectric conversion regions 22 (22X₅ and 22X₆) included in one pixel block 15J, in other words, shared by two pixels 3 (3a₂ and 3b₂) included in one pixel block 15J.

Then, as illustrated in FIG. 46, the amplification transistor AMP of the tenth embodiment includes, in the two photoelectric conversion regions 22 (22X₅ and 22X₆) included in one pixel block 15J, a gate electrode 75a electrically and mechanically connected to the floating diffusion region FD of one photoelectric conversion region 22X, on the upper surface portion 22a and the first side surface portion 22b of one photoelectric conversion region 22X₅, and electrically and mechanically connected to the floating diffusion region FD of the other photoelectric conversion region 22X₆ on the upper surface portion 22a and the first side surface portion 22b of the other photoelectric conversion region 22X₆. That is, the gate electrode 75a of the amplification transistor AMP of the tenth embodiment includes a head portion 75a₁ extending outside the first surface portion S1 of the semiconductor layer 21 over the photoelectric conversion region 22 and the inter-pixel isolation region 31, and a relay connection portion 75a₃ protruding from the head portion 75a₁ to the inside of the inter-pixel isolation region 31 and electrically and mechanically connected to the upper surface portion 22a and the first side surface portion 22b of each of the two photoelectric conversion regions 22 (22X₅ and 22X₆) adjacent to each other with the inter-pixel isolation region 31 interposed therebetween in plan view.

Also in the solid-state imaging device 1J according to the tenth embodiment, effects similar to those of the solid-state imaging device 1H according to the eighth embodiment described above can be obtained, and resistance can be reduced similarly to Modification 8-4 described above.

### Eleventh Embodiment

### Example of Application to Electronic Apparatus

The present technology (technology of the present disclosure) can be applied to various electronic apparatuses such as an imaging device such as a digital still camera or a digital video camera, a mobile phone having an imaging function, or other apparatuses having an imaging function, for example.

FIG. 47 is a diagram illustrating a schematic configuration of an electronic apparatus (for example, a camera) according to the fourth embodiment of the present technology.

As illustrated in FIG. 47, the electronic apparatus 100 includes a solid-state imaging device 101, an optical lens 102, a shutter device 103, a drive circuit 104, and a signal processing circuit 105. The electronic apparatus 100 is an embodiment in a case where the solid-state imaging device 1A according to the first embodiment of the present technology is used in an electronic apparatus (for example, a camera) as the solid-state imaging device 101.

The optical lens 102 forms an image of image light (incident light 106) from a subject on an imaging plane of the solid-state imaging device 101. Therefore, signal charge is accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with a drive signal (timing signal) supplied from the drive circuit 104, the solid-state imaging device 101 performs charge transfer. The signal processing circuit 105 performs various types of signal processing on a signal (pixel signal (image signal) output from the solid-state imaging device 101. A video signal obtained as a result of the signal processing is stored into a storage medium such as a memory, or is output to a monitor.

With such a configuration, in the solid-state imaging device 101, the transconductance (gm) of the transfer transistor TR is improved, so that the image quality performance of the electronic apparatus 100 according to the eleventh embodiment can be improved.

Note that the electronic apparatus 100 to which the solid-state imaging devices according to the embodiments described above can be applied is not limited to a camera, and the solid-state imaging devices can also be applied to other electronic apparatuses. For example, the solid-state imaging device may be applied to an imaging device such as a camera module for a mobile device such as a mobile phone or a tablet terminal.

Furthermore, the present technology can be applied to any photodetection device including not only the above-described solid-state imaging device as an image sensor but also a ranging sensor that is also called a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. Also in this ranging sensor, the pixel transistor described above can be adopted.

Note that the present technology may have the following configurations.
(1)

A photodetection device including:
a semiconductor layer including a first surface portion and a second surface portion located on sides opposite to each other in a thickness direction; and
a photoelectric conversion region partitioned by an isolation region extending in the thickness direction of the semiconductor layer and provided in the semiconductor layer,
in which the photoelectric conversion region includes:
an upper surface portion located on the first surface portion side of the semiconductor layer and a first side surface portion located on the isolation region side;
a transfer transistor provided on the upper surface portion side and transferring a signal charge photoelectrically converted by the photoelectric conversion unit to a charge holding unit; and
a plurality of pixel transistors provided on the side of the upper surface portion, and
at least one pixel transistor of the plurality of pixel transistors includes a gate electrode provided in the isolation region so as to be adjacent to the first side surface portion of the photoelectric conversion region with a gate insulating film interposed therebetween.
(2)

The photodetection device according to (1), in which at least one pixel transistor of the plurality of pixel transistors further includes a pair of main electrode regions provided on the upper surface portion side of the photoelectric conversion region while being separated from each other in a gate length direction of the gate electrode in plan view.
(3)

The photodetection device according to (1) or (2), in which the gate electrode is selectively provided in the isolation region.
(4)

The photodetection device according to any one of (1) to (3), in which the gate electrode is provided over the upper surface portion and the side surface portion of the photoelectric conversion region with the gate insulating film interposed therebetween.
(5)

The photodetection device according to (4), in which the gate electrode includes:
a head portion extending over the photoelectric conversion region and the isolation region in plan view outside the first surface portion of the semiconductor layer; and
a leg portion protruding from the head portion toward the isolation region and adjacent to the first side surface portion of the photoelectric conversion region with the gate insulating film interposed therebetween.
(6)

The photodetection device according to (1), in which
the photoelectric conversion region further includes an inter-element isolation region provided on the upper surface portion side, and a second side surface portion located on a side opposite to the first side surface portion in plan view and adjacent to the inter-element isolation region, and
the gate electrode is provided over each of the upper surface portion, the first side surface portion, and the second side surface portion with the gate insulating film interposed therebetween.
(7)

The photodetection device according to (6), in which
the gate electrode includes:
a head portion extending over the isolation region and the inter-element isolation region in plan view outside the first surface portion of the semiconductor layer;
a first leg portion protruding from the head portion toward the isolation region and adjacent to the first side surface portion of the photoelectric conversion region with the gate insulating film interposed therebetween; and
a second leg portion protruding from the head portion toward the inter-element isolation region and adjacent to the second side surface portion of the photoelectric conversion region with the gate insulating film interposed therebetween.
(8)

The photodetection device according to (6), in which at least one of the plurality of pixel transistors includes a channel formation portion between the first side surface portion and the second side surface portion of the photoelectric conversion region.
(9)

The photodetection device according to (1), in which
the isolation region includes a first vertical portion provided on the first surface portion side of the semiconductor layer, and a second vertical portion extending from the first vertical portion toward the second surface portion side of the semiconductor layer and having a width narrower than a width of the first vertical portion, and
the gate electrode is entirely provided in the first vertical portion.
(10)

The photodetection device according to (1), in which
the isolation region includes a first vertical portion provided on the first surface portion side of the semiconductor layer, and a second vertical portion extending from the first vertical portion toward the second surface portion side of the semiconductor layer and having a width narrower than a width of the first vertical portion, and
a part of the gate electrode is provided in the first vertical portion.
(11)

The photodetection device according to (1), in which the gate electrode is adjacent to the first side surface portion of each of the two photoelectric conversion regions adjacent to each other in plan view with the gate insulating film interposed therebetween.
(12)

The photodetection device according to (2), in which one of the pair of main electrode regions is shared with the charge holding unit.
(13)

The photodetection device according to (1), in which in the two photoelectric conversion regions adjacent to each other with the isolation region interposed therebetween in plan view, the gate electrode is adjacent to the first side surface portion of one of the photoelectric conversion regions with the gate insulating film interposed therebetween, and is connected adjacent to the charge holding unit of the other photoelectric conversion region.
(14)

The photodetection device according to (1), further including a relay conductor portion provided in the isolation region between the two photoelectric conversion regions adjacent to each other in plan view, in which
the relay conductor portion is connected to a semiconductor region provided in each of the two photoelectric conversion regions on the first side surface portion of each of the two photoelectric conversion regions adjacent to each other in plan view.
(15)

A photodetection device including:
a semiconductor layer; and
a photoelectric conversion region divided by an isolation region extending in a thickness direction of the semiconductor layer and provided in the semiconductor layer,
in which the photoelectric conversion region includes:
an upper surface portion and a side surface portion;
a charge holding unit provided on the upper surface portion side and holding a signal charge transferred from the photoelectric conversion unit via a transfer transistor; and
a pixel transistor provided on the upper surface portion side, and
in two of the photoelectric conversion regions adjacent to each other via the isolation region in plan view, the pixel transistor provided in one of the photoelectric conversion regions includes a gate electrode provided over the upper surface portion of the one of the photoelectric conversion regions and the isolation region in plan view and connected to the charge holding unit of the other photoelectric conversion region at the side surface portion of the other photoelectric conversion region.
(16)

The photodetection device according to (15), in which the gate electrode includes a head portion provided over the one of the photoelectric conversion regions and the isolation region, and a relay connection portion protruding from the head toward the isolation region and connected to the charge holding unit on the side surface portion of the other photoelectric conversion region.
(17)

The photodetection device according to (15) or (16), in which the gate electrode has a lower impurity concentration on a side of the other of the photoelectric conversion regions than on a side of the one of the photoelectric conversion regions.
(18)

The photodetection device according to any one of (15) to (17), in which
the gate electrode includes a first portion located on a side of the one of the photoelectric conversion regions and a second portion located on a side of the other of the photoelectric conversion regions and having an impurity concentration lower than an impurity concentration of the first portion, and
a boundary portion between the first portion and the second portion overlaps the isolation region in plan view.
(19)

The photodetection device according to any one of (16) to (18), in which the gate electrode further includes a leg portion protruding from the head portion toward one of the photoelectric conversion regions.
(20)

The photodetection device according to any one of (15) to (19), in which the gate electrode is connected to the charge holding unit over the upper surface portion and the side surface portion of the other photoelectric conversion region.
(21)

The photodetection device according to any one of (15) to (20), in which the isolation region includes a conductor to which a potential is applied.
(22)

An electronic apparatus including:
a photodetection device;
an optical lens that forms an image of image light from a subject on an imaging surface of the photodetection device; and
a signal processing circuit that performs signal processing on a signal output from the photodetection device, in which
the photodetection device includes:
a semiconductor layer including a first surface portion and a second surface portion located on opposite sides in a thickness direction;
a photoelectric conversion region partitioned by an isolation region extending in the thickness direction of the Semiconductor layer and provided in the semiconductor layer, the photoelectric conversion region including an upper surface portion located on the first surface portion side of the semiconductor layer and a first side surface portion located on the isolation region side;
a transfer transistor provided on the upper surface portion side of the photoelectric conversion region and transferring a signal charge photoelectrically converted by the photoelectric conversion unit to a charge holding unit; and
a plurality of pixel transistors provided on the upper surface portion of the photoelectric conversion region, and
at least one pixel transistor of the plurality of pixel transistors includes a gate electrode provided in the isolation region so as to be adjacent to the first side surface portion of the photoelectric conversion region via a gate insulating film.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A, 1B, 1C, 1D, 1E, 1F, 1G, 1H, 1I, 1J Solid-state imaging device
2 Semiconductor chip
2A Pixel array unit
2B Peripheral portion
3, 3a, 3a₁, 3a₂, 3b, 3b₁, 3b₂ Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15, 15, 15I, 15J Pixel block, 15H
16, 16G, 16H Pixel circuit (readout circuit)
21 Semiconductor layer
22 Photoelectric conversion region
22a Upper surface portion
22b First side surface portion
22c Second side surface portion
23 p-type semiconductor region
24 n-type semiconductor region
25 Photoelectric conversion unit
31, 31B Inter-pixel isolation region (isolation region)
31b₁ First vertical portion
31b₂ Second vertical portion
31bz Step portion
31x First planar portion
31y Second planar portion
31z1 First vertical portion
31z2 Second vertical portion
33 Dug portion
34 Isolation insulating film
35 Conductor
41 Inter-element isolation region (field isolation region)
42a Shallow groove portion
42b Isolation insulating film
43 Element formation region (active region)
45a, 45b Dug portion
46 Gate insulating film
47 Gate electrode film
47a, 47r, 47s, 47t Gate electrode
47t₁ Head portion
47t₂ Leg portion
51 Dug portion
52as, 52as, 52r, 52s Main electrode region
53r, 53s Channel formation portion
55 Multilayer wiring layer
56 Interlayer insulating film
57 First wiring layer
57a, 57f, 57r, 57s, 57t Contact electrode
58a, 58r, 58s, 58t Wiring
61 Planarization film
63 Optical filter
64 Microlens
71r Gate electrode
71r₁ Head portion
71r₂ Leg portion
71s Gate electrode
71s₁ Head portion
71s₂ Leg portion
72r Gate electrode
72r₁ Head portion
72r₂ First leg portion
72r₃ Second leg portion
72s Gate electrode
72s₁ Head portion
72s₂ First leg portion
72s₃ Second leg portion
73a Gate electrode
73a₁ Head portion
73a₂ Leg portion
74a, 74b Relay conductor portion
75a Gate electrode
75a₁ Head portion
75a₃ Relay connection portion
100 Electronic apparatus
101 Solid-state imaging device
102 Optical lens (optical system)
103 Shutter device
104 Drive circuit
105 Signal processing circuit
AMP Amplification transistor
FD n-type floating diffusion region
FCG, FDG Switching transistor
Q Pixel transistor
RST Reset transistor
SEL Selection transistor
S1 First surface portion
S2 Second surface portion
TR Transfer transistor
WC Power supply contact region

1. A photodetection device comprising:
a semiconductor layer including a first surface portion and a second surface portion located on sides opposite to each other in a thickness direction; and
a photoelectric conversion region partitioned by an isolation region extending in the thickness direction of the semiconductor layer and provided in the semiconductor layer,
wherein the photoelectric conversion region includes:
an upper surface portion located on the first surface portion side of the semiconductor layer and a first side surface portion located on the isolation region side;
a transfer transistor provided on the upper surface portion side and transferring a signal charge photoelectrically converted by the photoelectric conversion unit to a charge holding unit; and
a plurality of pixel transistors provided on the side of the upper surface portion, and
at least one pixel transistor of the plurality of pixel transistors includes a gate electrode provided in the isolation region so as to be adjacent to the first side surface portion of the photoelectric conversion region with a gate insulating film interposed therebetween.

2. The photodetection device according to claim 1, wherein at least one pixel transistor of the plurality of pixel transistors further includes a pair of main electrode regions provided on the upper surface portion side of the photoelectric conversion region while being separated from each other in a gate length direction of the gate electrode in plan view.

3. The photodetection device according to claim 1, wherein the gate electrode is selectively provided in the isolation region.

4. The photodetection device according to claim 1, wherein the gate electrode is provided over the upper surface portion and the side surface portion of the photoelectric conversion region with the gate insulating film interposed therebetween.

5. The photodetection device according to claim 4, wherein the gate electrode includes:
a head portion extending over the photoelectric conversion region and the isolation region in plan view outside the first surface portion of the semiconductor layer; and
a leg portion protruding from the head portion toward the isolation region and adjacent to the first side surface portion of the photoelectric conversion region with the gate insulating film interposed therebetween.

6. The photodetection device according to claim 1, wherein
the photoelectric conversion region further includes an inter-element isolation region provided on the upper surface portion side, and a second side surface portion located on a side opposite to the first side surface portion in plan view and adjacent to the inter-element isolation region, and
the gate electrode is provided over each of the upper surface portion, the first side surface portion, and the second side surface portion with the gate insulating film interposed therebetween.

7. The photodetection device according to claim 6, wherein
the gate electrode includes:
a head portion extending over the isolation region and the inter-element isolation region in plan view outside the first surface portion of the semiconductor layer;
a first leg portion protruding from the head portion toward the isolation region and adjacent to the first side surface portion of the photoelectric conversion region with the gate insulating film interposed therebetween; and
a second leg portion protruding from the head portion toward the inter-element isolation region and adjacent to the second side surface portion of the photoelectric conversion region with the gate insulating film interposed therebetween.

8. The photodetection device according to claim 6, wherein at least one of the plurality of pixel transistors includes a channel formation portion between the first side surface portion and the second side surface portion of the photoelectric conversion region.

9. The photodetection device according to claim 1, wherein the isolation region includes a first vertical portion provided on the first surface portion side of the semiconductor layer, and a second vertical portion extending from the first vertical portion toward the second surface portion side of the semiconductor layer and having a width narrower than a width of the first vertical portion, and the gate electrode is entirely provided in the first vertical portion.

10. The photodetection device according to claim 1, wherein
the isolation region includes a first vertical portion provided on the first surface portion side of the semiconductor layer, and a second vertical portion extending from the first vertical portion toward the second surface portion side of the semiconductor layer and having a width narrower than a width of the first vertical portion, and
a part of the gate electrode is provided in the first vertical portion.

11. The photodetection device according to claim 1, wherein the gate electrode is adjacent to the first side surface portion of each of the two photoelectric conversion regions adjacent to each other in plan view with the gate insulating film interposed therebetween.

12. The photodetection device according to claim 2, wherein one of the pair of main electrode regions is shared with the charge holding unit.

13. The photodetection device according to claim 1, wherein in the two photoelectric conversion regions adjacent to each other with the isolation region interposed therebetween in plan view, the gate electrode is adjacent to the first side surface portion of one of the photoelectric conversion regions with the gate insulating film interposed therebetween, and is connected adjacent to the charge holding unit of the other photoelectric conversion region.

14. The photodetection device according to claim 1, further comprising a relay conductor portion provided in the isolation region between the two photoelectric conversion regions adjacent to each other in plan view, wherein
the relay conductor portion is connected to a semiconductor region provided in each of the two photoelectric conversion regions on the first side surface portion of each of the two photoelectric conversion regions adjacent to each other in plan view.

15. A photodetection device comprising:
a semiconductor layer; and
a photoelectric conversion region divided by an isolation region extending in a thickness direction of the semiconductor layer and provided in the semiconductor layer,
wherein the photoelectric conversion region includes:
an upper surface portion and a side surface portion;
a charge holding unit provided on the upper surface portion side and holding a signal charge transferred from the photoelectric conversion unit via a transfer transistor; and
a pixel transistor provided on the upper surface portion side, and
in two of the photoelectric conversion regions adjacent to each other via the isolation region in plan view, the pixel transistor provided in one of the photoelectric conversion regions includes a gate electrode provided over the upper surface portion of the one of the photoelectric conversion regions and the isolation region in plan view and connected to the charge holding unit of the other photoelectric conversion region at the side surface portion of the other photoelectric conversion region.

16. The photodetection device according to claim 15, wherein the gate electrode includes a head portion provided over the one of the photoelectric conversion regions and the isolation region, and a relay connection portion protruding from the head toward the isolation region and connected to the charge holding unit on the side surface portion of the other photoelectric conversion region.

17. The photodetection device according to claim 15, wherein the gate electrode has a lower impurity concentration on a side of the other of the photoelectric conversion regions than on a side of the one of the photoelectric conversion regions.

18. The photodetection device according to claim 15, wherein
the gate electrode includes a first portion located on a side of the one of the photoelectric conversion regions and a second portion located on a side of the other of the photoelectric conversion regions and having an impurity concentration lower than an impurity concentration of the first portion, and a boundary portion between the first portion and the second portion overlaps the isolation region in plan view.

19. The photodetection device according to claim 16, wherein the gate electrode further includes a leg portion protruding from the head portion toward the one of the photoelectric conversion regions.

20. The photodetection device according to claim 15, wherein the gate electrode is connected to the charge holding unit over the upper surface portion and the side surface portion of the other photoelectric conversion region.

21. The photodetection device according to claim 15, wherein the isolation region includes a conductor to which a potential is applied.

22. An electronic apparatus comprising:
a photodetection device;
an optical lens that forms an image of image light from a subject on an imaging surface of the photodetection device; and
a signal processing circuit that performs signal processing on a signal output from the photodetection device, wherein
the photodetection device includes:
a semiconductor layer including a first surface portion and a second surface portion located on opposite sides in a thickness direction;
a photoelectric conversion region partitioned by an isolation region extending in the thickness direction of the semiconductor layer and provided in the semiconductor layer, the photoelectric conversion region including an upper surface portion located on the first surface portion side of the semiconductor layer and a first side surface portion located on the isolation region side;
a transfer transistor provided on the upper surface portion side of the photoelectric conversion region and transferring a signal charge photoelectrically converted by the photoelectric conversion unit to a charge holding unit; and
a plurality of pixel transistors provided on the upper surface portion of the photoelectric conversion region, and
at least one pixel transistor of the plurality of pixel transistors includes a gate electrode provided in the isolation region so as to be adjacent to the first side surface portion of the photoelectric conversion region via a gate insulating film.
